(19) United States
(12) Patent Application Publication
(10) Pub. No.: US 2017/0358760 A1
(43) Pub. Date: Dec. 14, 2017

(54) ORGANIC ELECTROLUMINESCENT DEVICE

(71) Applicant: MERCK PATENT GMBH, Darmstadt (DE)

(72) Inventors: Philipp STOESSEL, Frankfurt am Main (DE); Joachim KAISER, Darmstadt (DE); Jonas Valentin KROEBER, Frankfurt am Main (DE); Tobias GROSSMAN, Darmstadt (DE)

(73) Assignee: MERCK PATENT GMBH, Darmstadt (DE)

(21) Appl. No.: 15/521,126

(22) PCT Filed: Oct. 7, 2015
(86) PCT No.: PCT/EP2015/001987

§ 371 Date: Apr. 21, 2017

(30) Foreign Application Priority Data
Oct. 24, 2014 (EP) 14003625.2

(51) Int. Cl. H01L 51/00; C09K 11/02; H01L 51/50; C09K 11/06

(52) U.S. Cl. CPC H01L 51/0085; H01L 51/0072; C09K 11/06; C09K 11/025; H01L 51/5016; H01L 51/0067; C09K 2211/1029; H01L 2251/552; C09K 2211/1011; C09K 2211/185; C09K 2211/1007

(57) ABSTRACT

The present invention relates to organic electroluminescent devices which comprise mixtures of at least one phosphorescent material and at least two electron-transporting materials.

The present invention relates to organic electroluminescent devices which comprise mixtures of a phosphorescent material and a plurality of electron-transporting materials.

The structure of organic electroluminescent devices (OLEDs) in which organic semiconductors are employed as functional materials is described, for example, in U.S. Pat. No. 4,539,507, U.S. Pat. No. 5,151,629, EP 0676461 and WO 98/27136. The emitting materials employed here are, in particular, also organometallic iridium complexes which exhibit phosphorescence instead of fluorescence (M. A. Baldo et al., Appl. Phys. Lett. 1999, 75, 4-6). For quantum-mechanical reasons, an up to four-fold increase in energy and power efficiency is possible using organometallic compounds as phosphorescence emitters.

In the prior art, various matrix materials are used for phosphorescent emitters, inter alia triazine derivatives, pyrimidine derivatives or lactam derivatives. These can be employed either as an individual material or in a mixture with a further matrix material as matrix for phosphorescent emitters. Better results are frequently achieved on use of a mixture of two matrix materials than on use of a single matrix material. In general, a mixture of a hole-transport material and an electron-transport material is frequently employed as mixed matrix for phosphorescent emitters (for example in accordance with WO 02/047457, WO 2004/062324). In the case of mixtures of this type, however, there is still a further need for improvement, in particular with respect to the lifetime. Mixtures between triazine or pyrimidine derivatives and lactam derivatives are also known as mixed matrix for phosphorescent emitters (for example in accordance with WO 2014/094964). These mixtures exhibit very good lifetimes on use in organic electroluminescent devices, which represents a considerable advance.

However, they also require a higher emitter concentration for this purpose than mixtures with a hole- and an electron-transporting matrix material, usually in the order of more than 12% by vol. Furthermore, they typically have an operating voltage which is about 0.5 V higher, meaning that further improvements are desirable here.

The iridium compounds usually used are complexes which have three bidentate, monoanionic ligands, at least two of which are bonded to the iridium via in each case one carbon atom and one nitrogen atom or via two carbon atoms. Improvements in the iridium compounds can be achieved by condensing aliphatic alkyl groups onto the ligand, as described, for example, in WO 2014/023377. However, further improvements are also desirable here.

In general, there is still a further need for improvement in the case of organic electroluminescent devices which exhibit phosphorescent emission, in particular with respect to the combination of high efficiency, low voltage and long lifetime. Thus, although optimisation of one of these properties is possible, it is, however, problematic to optimise all these properties simultaneously. With conventional emitters, this can only be achieved on use of a high emitter concentration, which is not desirable with respect to resource conservation of the metal iridium present, meaning that improvements are desirable here. The same applies to the emitters described below if they are used in a conventional matrix or matrix mixture, meaning that improvements are still desirable on use of these emitters. The technical object on which the present invention is based is thus the provision of phosphorescent OLEDs which have improved properties, in particular with respect to a combination of the above-mentioned properties.

In summary, it can be stated that the object of the present invention is to provide OLEDs which have good efficiency and a low operating voltage at the same time as a good lifetime and use of a low emitter concentration. Compared with an OLED which, although comprising an emitter as described below, does so, however, in a matrix comprising a hole-transporting material and an electron-transporting material, the object is, in particular, to improve the lifetime of the OLED. By contrast, compared with an OLED which comprises a triplet emitter which does not contain a group of the formulae (1) to (7) as described below, but comprises a mixture of two electron-transporting matrix materials, the object is to improve the efficiency of the OLED and at the same time to reduce the triplet emitter concentration necessary for this purpose.

Surprisingly, it has been found that organic electroluminescent devices which comprise at least one phosphorescent emitter, as described below, and at least two electron-transporting matrix materials in the emitting layer achieve this object and result in improvements in the organic electroluminescent device. The present invention therefore relates to organic electroluminescent devices of this type.

The present invention relates to an organic electroluminescent device comprising cathode, anode and an emitting layer which comprises the following compounds:
(A) at least one electron-transporting compound which has an LUMO≦−2.4 eV; and
(B) at least one further electron-transporting compound which is different from the first electron-transporting compound and has an LUMO≦−2.4 eV; and
(C) at least one phosphorescent iridium compound which contains at least one at least bidentate ligand which is bonded to the iridium via one carbon atom and one nitrogen atom or via two carbon atoms and which contains at least one unit of one of the following formulae (1) to (7),

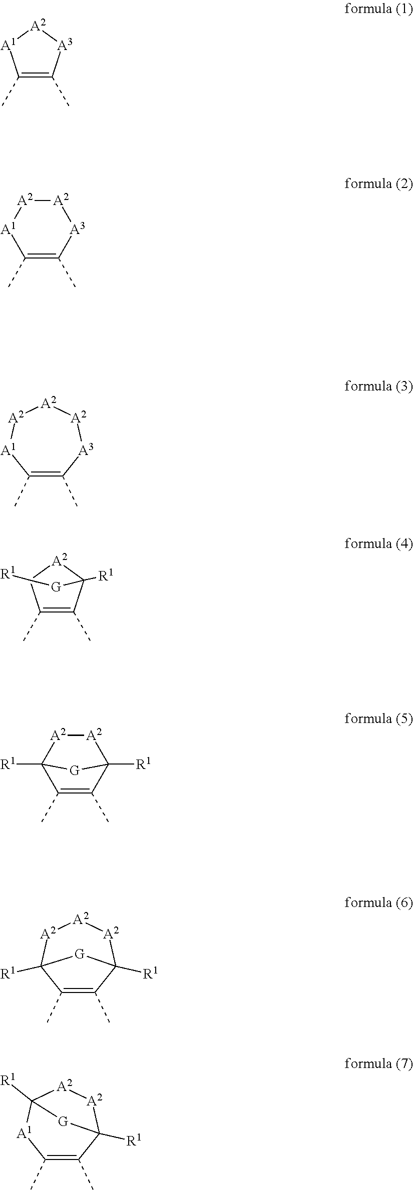

where the two carbon atoms explicitly drawn in are atoms which are part of the ligand and the dashed bonds indicate the linking of the two carbon atoms in the ligand and furthermore:
A¹, A³ are, identically or differently on each occurrence, C(R³)₂, O, S, NR³ or C(═O);
A² is C(R¹)₂, O, S, NR³ or C(═O);
with the proviso that no two heteroatoms in the groups of the formulae (1) to (7) are bonded directly to one another and that no two groups C═O are bonded directly to one another;
G is an alkylene group having 1, 2 or 3 C atoms, which may be substituted by one or more radicals R², —CR²═CR²— or an ortho-linked arylene or heteroarylene group having 5 to 14 aromatic ring atoms, which may be substituted by one or more radicals R²;
R¹ is on each occurrence, identically or differently, H, D, F, Cl, Br, I, N(R²)₂, CN, Si(R²)₃, B(OR²)₂, C(═O)R², a straight-chain alkyl, alkoxy or thioalkoxy group having 1 to 20 C atoms or a straight-chain alkenyl or alkynyl group having 2 to 20 C atoms or a branched or cyclic alkyl, alkenyl, alkynyl, alkoxy or thioalkoxy group having 3 to 20 C atoms, each of which may be substituted by one or more radicals R², where one or more non-adjacent CH₂ groups may be replaced by R²C═CR², Si(R²)₂, C═O, NR², O, S or CONR² and where one or more H atoms may be replaced by D, F or CN, or an aromatic or heteroaromatic ring system having 5 to 60 aromatic ring atoms, which may in each case be substituted by one or more radicals R², or an aryloxy or heteroaryloxy group having 5 to 40 aromatic ring atoms, which may be substituted by one or more radicals R², or a diarylamino group, diheteroarylamino group or arylheteroarylamino group having 10 to 40 aromatic ring atoms, which may be substituted by one or more radicals R²; two or more adjacent radicals R¹ here may form an aliphatic ring system with one another;
R² is on each occurrence, identically or differently, H, D, F or an aliphatic, aromatic and/or heteroaromatic organic radical having 1 to 20 C atoms, in particular a hydrocarbon radical, in which, in addition, one or more H atoms may be replaced by D or F; two or more substituents R² here may also form an aliphatic or aromatic ring system with one another;
R³ is, identically or differently on each occurrence, F, a straight-chain alkyl or alkoxy group having 1 to 10 C atoms, a branched or cyclic alkyl or alkoxy group having 3 to 10 C atoms, each of which may be substituted by one or more radicals R², where one or more non-adjacent CH₂ groups may be replaced by R²C═CR², Si(R²)₂, C═O, NR², O, S or CONR² and where one or more H atoms may be replaced by D or F, or an aromatic or heteroaromatic ring system having 5 to 24 aromatic ring atoms, which may in each case be substituted by one or more radicals R², or an aryloxy or heteroaryloxy group having 5 to 24 aromatic ring atoms, which may be substituted by one or more radicals R², or an aralkyl or heteroaralkyl group having 5 to 24 aromatic ring atoms, which may be substituted by one or more radicals R²; two radicals R³ here which are bonded to the same carbon atom may form an aliphatic or aromatic ring system with one another and thus form a spiro system; furthermore, R³ may form an aliphatic ring system with an adjacent radical R¹.

For the purposes of the present invention, all luminescent iridium compounds are referred to as phosphorescent.

An electron-transporting compound in the sense of the present invention, as is present in the emitting layer of the organic electroluminescent device according to the invention, is a compound which has an LUMO≦−2.40 eV. Preferably, the LUMO of at least one of the two electron-transporting compounds is ≦−2.50 eV and that of the other electron-transporting compound is ≦−2.40 eV. The LUMO of each of the electron-transporting compounds is particularly preferably ≦−2.50 eV, very particularly preferably ≦−2.60 eV and in particular ≦−2.65 eV. The LUMO here is the lowest unoccupied molecular orbital. The value of the LUMO of the compounds in the sense of the present application is determined by quantum-chemical calculation, as described in general terms below in the example part.

Adjacent substituents in the sense of the present application are substituents which are either bonded to the same carbon atom or which are bonded to carbon atoms which are bonded directly to one another.

An aryl group in the sense of this invention contains 6 to 60 C atoms; a heteroaryl group in the sense of this invention contains 2 to 60 C atoms and at least one heteroatom, with the proviso that the sum of C atoms and heteroatoms is at least 5. The heteroatoms are preferably selected from N, O and/or S. An aryl group or heteroaryl group here is taken to mean either a simple aromatic ring, i.e. benzene, or a simple heteroaromatic ring, for example pyridine, pyrimidine, thiophene, etc., or a condensed (fused) aryl or heteroaryl group, for example naphthalene, anthracene, phenanthrene, quinoline, isoquinoline, etc. Aromatic rings linked to one another by a single bond, such as, for example, biphenyl, are, by contrast, not referred to as an aryl or heteroaryl group, but instead as an aromatic ring system.

An aromatic ring system in the sense of this invention contains 6 to 80 C atoms in the ring system. A heteroaromatic ring system in the sense of this invention contains 2 to 60 C atoms and at least one heteroatom in the ring system, with the proviso that the sum of C atoms and heteroatoms is at least 5. The heteroatoms are preferably selected from N, O and/or S. An aromatic or heteroaromatic ring system in the sense of this invention is intended to be taken to mean a system which does not necessarily contain only aryl or heteroaryl groups, but instead in which, in addition, a plurality of aryl or heteroaryl groups may be connected by a non-aromatic unit, such as, for example, a C, N or O atom. Thus, for example, systems such as fluorene, 9,9′-spirobifluorene, 9,9-diarylfluorene, triarylamine, diaryl ether, stilbene, etc., are also intended to be taken to be aromatic ring systems in the sense of this invention, as are systems in which two or more aryl groups are connected, for example, by a short alkyl group.

For the purposes of the present invention, an aliphatic hydrocarbon radical or an alkyl group or an alkenyl or alkynyl group, which may contain 1 to 40 C atoms and in which, in addition, individual H atoms or CH₂ groups may be substituted by the above-mentioned groups, is preferably taken to mean the radicals methyl, ethyl, n-propyl, i-propyl, n-butyl, i-butyl, s-butyl, t-butyl, 2-methylbutyl, n-pentyl, s-pentyl, neopentyl, cyclopentyl, n-hexyl, neohexyl, cyclohexyl, n-heptyl, cycloheptyl, n-octyl, cyclooctyl, 2-ethylhexyl, trifluoromethyl, pentafluoroethyl, 2,2,2-trifluoroethyl, ethenyl, propenyl, butenyl, pentenyl, cyclopentenyl, hexenyl, cyclohexenyl, heptenyl, cycloheptenyl, octenyl, cyclooctenyl, ethynyl, propynyl, butynyl, pentynyl, hexynyl, heptynyl or octynyl. An alkoxy group having 1 to 40 C atoms is preferably taken to mean methoxy, trifluoromethoxy, ethoxy, n-propoxy, i-propoxy, n-butoxy, i-butoxy, s-butoxy, t-butoxy, n-pentoxy, s-pentoxy, 2-methylbutoxy, n-hexoxy, cyclohexyloxy, n-heptoxy, cycloheptyloxy, n-octyloxy, cyclooctyloxy, 2-ethylhexyloxy, pentafluoroethoxy or 2,2,2-trifluoroethoxy. A thioalkyl group having 1 to 40 C atoms is taken to mean, in particular, methylthio, ethylthio, n-propylthio, i-propylthio, n-butylthio, i-butylthio, s-butylthio, t-butylthio, n-pentylthio, s-pentylthio, n-hexylthio, cyclohexylthio, n-heptylthio, cycloheptylthio, n-octylthio, cyclooctylthio, 2-ethylhexylthio, trifluoromethylthio, pentafluoroethylthio, 2,2,2-trifluoroethylthio, ethenylthio, propenylthio, butenylthio, pentenylthio, cyclopentenylthio, hexenylthio, cyclohexenylthio, heptenylthio, cycloheptenylthio, octenylthio, cyclooctenylthio, ethynylthio, propynylthio, butynylthio, pentynylthio, hexynylthio, heptynylthio or octynylthio. In general, alkyl, alkoxy or thioalkyl groups in accordance with the present invention may be straight-chain, branched or cyclic, where one or more non-adjacent CH₂ groups may be replaced by the above-mentioned groups; furthermore, one or more H atoms may also be replaced by D, F, Cl, Br, I, CN or NO₂, preferably F, Cl or CN, furthermore preferably F or CN, particularly preferably CN.

An aromatic or heteroaromatic ring system having 5-30 or 5-60 aromatic ring atoms respectively, which may also in each case be substituted by the above-mentioned radicals R, R¹ or R², is taken to mean, in particular, groups derived from benzene, naphthalene, anthracene, benzanthracene, phenanthrene, pyrene, chrysene, perylene, fluoranthene, naphthacene, pentacene, benzopyrene, biphenyl, biphenylene, terphenyl, triphenylene, fluorene, spirobifluorene, dihydrophenanthrene, dihydropyrene, tetrahydropyrene, cis- or trans-indenofluorene, cis- or trans-indenocarbazole, cis- or trans-indolocarbazole, truxene, isotruxene, spirotruxene, spiroisotruxene, furan, benzofuran, isobenzofuran, dibenzofuran, thiophene, benzothiophene, isobenzothiophene, dibenzothiophene, pyrrole, indole, isoindole, carbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthimidazole, phenanthrimidazole, pyridimidazole, pyrazinimidazole, quinoxalinimidazole, oxazole, benzoxazole, naphthoxazole, anthroxazole, phenanthroxazole, isoxazole, 1,2-thiazole, 1,3-thiazole, benzothiazole, pyridazine, hexaazatriphenylene, benzopyridazine, pyrimidine, benzopyrimidine, quinoxaline, 1,5-diazaanthracene, 2,7-diazapyrene, 2,3-diazapyrene, 1,6-diazapyrene, 1,8-diazapyrene, 4,5-diazapyrene, 4,5,9,10-tetraazaperylene, pyrazine, phenazine, phenoxazine, phenothiazine, fluorubin, naphthyridine, azacarbazole, benzocarboline, phenanthroline, 1,2,3-triazole, 1,2,4-triazole, benzotriazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 1,3,5-triazine, 1,2,4-triazine, 1,2,3-triazine, tetrazole, 1,2,4,5-tetrazine, 1,2,3,4-tetrazine, 1,2,3,5-tetrazine, purine, pteridine, indolizine and benzothiadiazole or groups derived from a combination of these systems.

In a preferred embodiment, the emitting layer of the organic electroluminescent device consists only of the two electron-transporting compounds and the phosphorescent iridium compound and comprises no further compounds.

In a further embodiment of the invention, the emitting layer, apart from the two electron-transporting compounds and the phosphorescent iridium compound described above, also comprises at least one further iridium compound which either emits at shorter or longer wavelength than the iridium compound described above.

In a preferred embodiment of the invention, the electron-transporting compounds in the mixture are the matrix materials, which contribute insignificantly or not at all to the emission of the mixture, and the phosphorescent iridium compound is the emitting compound, i.e. the compound whose emission from the emitting layer is observed.

In order that the phosphorescent iridium compound is the emitting compound in the mixture of the emitting layer, it is preferred that the lowest triplet energy of the electron-transporting compounds is a maximum of 0.1 eV lower than the triplet energy of the phosphorescent iridium compound. T₁(matrix) is particularly preferably ≧T₁(emitter), where this relationship preferably applies to each of the two matrix materials.

The following particularly preferably applies: 0≦T₁(matrix)−T₁(emitter)≦0.3 eV;

very particularly preferably: 0≦T₁(matrix)−T₁(emitter)≦0.1 eV.

T₁(matrix) stands for the lowest triplet energy of the electron-transporting compound and T₁(emitter) stands for the lowest triplet energy of the phosphorescent iridium compound. The triplet energy of the matrix T₁(matrix) and of the emitter T₁(emitter) are, for the purposes of the present application, determined by quantum-chemical calculation, as described in general terms below in the example part.

Classes of compound which are preferably suitable as electron-transporting compounds in the organic electroluminescent device according to the invention are described below.

Suitable electron-transporting compounds are selected from the substance classes of the triazines, the pyrimidines, the pyrazines, the pyridazines, the pyridines, the lactams, the metal complexes, in particular the Be, Zn and Al complexes, the aromatic ketones, the aromatic phosphine oxides, the azaphospholes, the azaboroles, which are substituted by at least one electron-transporting substituent, and the quinoxalines. It is essential to the invention here that these materials have an LUMO of ≦−2.40 eV. Many derivatives of the above-mentioned substance classes have such an LUMO, meaning that these substance classes can generally be regarded as suitable, even if individual compounds of these substance classes possibly have an LUMO>−2.40 eV. In accordance with the invention, however, use is only made of materials which have an LUMO≦−2.40 eV. The person skilled in the art will, without inventive step, be able to select compounds which satisfy this condition for the LUMO from the materials of these substance classes, from which a multiplicity of materials are already known.

In a preferred embodiment of the invention, the electron-transporting compounds are purely organic compounds, i.e. compounds which do not contain metals.

In a preferred embodiment of the invention, at least one of the electron-transporting compounds is a triazine or pyrimidine compound, in particular a triazine compound. Particularly suitable triazine and pyrimidine compounds are described in detail below.

In a further preferred embodiment of the invention, at least one of the electron-transporting compounds is a lactam compound. Particularly suitable lactams are described in detail below.

In a particularly preferred embodiment of the invention, one of the electron-transporting compounds is a triazine or pyrimidine compound, in particular a triazine compound, and the other of the electron-transporting compounds is a lactam compound.

If the electron-transporting compound is a triazine or pyrimidine compound, this compound is then preferably selected from the compounds of the following formulae (8) and (9),

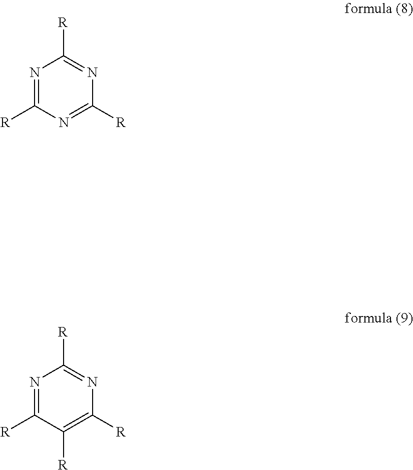

where R¹ and R² have the meanings given above and furthermore:
R is selected on each occurrence, identically or differently, from the group consisting of H, D, F, Cl, Br, I, CN, NO₂, N(R¹)₂, C(═O)R¹, P(═O)R¹, a straight-chain alkyl, alkoxy or thioalkyl group having 1 to 20 C atoms or a branched or cyclic alkyl, alkoxy or thioalkyl group having 3 to 20 C atoms or an alkenyl or alkynyl group having 2 to 20 C atoms, each of which may be substituted by one or more radicals R¹, where one or more non-adjacent CH₂ groups may be replaced by R¹C═CR¹, C≡C, Si(R¹)₂, C═O, C═S, C═NR¹, P(═O)(R¹), SO, SO₂, NR¹, O, S or CONR¹ and where one or more H atoms may be replaced by D, F, Cl, Br, I, CN or NO₂, an aromatic or heteroaromatic ring system having 5 to 40 aromatic ring atoms, which may in each case be substituted by one or more radicals R¹, an aryloxy or heteroaryloxy group having 5 to 40 aromatic ring atoms, which may be substituted by one or more radicals R¹, or an aralkyl or heteroaralkyl group having 5 to 40 aromatic ring atoms, which may be substituted by one or more radicals R¹, where two or more adjacent substituents R may optionally form a monocyclic or polycyclic, aliphatic, aromatic or heteroaromatic ring system, which may be substituted by one or more radicals R¹.

In a preferred embodiment of the compounds of the formula (8) or formula (9), at least one of the substituents R stands for an aromatic or heteroaromatic ring system, which may in each case be substituted by one or mire radicals R¹. In formula (1), it is particularly preferred for all three substituents R to stand for an aromatic or heteroaromatic ring system, which may in each case be substituted by one or more radicals R¹. In formula (2), it is particularly preferred for two or three substituents R to stand for an aromatic or heteroaromatic ring system, which may in each case be substituted by one or more radicals R¹, and for the other substituents R to stand for H. Particularly preferred embodiments are thus the compounds of the following formulae (8a) and (9a) to (9d),

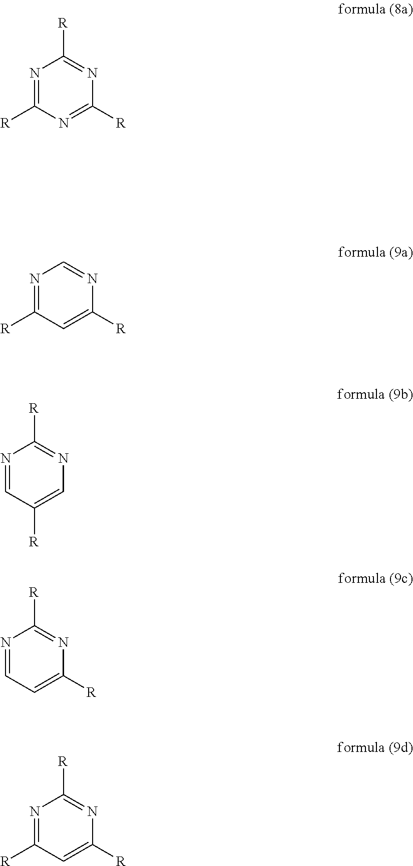

where R stands, identically or differently, for an aromatic or heteroaromatic ring system having 5 to 40 aromatic ring atoms, which may in each case be substituted by one or more radicals R¹, and R¹ has the meaning given above.

In the case of the pyrimidine compounds, preference is given here to the compounds of the formulae (9a) and (9d), in particular compounds of the formula (9d).

Preferred aromatic or heteroaromatic ring systems R in formulae (8) and (9) contain 5 to 30 aromatic ring atoms, in particular 6 to 24 aromatic ring atoms, and may be substituted by one or more radicals R¹. The aromatic or heteroaromatic ring systems here preferably contain no condensed aryl or heteroaryl groups in which more than two aromatic six-membered rings are condensed directly onto one another. They particularly preferably contain absolutely no aryl or heteroaryl groups in which aromatic six-membered rings are condensed directly onto one another. Thus, it is preferred for R to have, for example, no naphthyl groups or higher condensed aryl groups and likewise no quinoline groups, acridine groups, etc. By contrast, it is possible for R to have, for example, carbazole groups, dibenzofuran groups, etc., since no 6-membered aromatic or heteroaromatic rings are condensed directly onto one another in these structures. Further suitable substituents are phenanthrene and triphenylene.

Preferred substituents R in formulae (8) and (9) are selected, identically or differently on each occurrence, from the group consisting of benzene, biphenyl, in particular ortho-, meta- or para-biphenyl, terphenyl, in particular ortho-, meta-, para- or branched terphenyl, quaterphenyl, in particular ortho-, meta-, para- or branched quaterphenyl, fluorenyl, in particular 1-, 2-, 3- or 4-fluorenyl, spirobifluorenyl, in particular 1-, 2-, 3- or 4-spirobifluorenyl, naphthyl, in particular 1- or 2-naphthyl, pyrrole, furan, thiophene, indole, benzofuran, benzothiophene, carbazole, in particular 1-, 2-, 3- or 4-carbazole, 1-, 2- or 3-dibenzofuran, in particular 1-, 2-, 3- or 4-dibenzofuran, dibenzothiophene, in particular 1-, 2-, 3- or 4-dibenzothiophene, indenocarbazole, indolocarbazole, pyridine, in particular 2-, 3- or 4-pyridine, pyrimidine, in particular 2-, 4- or 5-pyrimidine, pyrazine, pyridazine, triazine, phenanthrene, triphenylene or combinations of two or three of these groups, each of which may be substituted by one or more radicals R¹. “Combination of two or three of these groups” here means that two or three of the above-mentioned groups are condensed directly onto one another.

It is particularly preferred for at least one group R to be selected from the structures of the following formulae (10) to (52),

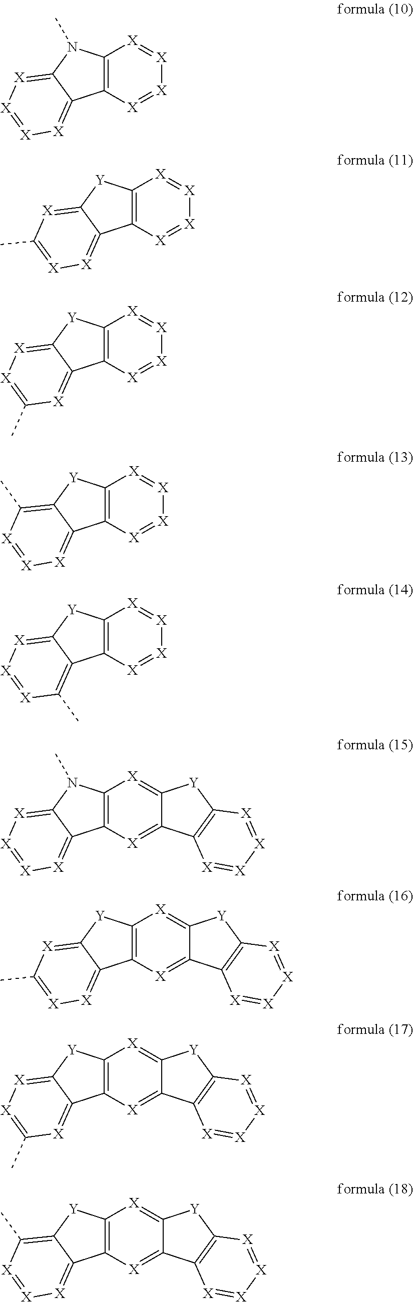

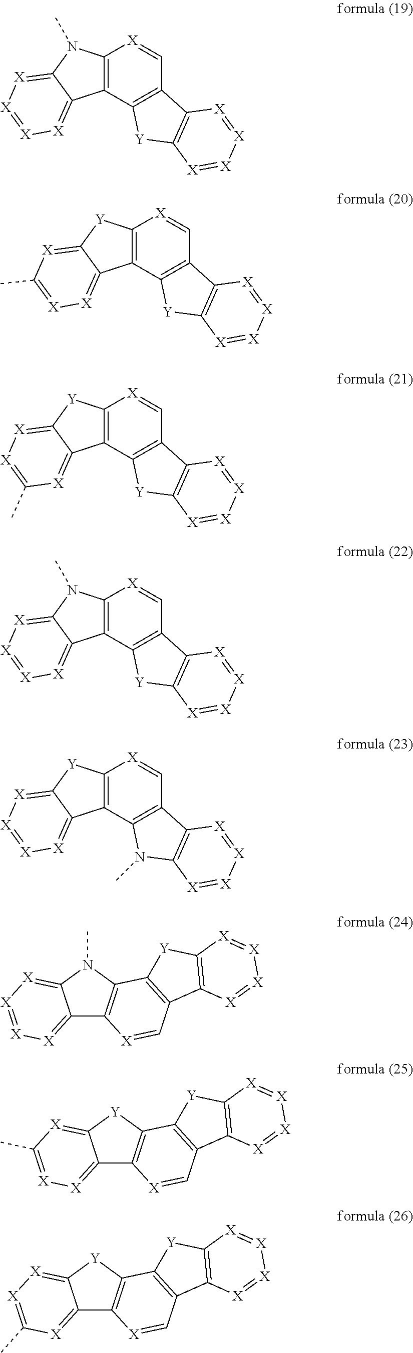

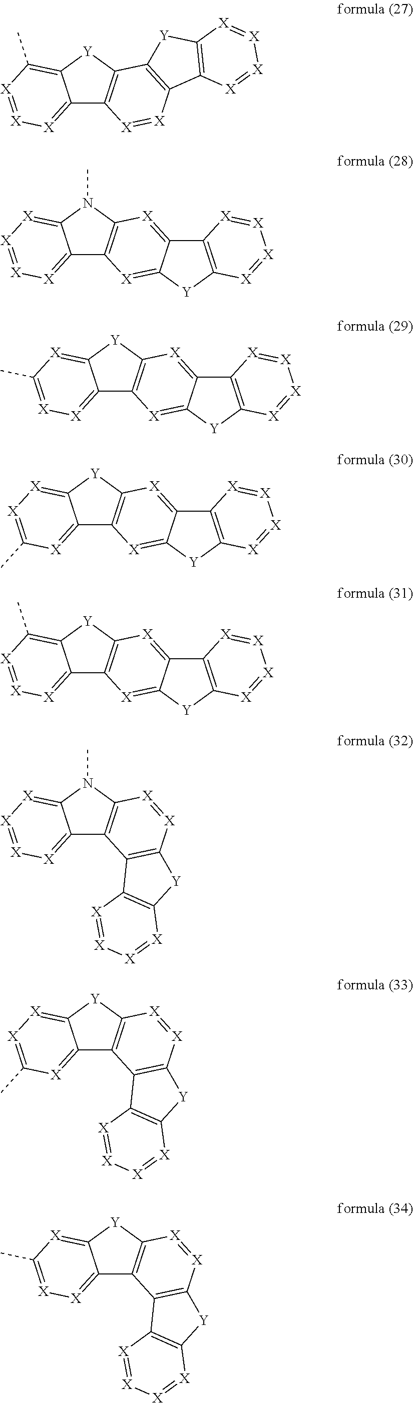

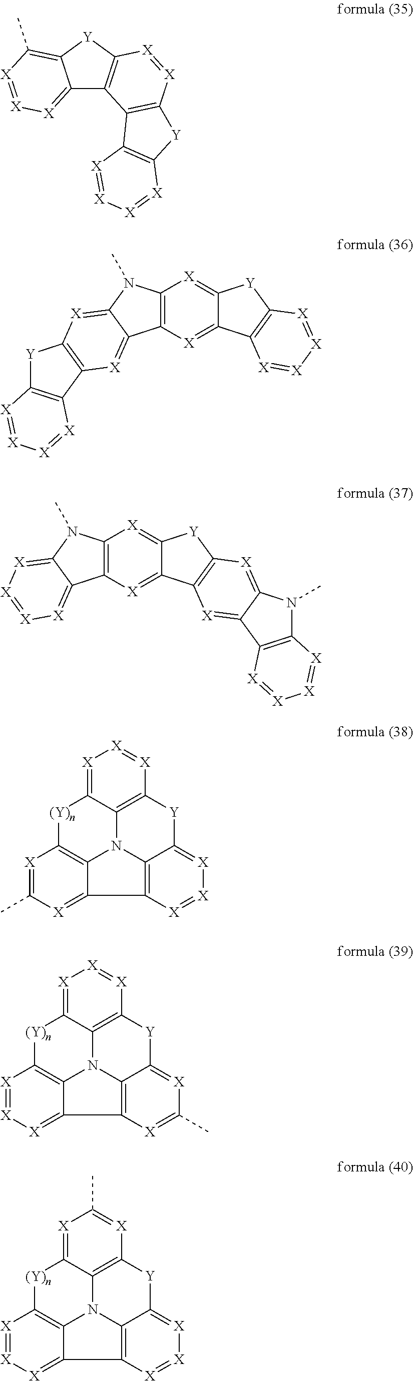

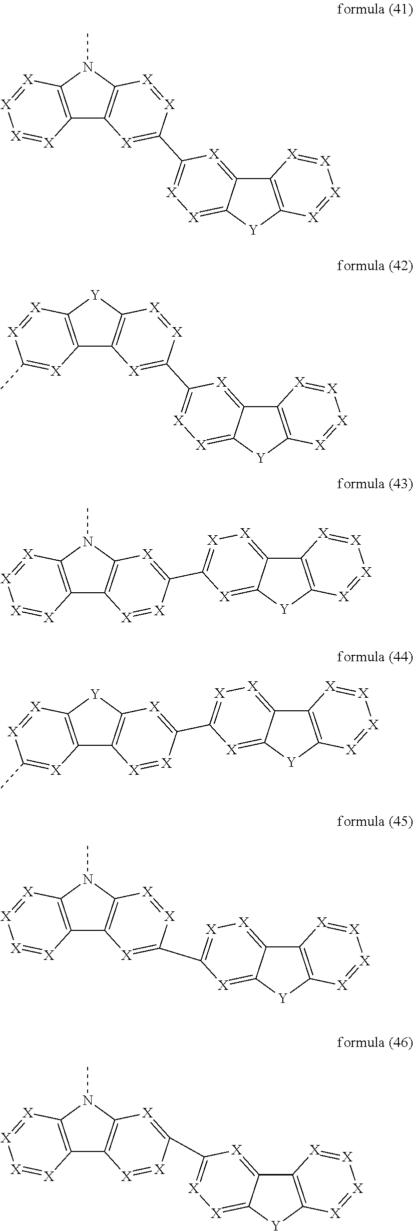

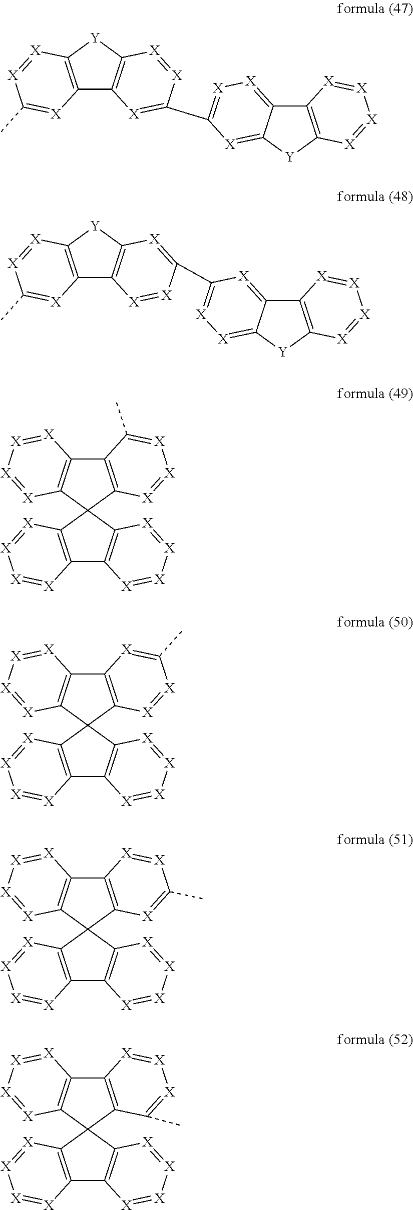

where R¹ and R² have the meanings given above, the dashed bond represents the bond to the group of the formula (8) or (9), and furthermore:
X is on each occurrence, identically or differently, CR¹ or N, where preferably a maximum of 2 symbols X per ring stand for N;
Y is on each occurrence, identically or differently, C(R¹)₂, NR¹, O or S;
n is 0 or 1, where n equals 0 means that no group Y is bonded at this position and instead radicals R¹ are bonded to the corresponding carbon atoms.

The term “ring”, as used in the definition of X and below, relates to each individual 5- or 6-membered ring within the structure.

In preferred groups of the above-mentioned formulae (10) to (52), a maximum of one symbol X per ring stands for N. The symbol X particularly preferably stands, identically or differently on each occurrence, for CR¹, in particular for CH.

If the groups of the formulae (10) to (52) contain a plurality of groups Y, all combinations from the definition of Y are suitable for this purpose. It is preferred in groups of the formulae (11) to (14) and (41) to (48) if Y stands, identically or differently on each occurrence, for NR¹, O or S. It is furthermore preferred in groups of the formulae (15) to (37) if Y stands, identically or differently on each occurrence, for NR¹, C(R¹)₂ or O. If the groups of the formulae (15) to (37) contain two groups Y, it is particularly preferred if one group Y stands for NR¹ and the other stands for C(R¹)₂ or if both groups Y stand for O or if both groups Y stand for NR¹. If the groups of the formulae (38) to (40) contain two groups Y, it is preferred if these stand, identically or differently, for C(R¹)₂ or NR¹, particularly preferably for C(R¹)₂.

If Y stands for NR¹, the substituent R¹ which is bonded directly to a nitrogen atom preferably stands for an aromatic or heteroaromatic ring system having 5 to 24 aromatic ring atoms, which may also be substituted by one or more radicals R². In a particularly preferred embodiment, this substituent R¹ stands, identically or differently on each occurrence, for an aromatic or heteroaromatic ring system having 6 to 24, preferably 6 to 18, particularly preferably 6 to 12 aromatic ring atoms which has no condensed aryl groups and which has no condensed heteroaryl groups in which two or more aromatic or heteroaromatic 6-membered ring groups are condensed directly onto one another and which may in each case also be substituted by one or more radicals R².

If Y stands for C(R¹)₂, R¹ preferably stands, identically or differently on each occurrence, for a linear alkyl group having 1 to 10 C atoms, preferably having 1 to 4 C atoms, or for a branched or cyclic alkyl group having 3 to 10 C atoms, preferably having 3 to 4 C atoms, or for an aromatic or heteroaromatic ring system having 6 to 24, m preferably 6 to 12 aromatic ring atoms, which may also be substituted by one or more radicals R². R¹ very particularly preferably stands for a methyl group or for a phenyl group, which may also be substituted by one or more radicals R², where a spiro system may also be formed by ring formation of the two phenyl groups.

Furthermore, it may be preferred for the group of the above-mentioned formulae (10) to (52) not to bond directly to the triazine in formula (1) or the pyrimidine in formula (9), but instead via a bridging group. This bridging group is then preferably selected from an aromatic or heteroaromatic ring system having 5 to 24 aromatic ring atoms, in particular having 6 to 12 aromatic ring atoms, which may in each case be substituted by one or more radicals R¹. The aromatic or heteroaromatic ring system here preferably contains no aryl or heteroaryl groups in which more than two aromatic six-membered rings are condensed onto one another. The aromatic or heteroaromatic ring system particularly preferably contains no aryl or heteroaryl groups in which aromatic six-membered rings are condensed onto one another. Preferred bridging groups of this type are selected from phenylene, in particular ortho-, meta- or para-phenylene, or biphenyl, each of which may be substituted by one or more radicals R¹, where unsubstituted meta-phenylene is particularly preferred.

Examples of preferred compounds of the formula (8) or (9) are the compounds shown in the following table.

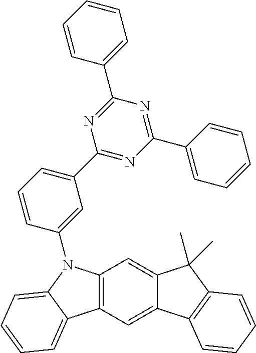 [SMILES: CC1(C)c2ccccc2-c2cc3c4ccccc4n(-c4cccc(-c5nc(-c6ccccc6)nc(-c6ccccc6)n5)c4)c3cc21]

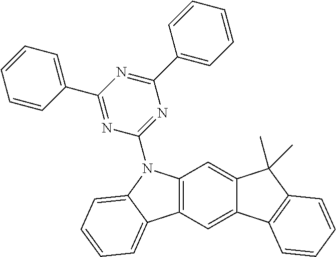 [SMILES: CC1(C)c2ccccc2-c2cc3c4ccccc4n(-c4nc(-c5ccccc5)nc(-c5ccccc5)n4)c3cc21]

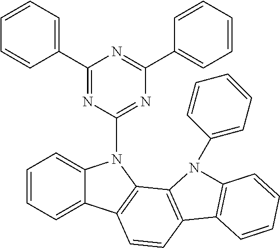 [SMILES: c1ccc(-c2nc(-c3ccccc3)nc(-n3c4ccccc4c4ccc5c6ccccc6n(-c6ccccc6)c5c43)n2)cc1]

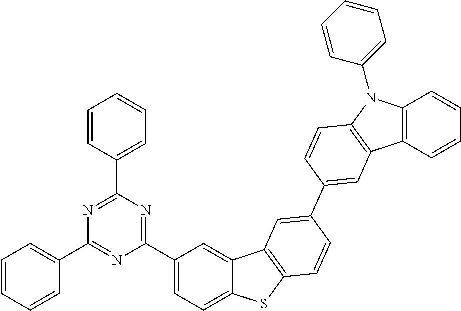 [SMILES: c1ccc(-c2nc(-c3ccccc3)nc(-c3ccc4sc5ccc(-c6ccc7c(c6)c6ccccc6n7-c6ccccc6)cc5c4c3)n2)cc1]

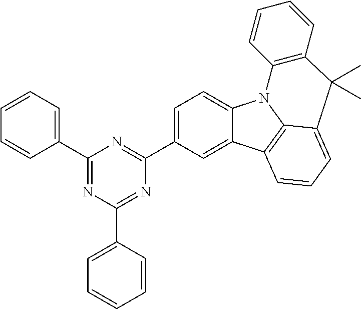 [SMILES: CC1(C)c2ccccc2-n2c3ccc(-c4nc(-c5ccccc5)nc(-c5ccccc5)n4)cc3c3cccc1c32]

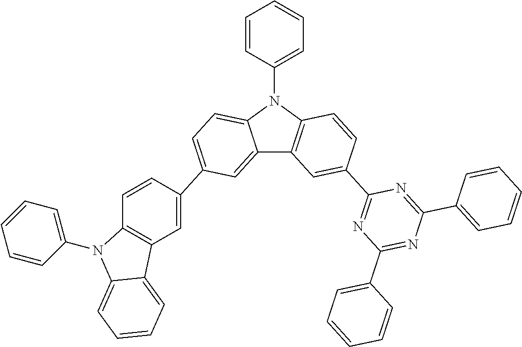 [SMILES: c1ccc(-c2nc(-c3ccccc3)nc(-c3ccc4c(c3)c3cc(-c5ccc6c(c5)c5ccccc5n6-c5ccccc5)ccc3n4-c3ccccc3)n2)cc1]

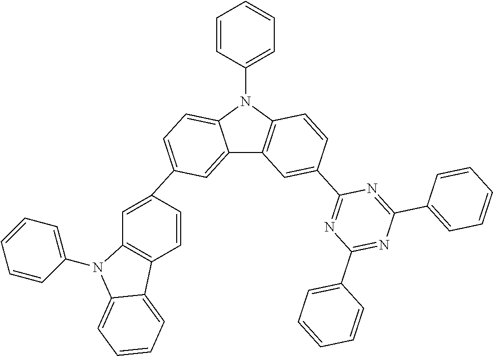 [SMILES: c1ccc(-c2nc(-c3ccccc3)nc(-c3ccc4c(c3)c3cc(-c5ccc6c7ccccc7n(-c7ccccc7)c6c5)ccc3n4-c3ccccc3)n2)cc1]

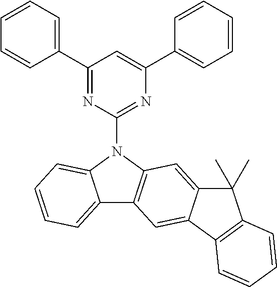 [SMILES: CC1(C)c2ccccc2-c2cc3c4ccccc4n(-c4nc(-c5ccccc5)cc(-c5ccccc5)n4)c3cc21]

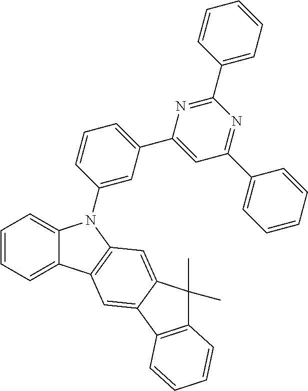 [SMILES: CC1(C)c2ccccc2-c2cc3c4ccccc4n(-c4cccc(-c5cc(-c6ccccc6)nc(-c6ccccc6)n5)c4)c3cc21]

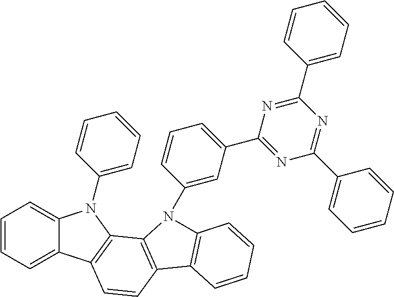 [SMILES: c1ccc(-c2nc(-c3ccccc3)nc(-c3cccc(-n4c5ccccc5c5ccc6c7ccccc7n(-c7ccccc7)c6c54)c3)n2)cc1]

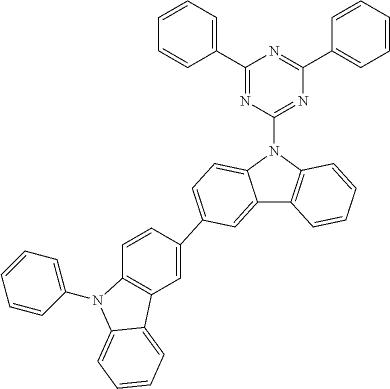 [SMILES: c1ccc(-c2nc(-c3ccccc3)nc(-n3c4ccccc4c4cc(-c5ccc6c(c5)c5ccccc5n6-c5ccccc5)ccc43)n2)cc1]

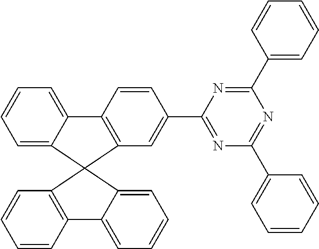 [SMILES: c1ccc(-c2nc(-c3ccccc3)nc(-c3ccc4c(c3)C3(c5ccccc5-c5ccccc53)c3ccccc3-4)n2)cc1]

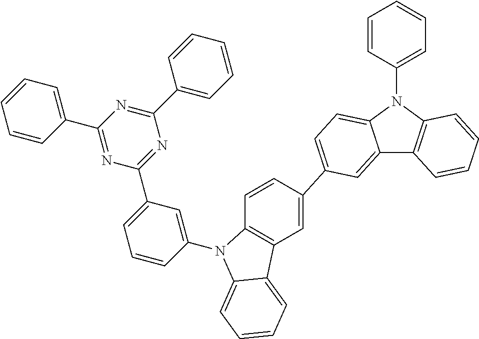 [SMILES: c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1]

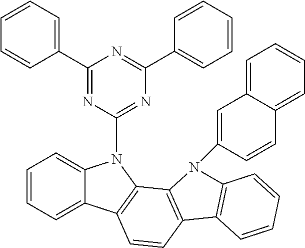 [SMILES: c1ccc(-c2nc(-c3ccccc3)nc(-n3c4ccccc4c4ccc5c6ccccc6n(-c6ccc7ccccc7c6)c5c43)n2)cc1]

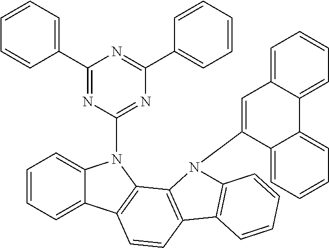 [SMILES: c1ccc(-c2nc(-c3ccccc3)nc(-n3c4ccccc4c4ccc5c6ccccc6n(-c6cc7ccccc7c7ccccc67)c5c43)n2)cc1]

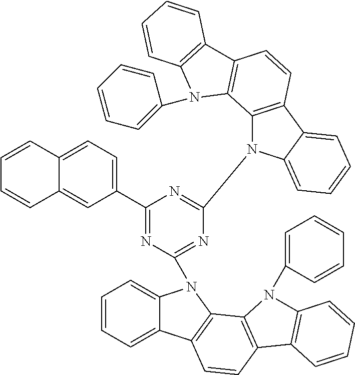 [SMILES: c1ccc(-n2c3ccccc3c3ccc4c5ccccc5n(-c5nc(-c6ccc7ccccc7c6)nc(-n6c7ccccc7c7ccc8c9ccccc9n(-c9ccccc9)c8c76)n5)c4c32)cc1]

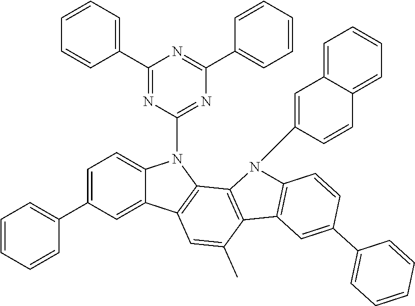 [SMILES: Cc1cc2c3cc(-c4ccccc4)ccc3n(-c3nc(-c4ccccc4)nc(-c4ccccc4)n3)c2c2c1c1cc(-c3ccccc3)ccc1n2-c1ccc2ccccc2c1]

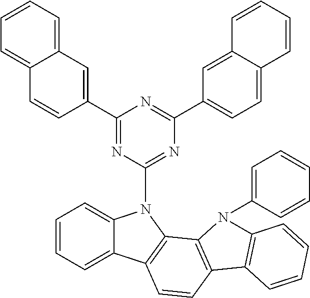 [SMILES: c1ccc(-n2c3ccccc3c3ccc4c5ccccc5n(-c5nc(-c6ccc7ccccc7c6)nc(-c6ccc7ccccc7c6)n5)c4c32)cc1]

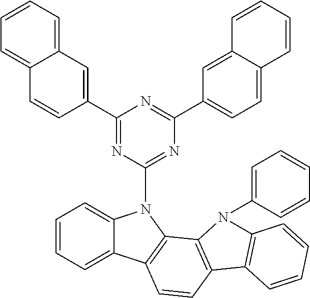 [SMILES: c1ccc(-n2c3ccccc3c3ccc4c5ccccc5n(-c5nc(-c6ccc7ccccc7c6)nc(-c6ccc7ccccc7c6)n5)c4c32)cc1]

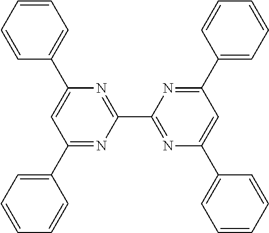 [SMILES: c1ccc(-c2cc(-c3ccccc3)nc(-c3nc(-c4ccccc4)cc(-c4ccccc4)n3)n2)cc1]

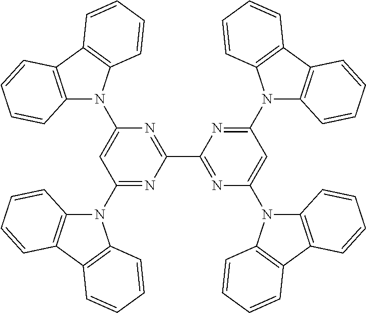 [SMILES: c1ccc2c(c1)c1ccccc1n2-c1cc(-n2c3ccccc3c3ccccc32)nc(-c2nc(-n3c4ccccc4c4ccccc43)cc(-n3c4ccccc4c4ccccc43)n2)n1]

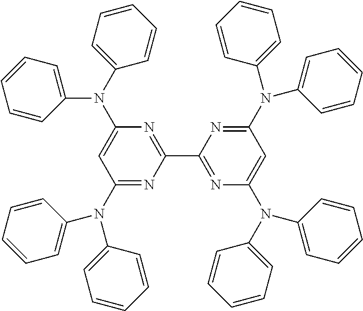 [SMILES: c1ccc(N(c2ccccc2)c2cc(N(c3ccccc3)c3ccccc3)nc(-c3nc(N(c4ccccc4)c4ccccc4)cc(N(c4ccccc4)c4ccccc4)n3)n2)cc1]

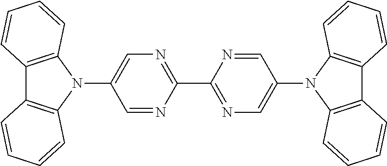 [SMILES: c1ccc2c(c1)c1ccccc1n2-c1cnc(-c2ncc(-n3c4ccccc4c4ccccc43)cn2)nc1]

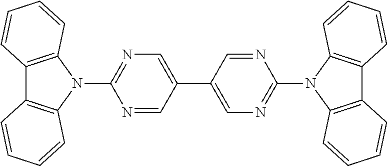 [SMILES: c1ccc2c(c1)c1ccccc1n2-c1ncc(-c2cnc(-n3c4ccccc4c4ccccc43)nc2)cn1]

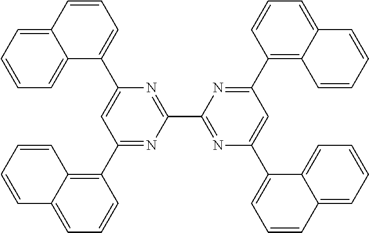 [SMILES: c1ccc2c(-c3cc(-c4cccc5ccccc45)nc(-c4nc(-c5cccc6ccccc56)cc(-c5cccc6ccccc56)n4)n3)cccc2c1]

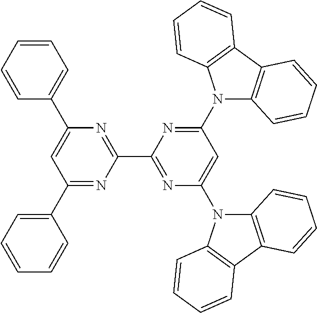 [SMILES: c1ccc(-c2cc(-c3ccccc3)nc(-c3nc(-n4c5ccccc5c5ccccc54)cc(-n4c5ccccc5c5ccccc54)n3)n2)cc1]

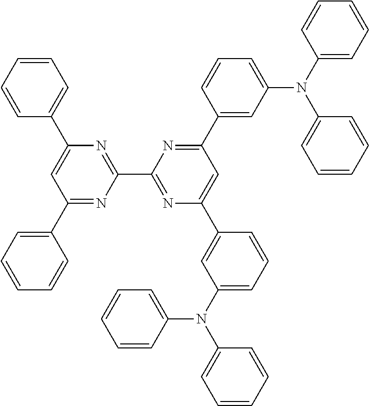 [SMILES: c1ccc(-c2cc(-c3ccccc3)nc(-c3nc(-c4cccc(N(c5ccccc5)c5ccccc5)c4)cc(-c4cccc(N(c5ccccc5)c5ccccc5)c4)n3)n2)cc1]

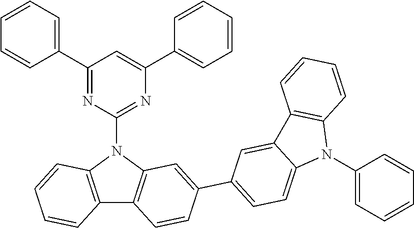 [SMILES: c1ccc(-c2cc(-c3ccccc3)nc(-n3c4ccccc4c4ccc(-c5ccc6c(c5)c5ccccc5n6-c5ccccc5)cc43)n2)cc1]

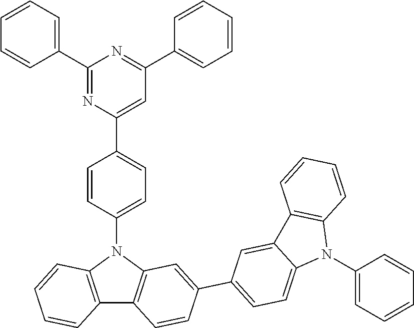 [SMILES: c1ccc(-c2cc(-c3ccc(-n4c5ccccc5c5ccc(-c6ccc7c(c6)c6ccccc6n7-c6ccccc6)cc54)cc3)nc(-c3ccccc3)n2)cc1]

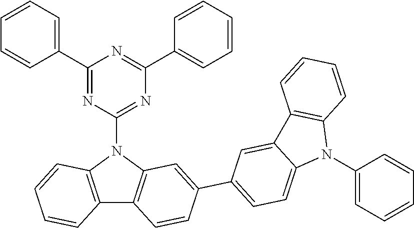 [SMILES: c1ccc(-c2nc(-c3ccccc3)nc(-n3c4ccccc4c4ccc(-c5ccc6c(c5)c5ccccc5n6-c5ccccc5)cc43)n2)cc1]

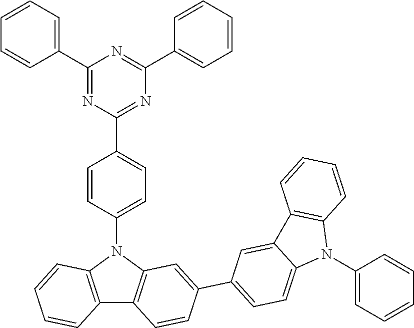 [SMILES: c1ccc(-c2nc(-c3ccccc3)nc(-c3ccc(-n4c5ccccc5c5ccc(-c6ccc7c(c6)c6ccccc6n7-c6ccccc6)cc54)cc3)n2)cc1]

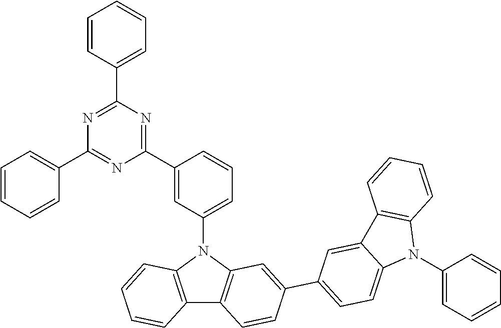 [SMILES: c1ccc(-c2nc(-c3ccccc3)nc(-c3cccc(-n4c5ccccc5c5ccc(-c6ccc7c(c6)c6ccccc6n7-c6ccccc6)cc54)c3)n2)cc1]

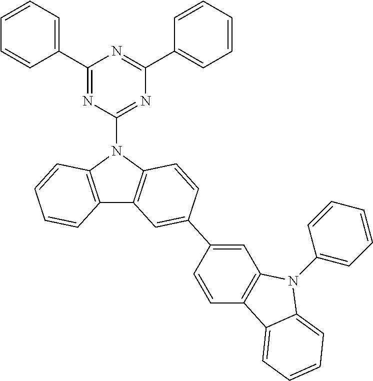 [SMILES: c1ccc(-c2nc(-c3ccccc3)nc(-n3c4ccccc4c4cc(-c5ccc6c7ccccc7n(-c7ccccc7)c6c5)ccc43)n2)cc1]

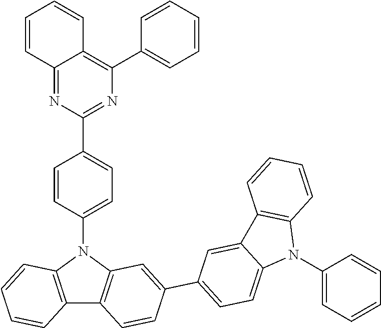 [SMILES: c1ccc(-c2nc(-c3ccc(-n4c5ccccc5c5ccc(-c6ccc7c(c6)c6ccccc6n7-c6ccccc6)cc54)cc3)nc3ccccc23)cc1]

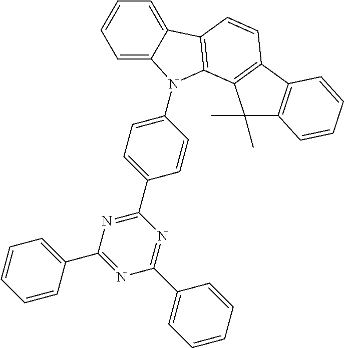 [SMILES: CC1(C)c2ccccc2-c2ccc3c4ccccc4n(-c4ccc(-c5nc(-c6ccccc6)nc(-c6ccccc6)n5)cc4)c3c21]

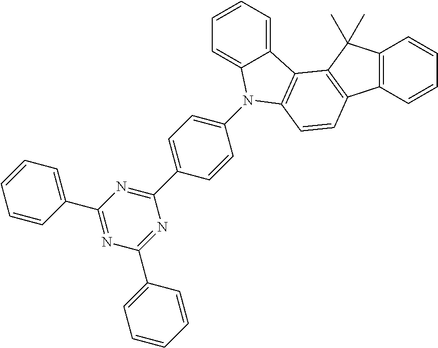 [SMILES: CC1(C)c2ccccc2-c2ccc3c(c21)c1ccccc1n3-c1ccc(-c2nc(-c3ccccc3)nc(-c3ccccc3)n2)cc1]

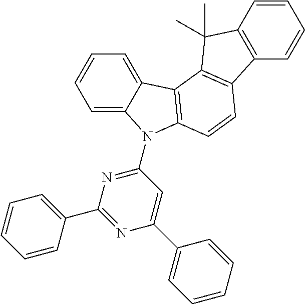 [SMILES: CC1(C)c2ccccc2-c2ccc3c(c21)c1ccccc1n3-c1cc(-c2ccccc2)nc(-c2ccccc2)n1]

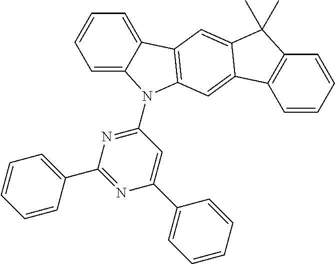 [SMILES: CC1(C)c2ccccc2-c2cc3c(cc21)c1ccccc1n3-c1cc(-c2ccccc2)nc(-c2ccccc2)n1]

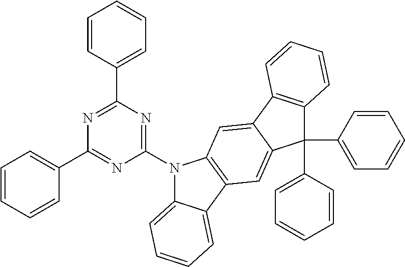 [SMILES: c1ccc(-c2nc(-c3ccccc3)nc(-n3c4ccccc4c4cc5c(cc43)-c3ccccc3C5(c3ccccc3)c3ccccc3)n2)cc1]

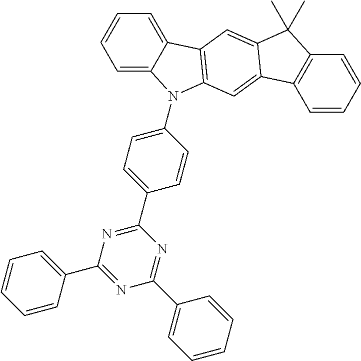 [SMILES: CC1(C)c2ccccc2-c2cc3c(cc21)c1ccccc1n3-c1ccc(-c2nc(-c3ccccc3)nc(-c3ccccc3)n2)cc1]

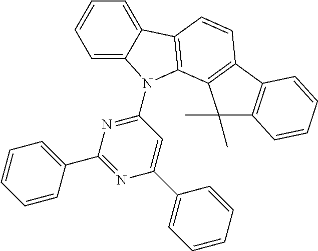 [SMILES: CC1(C)c2ccccc2-c2ccc3c4ccccc4n(-c4cc(-c5ccccc5)nc(-c5ccccc5)n4)c3c21]

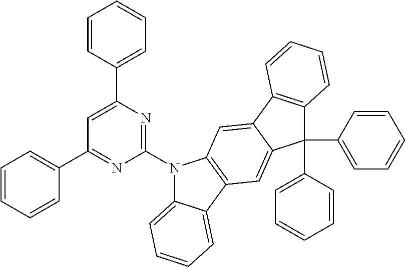 [SMILES: c1ccc(-c2cc(-c3ccccc3)nc(-n3c4ccccc4c4cc5c(cc43)-c3ccccc3C5(c3ccccc3)c3ccccc3)n2)cc1]

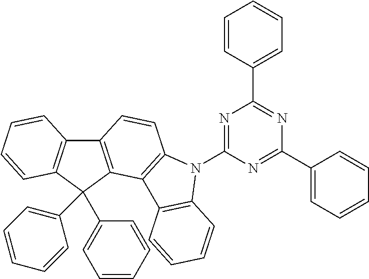 [SMILES: c1ccc(-c2nc(-c3ccccc3)nc(-n3c4ccccc4c4c5c(ccc43)-c3ccccc3C5(c3ccccc3)c3ccccc3)n2)cc1]

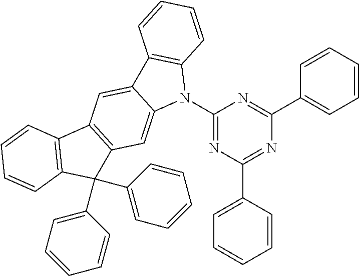 [SMILES: c1ccc(-c2nc(-c3ccccc3)nc(-n3c4ccccc4c4cc5c(cc43)C(c3ccccc3)(c3ccccc3)c3ccccc3-5)n2)cc1]

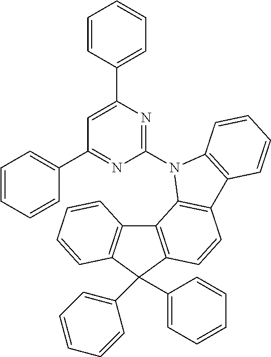 [SMILES: c1ccc(-c2cc(-c3ccccc3)nc(-n3c4ccccc4c4ccc5c(c43)-c3ccccc3C5(c3ccccc3)c3ccccc3)n2)cc1]

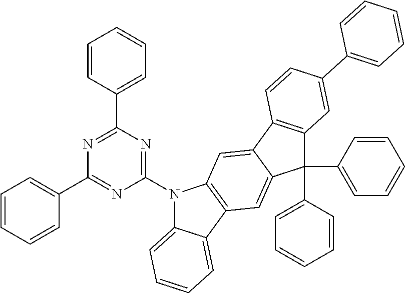 [SMILES: c1ccc(-c2ccc3c(c2)C(c2ccccc2)(c2ccccc2)c2cc4c5ccccc5n(-c5nc(-c6ccccc6)nc(-c6ccccc6)n5)c4cc2-3)cc1]

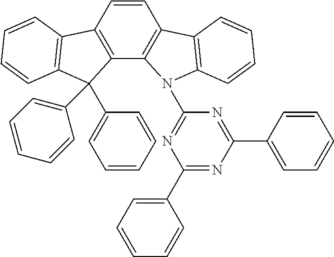 [SMILES: c1ccc(-c2nc(-c3ccccc3)nc(-n3c4ccccc4c4ccc5c(c43)C(c3ccccc3)(c3ccccc3)c3ccccc3-5)n2)cc1]

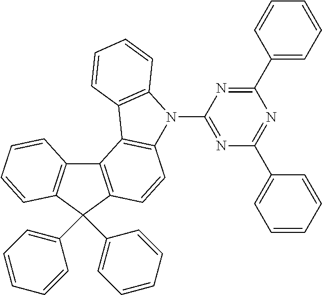 [SMILES: c1ccc(-c2nc(-c3ccccc3)nc(-n3c4ccccc4c4c5c(ccc43)C(c3ccccc3)(c3ccccc3)c3ccccc3-5)n2)cc1]

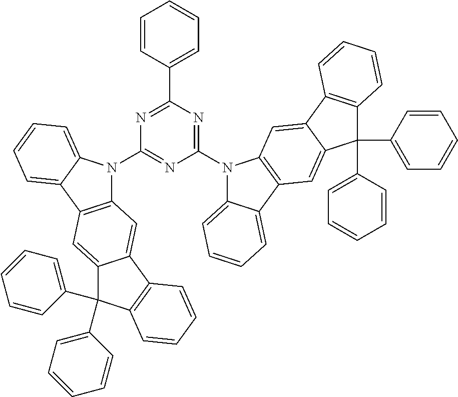 [SMILES: c1ccc(-c2nc(-n3c4ccccc4c4cc5c(cc43)-c3ccccc3C5(c3ccccc3)c3ccccc3)nc(-n3c4ccccc4c4cc5c(cc43)-c3ccccc3C5(c3ccccc3)c3ccccc3)n2)cc1]

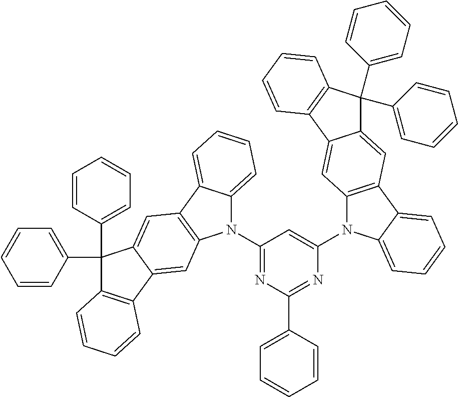 [SMILES: c1ccc(-c2nc(-n3c4ccccc4c4cc5c(cc43)-c3ccccc3C5(c3ccccc3)c3ccccc3)cc(-n3c4ccccc4c4cc5c(cc43)-c3ccccc3C5(c3ccccc3)c3ccccc3)n2)cc1]

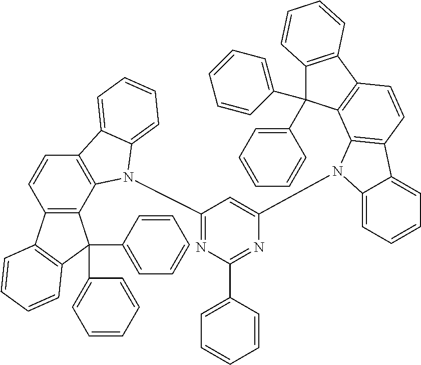 [SMILES: c1ccc(-c2nc(-n3c4ccccc4c4ccc5c(c43)C(c3ccccc3)(c3ccccc3)c3ccccc3-5)cc(-n3c4ccccc4c4ccc5c(c43)C(c3ccccc3)(c3ccccc3)c3ccccc3-5)n2)cc1]

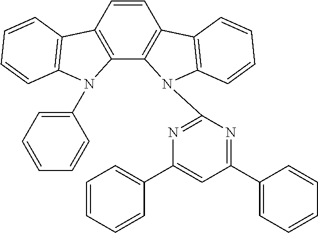 [SMILES: c1ccc(-c2cc(-c3ccccc3)nc(-n3c4ccccc4c4ccc5c6ccccc6n(-c6ccccc6)c5c43)n2)cc1]

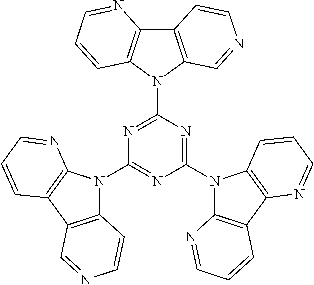 [SMILES: c1cnc2c(c1)c1cnccc1n2-c1nc(-n2c3cnccc3c3ncccc32)nc(-n2c3cccnc3c3cccnc32)n1]

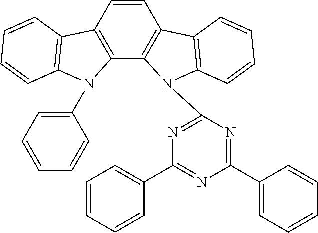 [SMILES: c1ccc(-c2nc(-c3ccccc3)nc(-n3c4ccccc4c4ccc5c6ccccc6n(-c6ccccc6)c5c43)n2)cc1]

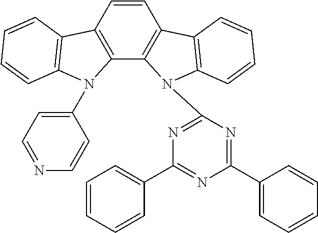 [SMILES: c1ccc(-c2nc(-c3ccccc3)nc(-n3c4ccccc4c4ccc5c6ccccc6n(-c6ccncc6)c5c43)n2)cc1]

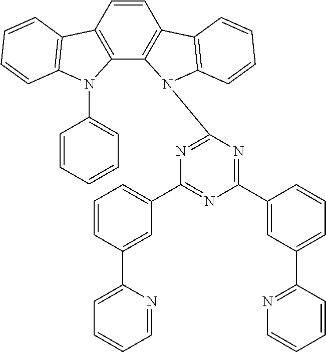 [SMILES: c1ccc(-n2c3ccccc3c3ccc4c5ccccc5n(-c5nc(-c6cccc(-c7ccccn7)c6)nc(-c6cccc(-c7ccccn7)c6)n5)c4c32)cc1]

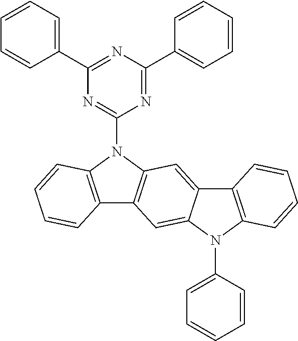 [SMILES: c1ccc(-c2nc(-c3ccccc3)nc(-n3c4ccccc4c4cc5c(cc43)c3ccccc3n5-c3ccccc3)n2)cc1]

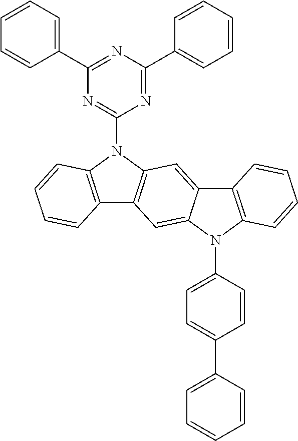 [SMILES: c1ccc(-c2ccc(-n3c4ccccc4c4cc5c(cc43)c3ccccc3n5-c3nc(-c4ccccc4)nc(-c4ccccc4)n3)cc2)cc1]

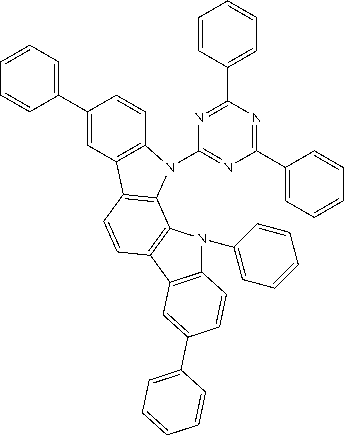 [SMILES: c1ccc(-c2ccc3c(c2)c2ccc4c5cc(-c6ccccc6)ccc5n(-c5nc(-c6ccccc6)nc(-c6ccccc6)n5)c4c2n3-c2ccccc2)cc1]

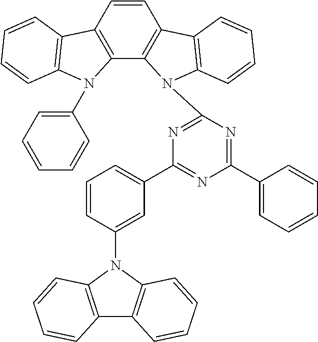 [SMILES: c1ccc(-c2nc(-c3cccc(-n4c5ccccc5c5ccccc54)c3)nc(-n3c4ccccc4c4ccc5c6ccccc6n(-c6ccccc6)c5c43)n2)cc1]

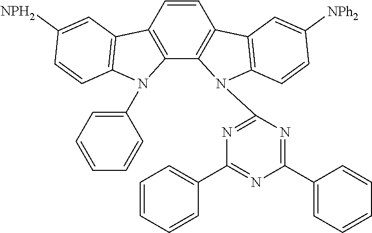

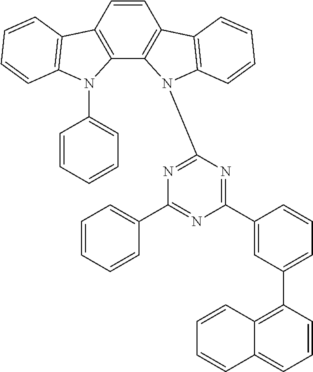 [SMILES: c1ccc(-c2nc(-c3cccc(-c4cccc5ccccc45)c3)nc(-n3c4ccccc4c4ccc5c6ccccc6n(-c6ccccc6)c5c43)n2)cc1]

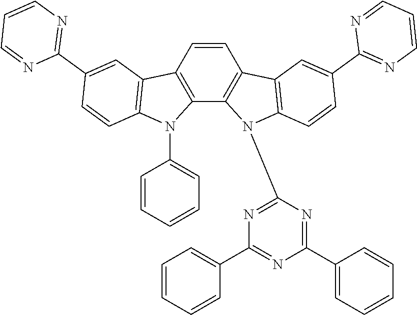 [SMILES: c1ccc(-c2nc(-c3ccccc3)nc(-n3c4ccc(-c5ncccn5)cc4c4ccc5c6cc(-c7ncccn7)ccc6n(-c6ccccc6)c5c43)n2)cc1]

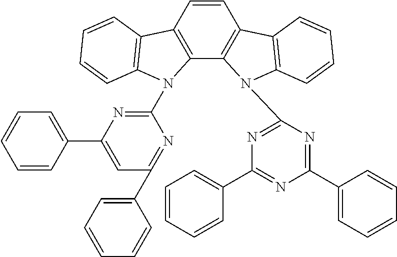 [SMILES: c1ccc(-c2cc(-c3ccccc3)nc(-n3c4ccccc4c4ccc5c6ccccc6n(-c6nc(-c7ccccc7)nc(-c7ccccc7)n6)c5c43)n2)cc1]

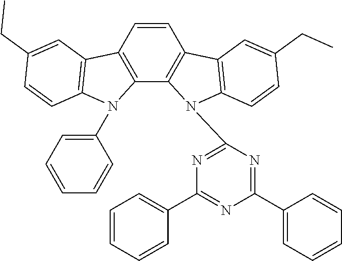 [SMILES: CCc1ccc2c(c1)c1ccc3c4cc(CC)ccc4n(-c4nc(-c5ccccc5)nc(-c5ccccc5)n4)c3c1n2-c1ccccc1]

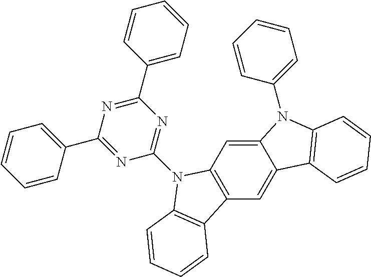 [SMILES: c1ccc(-c2nc(-c3ccccc3)nc(-n3c4ccccc4c4cc5c6ccccc6n(-c6ccccc6)c5cc43)n2)cc1]

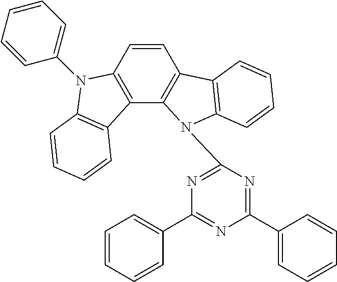 [SMILES: c1ccc(-c2nc(-c3ccccc3)nc(-n3c4ccccc4c4ccc5c(c6ccccc6n5-c5ccccc5)c43)n2)cc1]

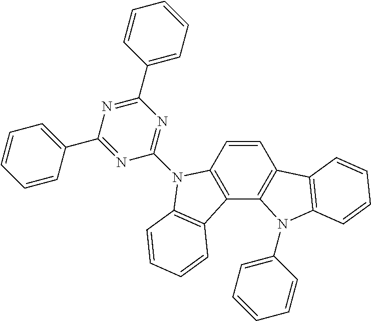 [SMILES: c1ccc(-c2nc(-c3ccccc3)nc(-n3c4ccccc4c4c3ccc3c5ccccc5n(-c5ccccc5)c34)n2)cc1]

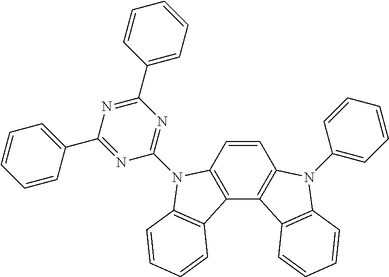 [SMILES: c1ccc(-c2nc(-c3ccccc3)nc(-n3c4ccccc4c4c5c6ccccc6n(-c6ccccc6)c5ccc43)n2)cc1]

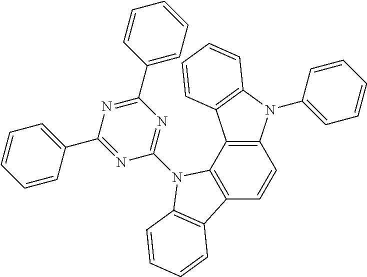 [SMILES: c1ccc(-c2nc(-c3ccccc3)nc(-n3c4ccccc4c4ccc5c(c6ccccc6n5-c5ccccc5)c43)n2)cc1]

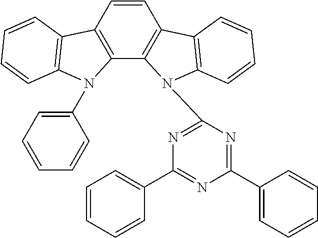 [SMILES: c1ccc(-c2nc(-c3ccccc3)nc(-n3c4ccccc4c4ccc5c6ccccc6n(-c6ccccc6)c5c43)n2)cc1]

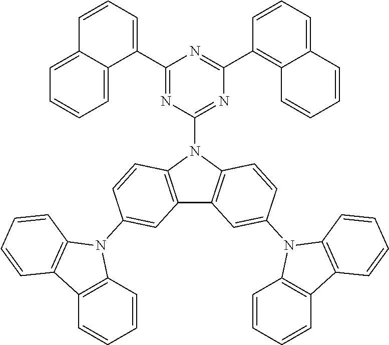 [SMILES: c1ccc2c(-c3nc(-c4cccc5ccccc45)nc(-n4c5ccc(-n6c7ccccc7c7ccccc76)cc5c5cc(-n6c7ccccc7c7ccccc76)ccc54)n3)cccc2c1]

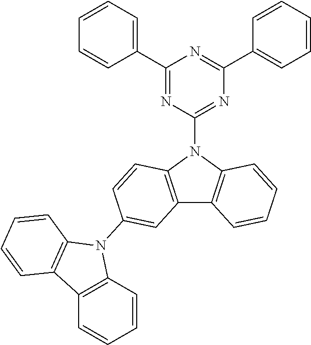 [SMILES: c1ccc(-c2nc(-c3ccccc3)nc(-n3c4ccccc4c4cc(-n5c6ccccc6c6ccccc65)ccc43)n2)cc1]

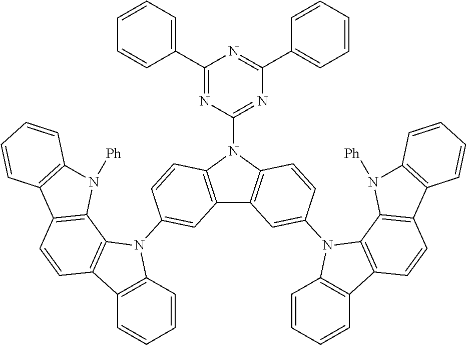 [SMILES: c1ccc(-c2nc(-c3ccccc3)nc(-n3c4ccc(-n5c6ccccc6c6ccc7c8ccccc8n(-c8ccccc8)c7c65)cc4c4cc(-n5c6ccccc6c6ccc7c8ccccc8n(-c8ccccc8)c7c65)ccc43)n2)cc1]

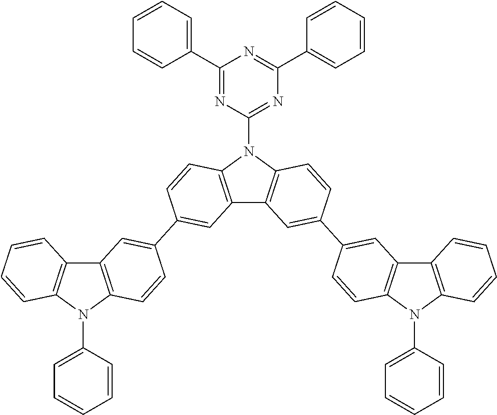 [SMILES: c1ccc(-c2nc(-c3ccccc3)nc(-n3c4ccc(-c5ccc6c(c5)c5ccccc5n6-c5ccccc5)cc4c4cc(-c5ccc6c(c5)c5ccccc5n6-c5ccccc5)ccc43)n2)cc1]

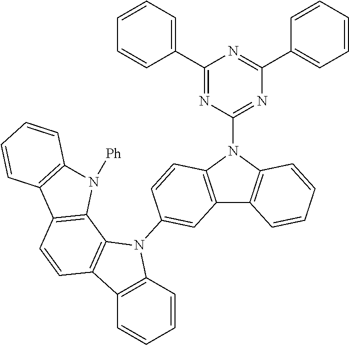 [SMILES: c1ccc(-c2nc(-c3ccccc3)nc(-n3c4ccccc4c4cc(-n5c6ccccc6c6ccc7c8ccccc8n(-c8ccccc8)c7c65)ccc43)n2)cc1]

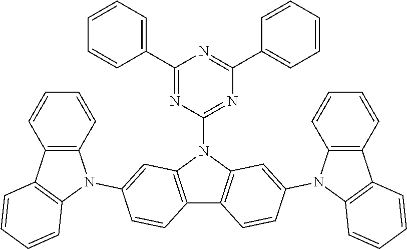 [SMILES: c1ccc(-c2nc(-c3ccccc3)nc(-n3c4cc(-n5c6ccccc6c6ccccc65)ccc4c4ccc(-n5c6ccccc6c6ccccc65)cc43)n2)cc1]

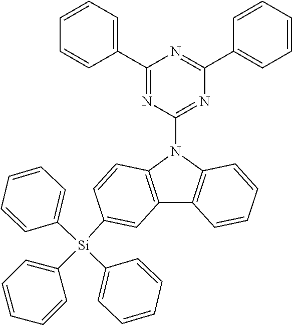 [SMILES: c1ccc(-c2nc(-c3ccccc3)nc(-n3c4ccccc4c4cc([Si](c5ccccc5)(c5ccccc5)c5ccccc5)ccc43)n2)cc1]

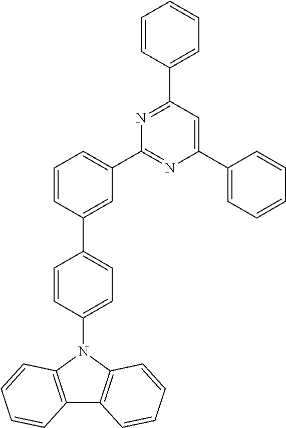 [SMILES: c1ccc(-c2cc(-c3ccccc3)nc(-c3cccc(-c4ccc(-n5c6ccccc6c6ccccc65)cc4)c3)n2)cc1]

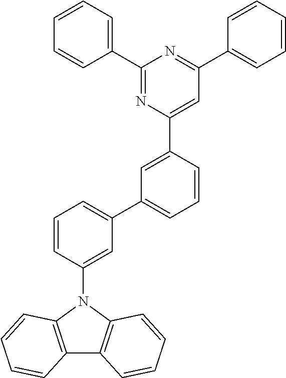 [SMILES: c1ccc(-c2cc(-c3cccc(-c4cccc(-n5c6ccccc6c6ccccc65)c4)c3)nc(-c3ccccc3)n2)cc1]

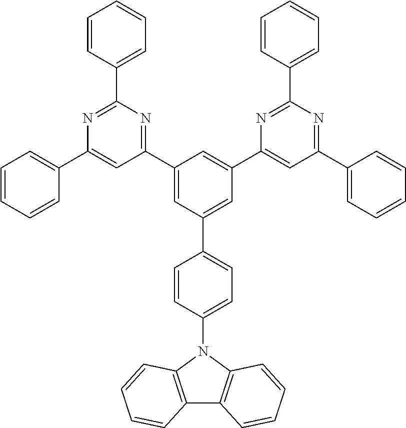 [SMILES: c1ccc(-c2cc(-c3cc(-c4ccc(-n5c6ccccc6c6ccccc65)cc4)cc(-c4cc(-c5ccccc5)nc(-c5ccccc5)n4)c3)nc(-c3ccccc3)n2)cc1]

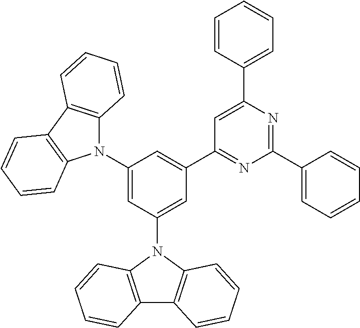 [SMILES: c1ccc(-c2cc(-c3cc(-n4c5ccccc5c5ccccc54)cc(-n4c5ccccc5c5ccccc54)c3)nc(-c3ccccc3)n2)cc1]

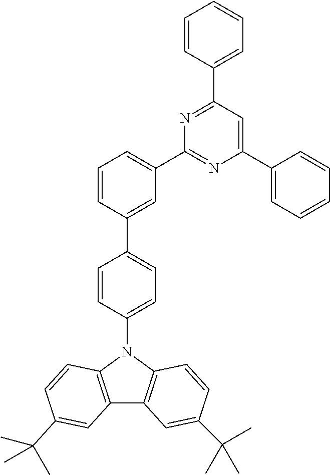 [SMILES: CC(C)(C)c1ccc2c(c1)c1cc(C(C)(C)C)ccc1n2-c1ccc(-c2cccc(-c3nc(-c4ccccc4)cc(-c4ccccc4)n3)c2)cc1]

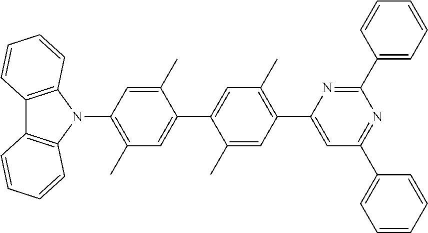 [SMILES: Cc1cc(-c2cc(C)c(-n3c4ccccc4c4ccccc43)cc2C)c(C)cc1-c1cc(-c2ccccc2)nc(-c2ccccc2)n1]

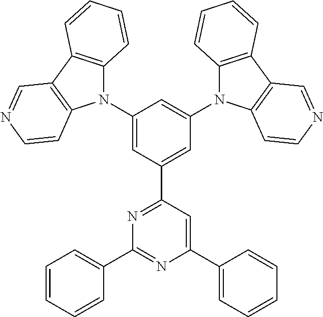 [SMILES: c1ccc(-c2cc(-c3cc(-n4c5ccccc5c5cnccc54)cc(-n4c5ccccc5c5cnccc54)c3)nc(-c3ccccc3)n2)cc1]

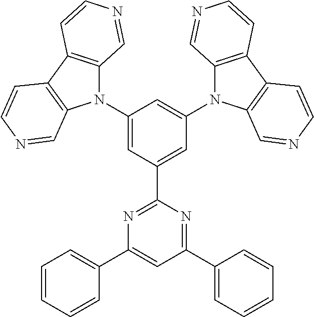 [SMILES: c1ccc(-c2cc(-c3ccccc3)nc(-c3cc(-n4c5cnccc5c5ccncc54)cc(-n4c5cnccc5c5ccncc54)c3)n2)cc1]

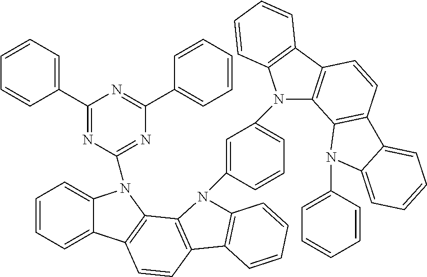 [SMILES: c1ccc(-c2nc(-c3ccccc3)nc(-n3c4ccccc4c4ccc5c6ccccc6n(-c6cccc(-n7c8ccccc8c8ccc9c%10ccccc%10n(-c%10ccccc%10)c9c87)c6)c5c43)n2)cc1]

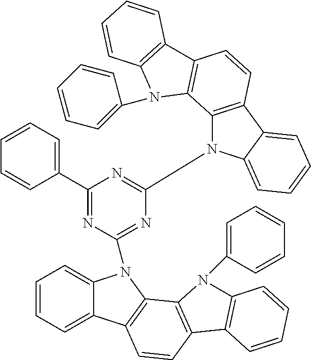 [SMILES: c1ccc(-c2nc(-n3c4ccccc4c4ccc5c6ccccc6n(-c6ccccc6)c5c43)nc(-n3c4ccccc4c4ccc5c6ccccc6n(-c6ccccc6)c5c43)n2)cc1]

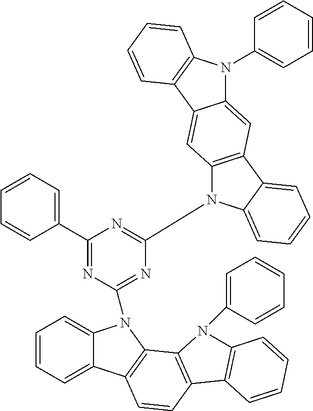 [SMILES: c1ccc(-c2nc(-n3c4ccccc4c4cc5c(cc43)c3ccccc3n5-c3ccccc3)nc(-n3c4ccccc4c4ccc5c6ccccc6n(-c6ccccc6)c5c43)n2)cc1]

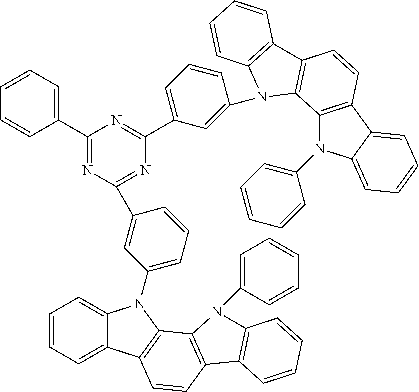 [SMILES: c1ccc(-c2nc(-c3cccc(-n4c5ccccc5c5ccc6c7ccccc7n(-c7ccccc7)c6c54)c3)nc(-c3cccc(-n4c5ccccc5c5ccc6c7ccccc7n(-c7ccccc7)c6c54)c3)n2)cc1]

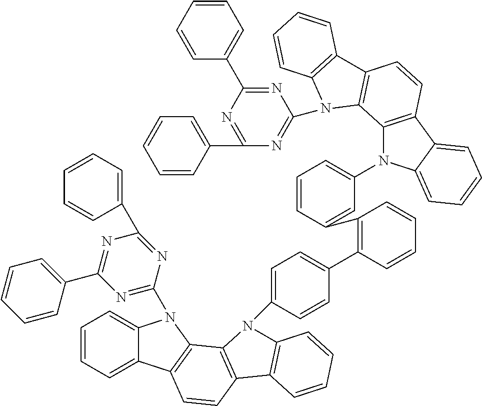 [SMILES: c1ccc(-c2nc(-c3ccccc3)nc(-n3c4ccccc4c4ccc5c6ccccc6n(-c6ccc(-c7ccccc7-c7cccc(-n8c9ccccc9c9ccc%10c%11ccccc%11n(-c%11nc(-c%12ccccc%12)nc(-c%12ccccc%12)n%11)c%10c98)c7)cc6)c5c43)n2)cc1]

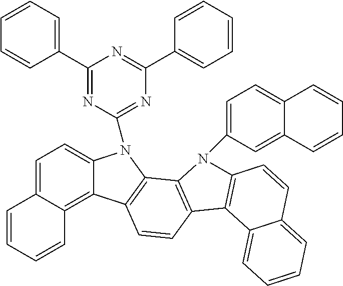 [SMILES: c1ccc(-c2nc(-c3ccccc3)nc(-n3c4ccc5ccccc5c4c4ccc5c6c7ccccc7ccc6n(-c6ccc7ccccc7c6)c5c43)n2)cc1]

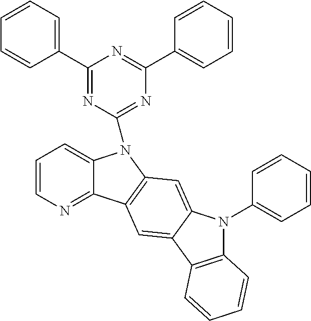 [SMILES: c1ccc(-c2nc(-c3ccccc3)nc(-n3c4cc5c(cc4c4ncccc43)c3ccccc3n5-c3ccccc3)n2)cc1]

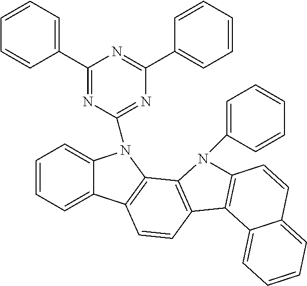 [SMILES: c1ccc(-c2nc(-c3ccccc3)nc(-n3c4ccccc4c4ccc5c6c7ccccc7ccc6n(-c6ccccc6)c5c43)n2)cc1]

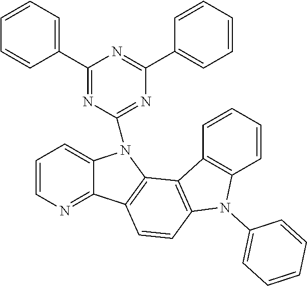 [SMILES: c1ccc(-c2nc(-c3ccccc3)nc(-n3c4cccnc4c4ccc5c(c6ccccc6n5-c5ccccc5)c43)n2)cc1]

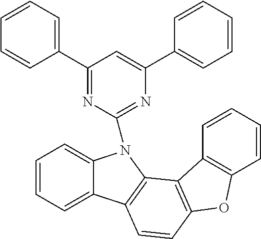 [SMILES: c1ccc(-c2cc(-c3ccccc3)nc(-n3c4ccccc4c4ccc5oc6ccccc6c5c43)n2)cc1]

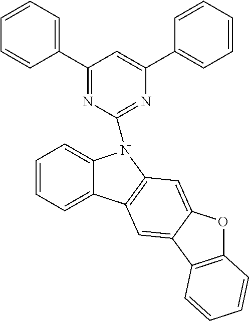 [SMILES: c1ccc(-c2cc(-c3ccccc3)nc(-n3c4ccccc4c4cc5c(cc43)oc3ccccc35)n2)cc1]

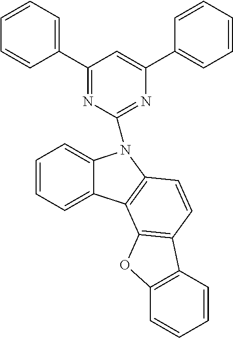 [SMILES: c1ccc(-c2cc(-c3ccccc3)nc(-n3c4ccccc4c4c5oc6ccccc6c5ccc43)n2)cc1]

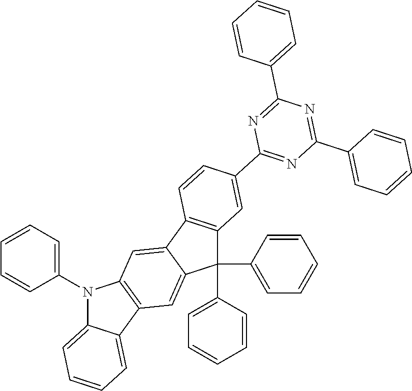 [SMILES: c1ccc(-c2nc(-c3ccccc3)nc(-c3ccc4c(c3)C(c3ccccc3)(c3ccccc3)c3cc5c6ccccc6n(-c6ccccc6)c5cc3-4)n2)cc1]

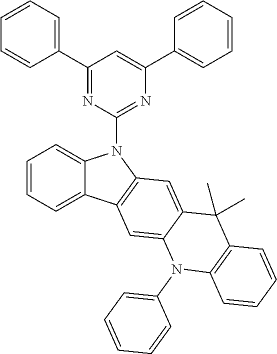 [SMILES: CC1(C)c2ccccc2N(c2ccccc2)c2cc3c4ccccc4n(-c4nc(-c5ccccc5)cc(-c5ccccc5)n4)c3cc21]

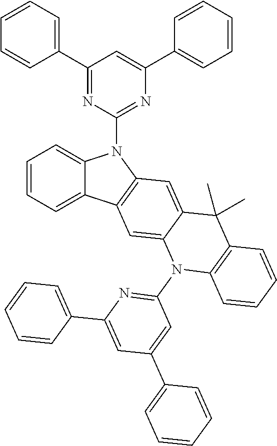 [SMILES: CC1(C)c2ccccc2N(c2cc(-c3ccccc3)cc(-c3ccccc3)n2)c2cc3c4ccccc4n(-c4nc(-c5ccccc5)cc(-c5ccccc5)n4)c3cc21]

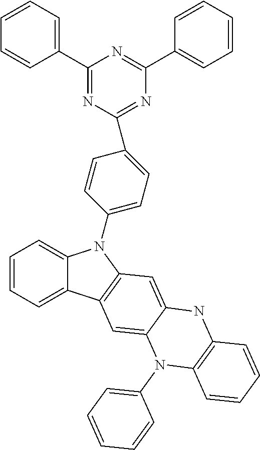 [SMILES: c1ccc(-c2nc(-c3ccccc3)nc(-c3ccc(-n4c5ccccc5c5cc6c(cc54)Nc4ccccc4N6c4ccccc4)cc3)n2)cc1]

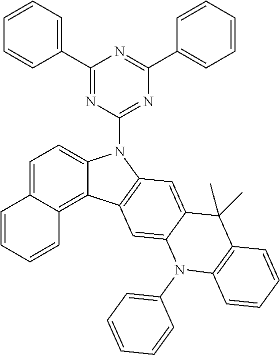 [SMILES: CC1(C)c2ccccc2N(c2ccccc2)c2cc3c4c5ccccc5ccc4n(-c4nc(-c5ccccc5)nc(-c5ccccc5)n4)c3cc21]

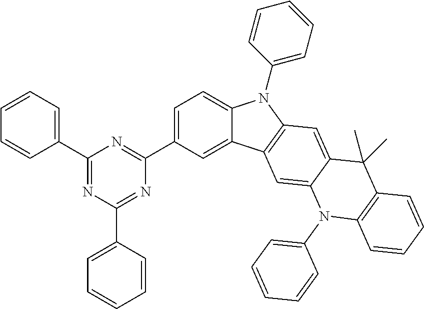 [SMILES: CC1(C)c2ccccc2N(c2ccccc2)c2cc3c4cc(-c5nc(-c6ccccc6)nc(-c6ccccc6)n5)ccc4n(-c4ccccc4)c3cc21]

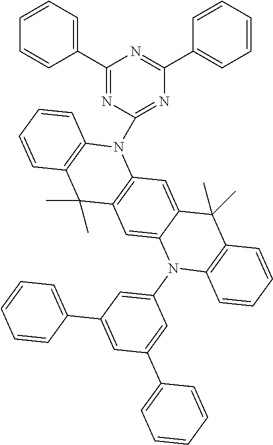 [SMILES: CC1(C)c2ccccc2N(c2cc(-c3ccccc3)cc(-c3ccccc3)c2)c2cc3c(cc21)N(c1nc(-c2ccccc2)nc(-c2ccccc2)n1)c1ccccc1C3(C)C]

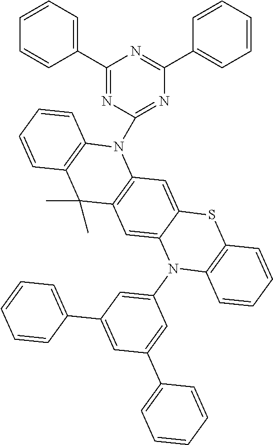 [SMILES: CC1(C)c2ccccc2N(c2nc(-c3ccccc3)nc(-c3ccccc3)n2)c2cc3c(cc21)N(c1cc(-c2ccccc2)cc(-c2ccccc2)c1)c1ccccc1S3]

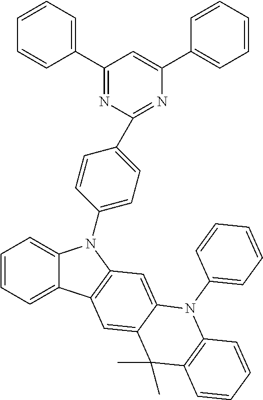 [SMILES: CC1(C)c2ccccc2N(c2ccccc2)c2cc3c(cc21)c1ccccc1n3-c1ccc(-c2nc(-c3ccccc3)cc(-c3ccccc3)n2)cc1]

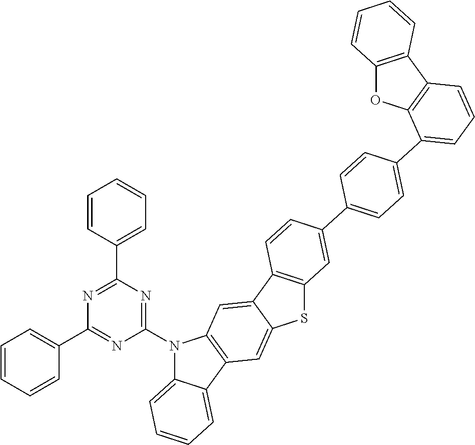 [SMILES: c1ccc(-c2nc(-c3ccccc3)nc(-n3c4ccccc4c4cc5sc6cc(-c7ccc(-c8cccc9c8oc8ccccc89)cc7)ccc6c5cc43)n2)cc1]

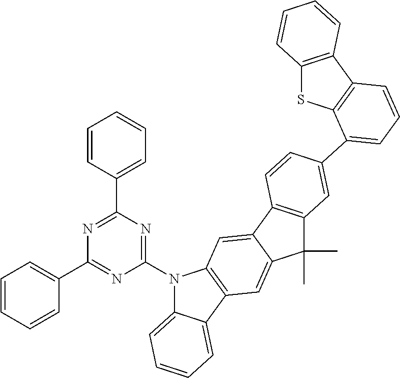 [SMILES: CC1(C)c2cc(-c3cccc4c3sc3ccccc34)ccc2-c2cc3c(cc21)c1ccccc1n3-c1nc(-c2ccccc2)nc(-c2ccccc2)n1]

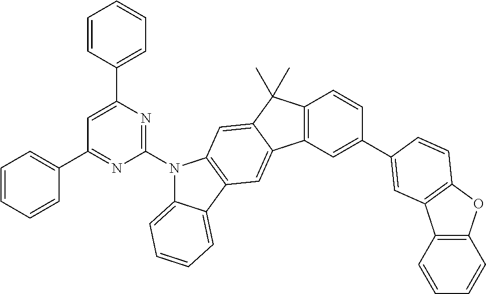 [SMILES: CC1(C)c2ccc(-c3ccc4oc5ccccc5c4c3)cc2-c2cc3c4ccccc4n(-c4nc(-c5ccccc5)cc(-c5ccccc5)n4)c3cc21]

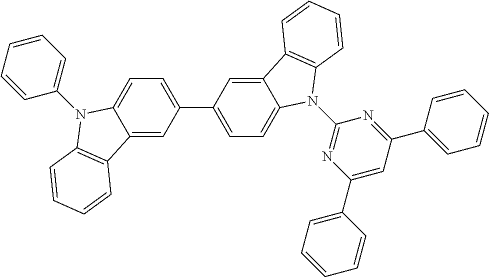 [SMILES: c1ccc(-c2cc(-c3ccccc3)nc(-n3c4ccccc4c4cc(-c5ccc6c(c5)c5ccccc5n6-c5ccccc5)ccc43)n2)cc1]

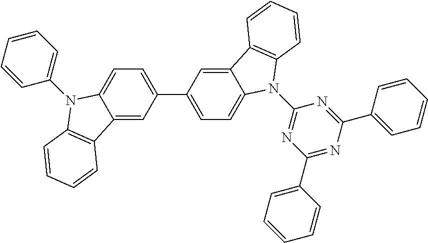 [SMILES: c1ccc(-c2nc(-c3ccccc3)nc(-n3c4ccccc4c4cc(-c5ccc6c(c5)c5ccccc5n6-c5ccccc5)ccc43)n2)cc1]

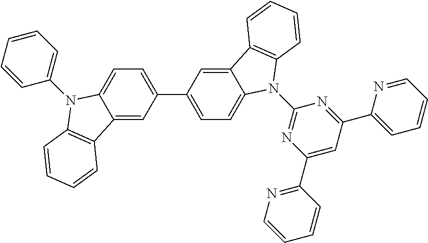 [SMILES: c1ccc(-n2c3ccccc3c3cc(-c4ccc5c(c4)c4ccccc4n5-c4nc(-c5ccccn5)cc(-c5ccccn5)n4)ccc32)cc1]

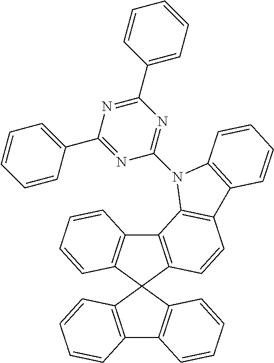 [SMILES: c1ccc(-c2nc(-c3ccccc3)nc(-n3c4ccccc4c4ccc5c(c43)-c3ccccc3C53c4ccccc4-c4ccccc43)n2)cc1]

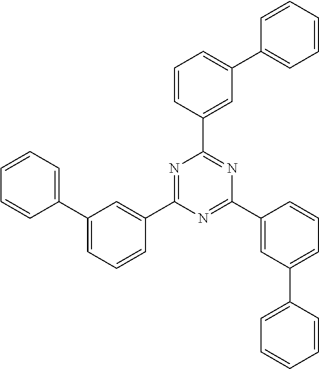 [SMILES: c1ccc(-c2cccc(-c3nc(-c4cccc(-c5ccccc5)c4)nc(-c4cccc(-c5ccccc5)c4)n3)c2)cc1]

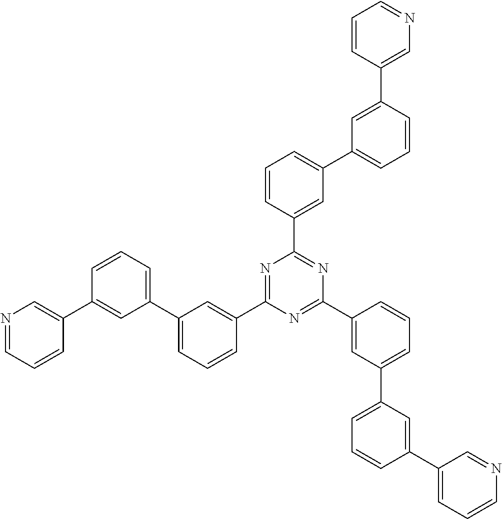 [SMILES: c1cncc(-c2cccc(-c3cccc(-c4nc(-c5cccc(-c6cccc(-c7cccnc7)c6)c5)nc(-c5cccc(-c6cccc(-c7cccnc7)c6)c5)n4)c3)c2)c1]

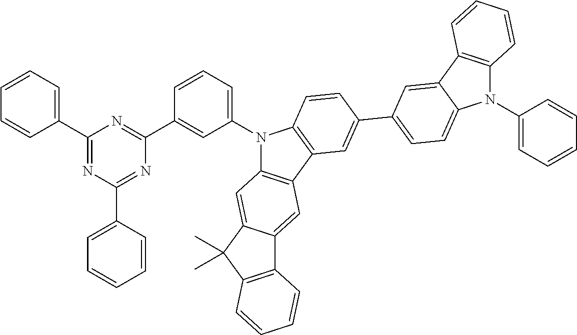 [SMILES: CC1(C)c2ccccc2-c2cc3c4cc(-c5ccc6c(c5)c5ccccc5n6-c5ccccc5)ccc4n(-c4cccc(-c5nc(-c6ccccc6)nc(-c6ccccc6)n5)c4)c3cc21]

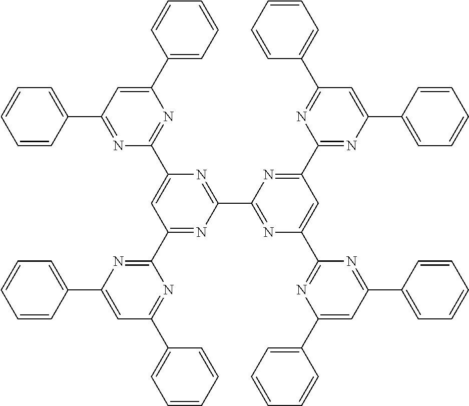 [SMILES: c1ccc(-c2cc(-c3ccccc3)nc(-c3cc(-c4nc(-c5ccccc5)cc(-c5ccccc5)n4)nc(-c4nc(-c5nc(-c6ccccc6)cc(-c6ccccc6)n5)cc(-c5nc(-c6ccccc6)cc(-c6ccccc6)n5)n4)n3)n2)cc1]

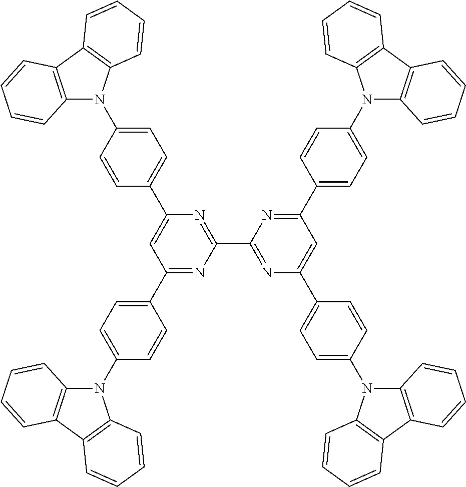 [SMILES: c1ccc2c(c1)c1ccccc1n2-c1ccc(-c2cc(-c3ccc(-n4c5ccccc5c5ccccc54)cc3)nc(-c3nc(-c4ccc(-n5c6ccccc6c6ccccc65)cc4)cc(-c4ccc(-n5c6ccccc6c6ccccc65)cc4)n3)n2)cc1]

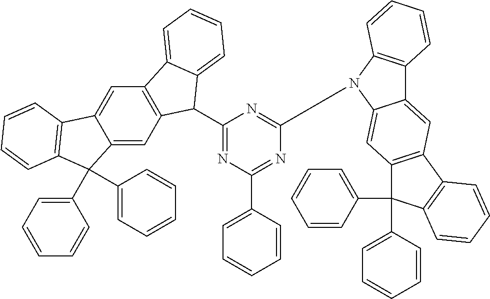 [SMILES: c1ccc(-c2nc(C3c4ccccc4-c4cc5c(cc43)C(c3ccccc3)(c3ccccc3)c3ccccc3-5)nc(-n3c4ccccc4c4cc5c(cc43)C(c3ccccc3)(c3ccccc3)c3ccccc3-5)n2)cc1]

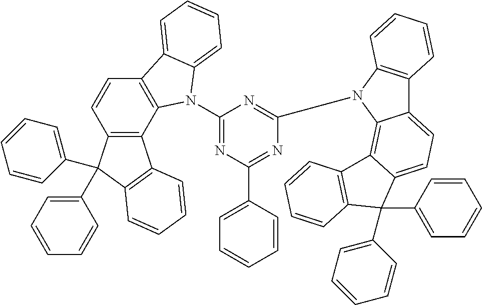 [SMILES: c1ccc(-c2nc(-n3c4ccccc4c4ccc5c(c43)-c3ccccc3C5(c3ccccc3)c3ccccc3)nc(-n3c4ccccc4c4ccc5c(c43)-c3ccccc3C5(c3ccccc3)c3ccccc3)n2)cc1]

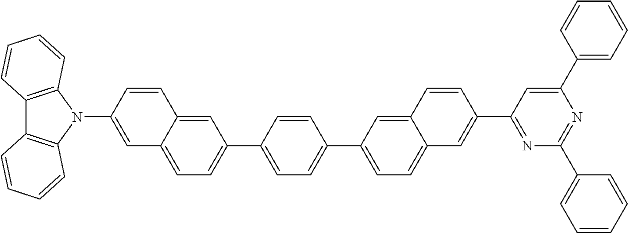 [SMILES: c1ccc(-c2cc(-c3ccc4cc(-c5ccc(-c6ccc7cc(-n8c9ccccc9c9ccccc98)ccc7c6)cc5)ccc4c3)nc(-c3ccccc3)n2)cc1]

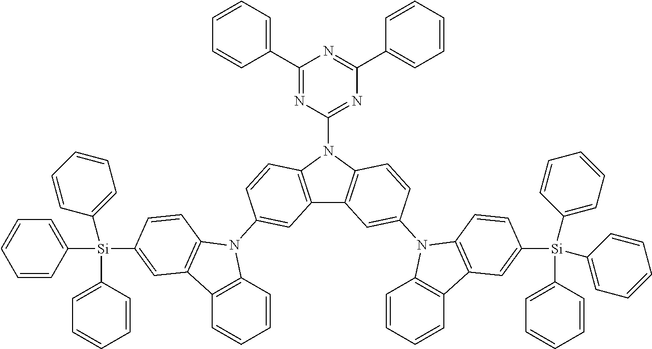 [SMILES: c1ccc(-c2nc(-c3ccccc3)nc(-n3c4ccc(-n5c6ccccc6c6cc([Si](c7ccccc7)(c7ccccc7)c7ccccc7)ccc65)cc4c4cc(-n5c6ccccc6c6cc([Si](c7ccccc7)(c7ccccc7)c7ccccc7)ccc65)ccc43)n2)cc1]

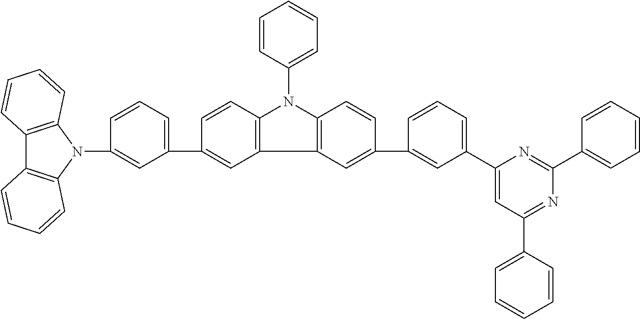 [SMILES: c1ccc(-c2cc(-c3cccc(-c4ccc5c(c4)c4cc(-c6cccc(-n7c8ccccc8c8ccccc87)c6)ccc4n5-c4ccccc4)c3)nc(-c3ccccc3)n2)cc1]

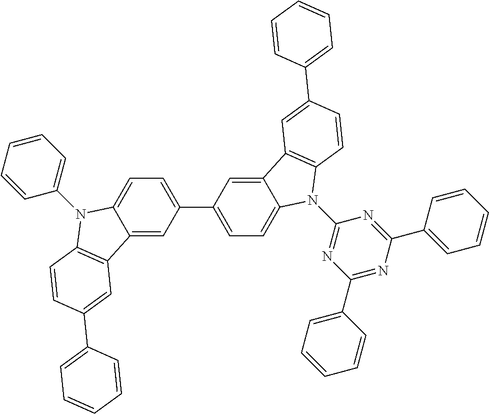 [SMILES: c1ccc(-c2ccc3c(c2)c2cc(-c4ccc5c(c4)c4cc(-c6ccccc6)ccc4n5-c4nc(-c5ccccc5)nc(-c5ccccc5)n4)ccc2n3-c2ccccc2)cc1]

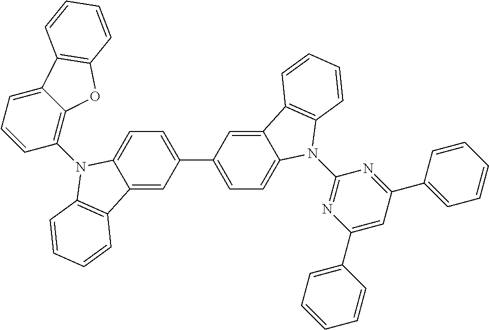 [SMILES: c1ccc(-c2cc(-c3ccccc3)nc(-n3c4ccccc4c4cc(-c5ccc6c(c5)c5ccccc5n6-c5cccc6c5oc5ccccc56)ccc43)n2)cc1]

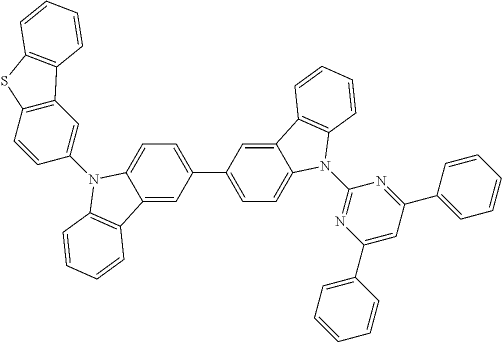 [SMILES: c1ccc(-c2cc(-c3ccccc3)nc(-n3c4ccccc4c4cc(-c5ccc6c(c5)c5ccccc5n6-c5ccc6sc7ccccc7c6c5)ccc43)n2)cc1]

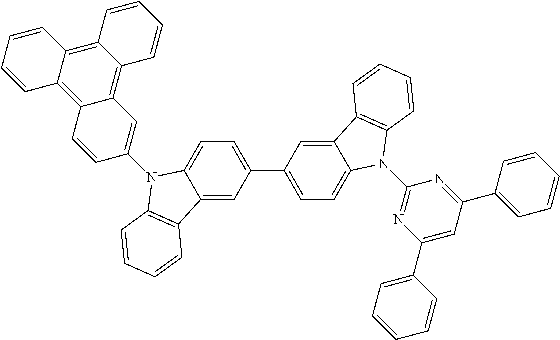 [SMILES: c1ccc(-c2cc(-c3ccccc3)nc(-n3c4ccccc4c4cc(-c5ccc6c(c5)c5ccccc5n6-c5ccc6c7ccccc7c7ccccc7c6c5)ccc43)n2)cc1]

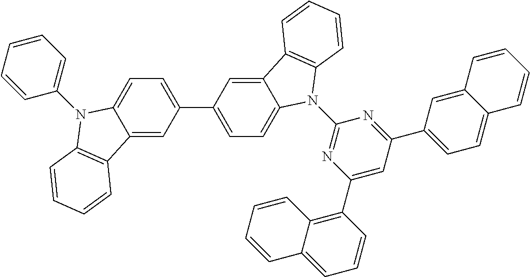 [SMILES: c1ccc(-n2c3ccccc3c3cc(-c4ccc5c(c4)c4ccccc4n5-c4nc(-c5ccc6ccccc6c5)cc(-c5cccc6ccccc56)n4)ccc32)cc1]

If the electron-conducting compound is a lactam, this compound is then preferably selected from the compounds of the following formulae (53) and (54),

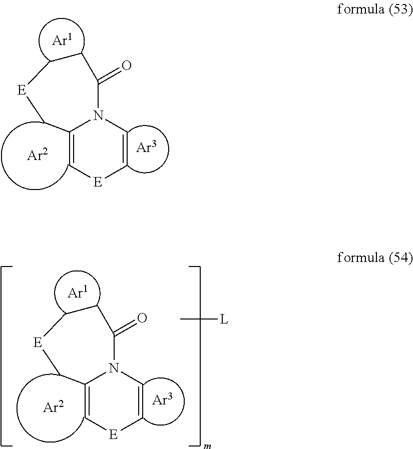

where R, R¹ and R² have the meanings given above, and the following applies to the other symbols and indices used:
E is, identically or differently on each occurrence, a single bond, NR, CR₂, O or S;
Ar¹ is, together with the carbon atoms explicitly depicted, an aromatic or heteroaromatic ring system having 5 to 30 aromatic ring atoms, which may be substituted by one or more radicals R;
Ar², Ar³ are, identically or differently on each occurrence, together with the carbon atoms explicitly depicted, an aromatic or heteroaromatic ring system having 5 to 30 aromatic ring atoms, which may be substituted by one or more radicals R;
L is for m=2 a single bond or a divalent group, or for m=3 a trivalent group or for m=4 a tetravalent group, which is in each case bonded to Ar¹, Ar² or Ar³ at any desired position or is bonded to E in place of a radical R;
m is 2, 3 or 4.

In a preferred embodiment of the invention, Ar¹, Ar² and Ar³, identically or differently on each occurrence, together with the carbon atoms explicitly depicted, are aryl or heteroaryl groups having 5 to 10 aromatic ring atoms, in particular having 5 or 6 aromatic ring atoms, which may be substituted by one or more radicals R.

In a preferred embodiment of the compound of the formula (53) or (54), the group Ar¹ stands for a group of the following formula (55), (56), (57) or (58),

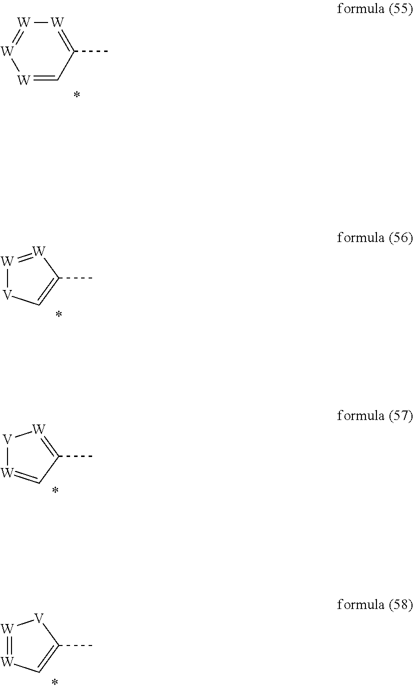

where the dashed bond indicates the link to the carbonyl group, * indicates the position of the link to E, and furthermore:
W is, identically or differently on each occurrence, CR or N; or two adjacent groups W stand for a group of the following formula (59) or (60),

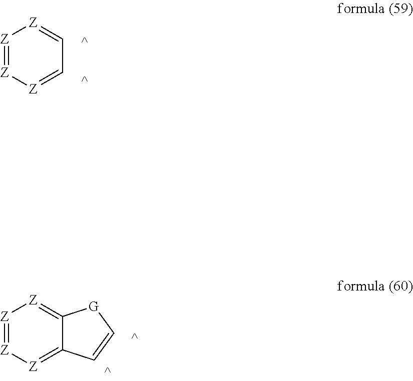

where G stands for CR₂, NR, O or S, Z stands, identically or differently on each occurrence, for CR or N, and A indicate the corresponding adjacent groups W in the formulae (55) to (58);

V is NR, O or S.

In a further preferred embodiment of the invention, the group Ar² stands for a group of one of the following formulae (61), (62) and (63),

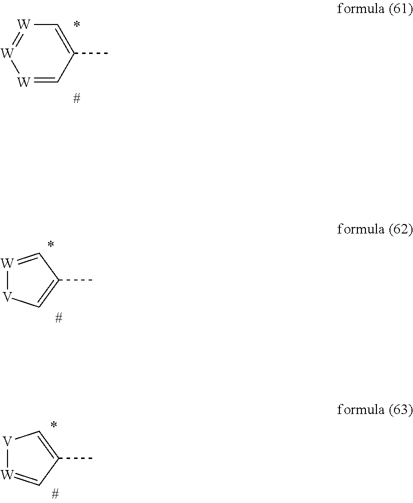

where the dashed bond indicates the link to N, # indicates the position of the link to E and Ar³, * indicates the link to E and Ar¹, and W and V have the meanings given above.

In a further preferred embodiment of the invention, the group Ar³ stands for a group of one of the following formulae (64), (65), (66) and (67),

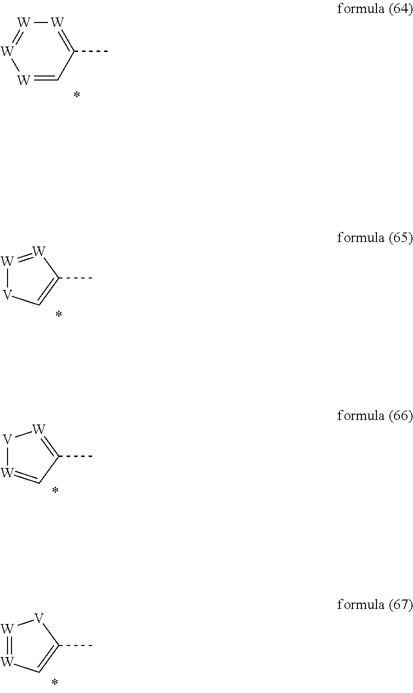

where the dashed bond indicates the link to N, * indicates the link to E, and W and V have the meanings given above.

The above-mentioned preferred groups Ar¹, Ar² and Ar³ can be combined with one another as desired here.

In a further preferred embodiment of the invention, at least one group E stands for a single bond. Particularly preferably, all groups E stand for single bonds.

In a preferred embodiment of the invention, the above-mentioned preferences occur simultaneously. Particular preference is therefore given to compounds of the formulae (53) and (54) for which:
Ar¹ is selected from the groups of the above-mentioned formulae (55), (56), (57) and (58);
Ar² is selected from the groups of the above-mentioned formulae (61), (62) and (63);
Ar³ is selected from the groups of the above-mentioned formulae (64), (65), (66) and (67).

Particularly preferably, at least two of the groups Ar¹, Ar² and Ar³ stand for a 6-membered aryl or 6-membered heteroaryl ring group. Particularly preferably, Ar¹ stands for a group of the formula (55) and at the same time Ar² stands for a group of the formula (61), or Ar¹ stands for a group of the formula (55) and at the same time Ar³ stands for a group of the formula (64), or Ar² stands for a group of the formula (61) and at the same time Ar³ stands for a group of the formula (64).

Particularly preferred embodiments of the formula (53) are therefore the compounds of the following formulae (65) to (74),

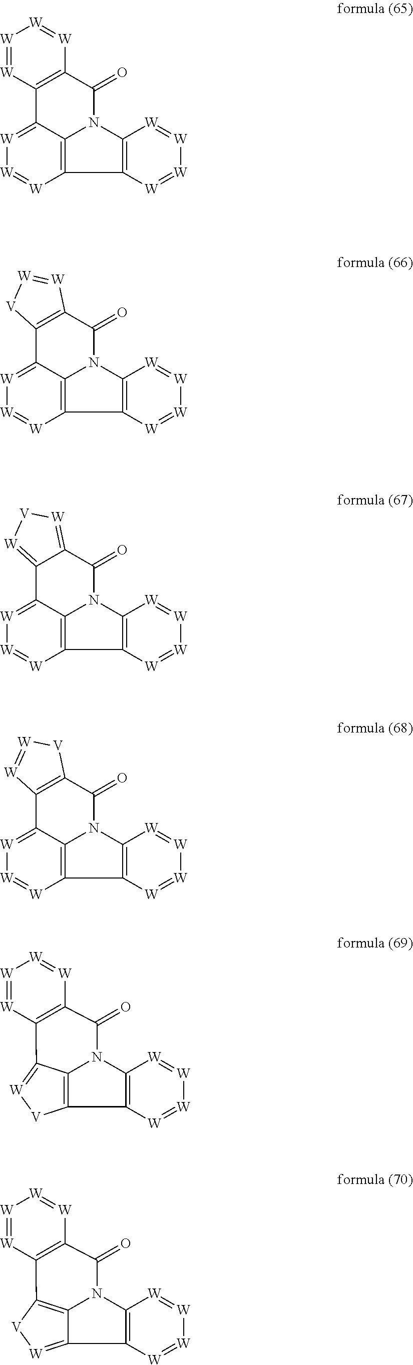

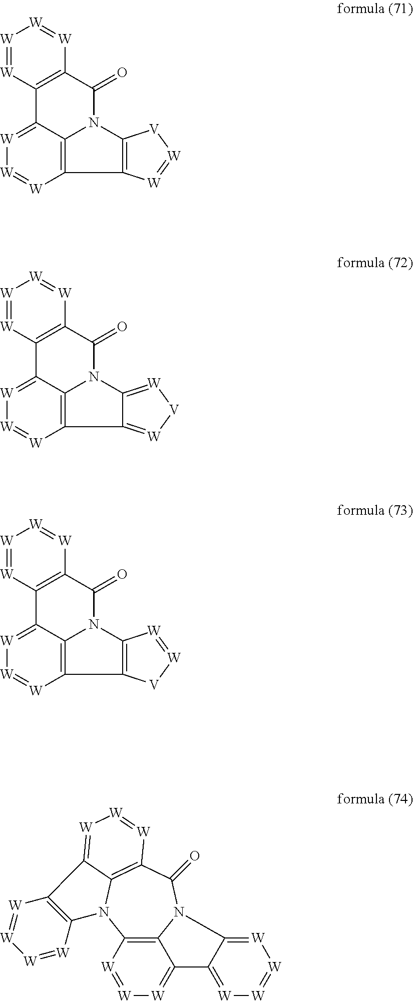

where the symbols used have the meanings given above.

It is furthermore preferred for W to stand for CR or N and not for a group of the formula (59) or (60). In a preferred embodiment of the compounds of the formulae (65) to (74), in total a maximum of one symbol W per ring stands for N, and the remaining symbols W stand for CR. In a particularly preferred embodiment of the invention, all symbols W stand for CR. Particular preference is therefore given to the compounds of the following formulae (65a) to (74a),

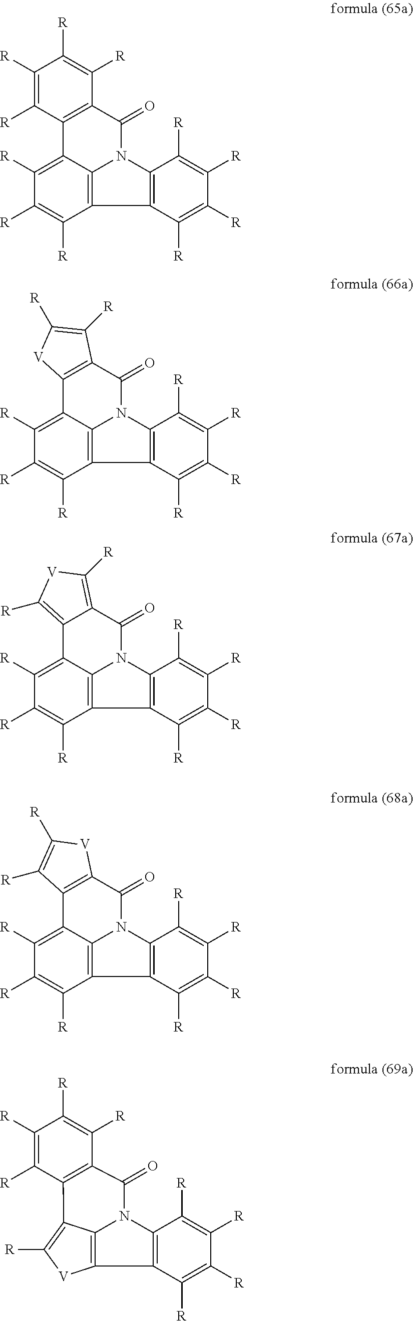

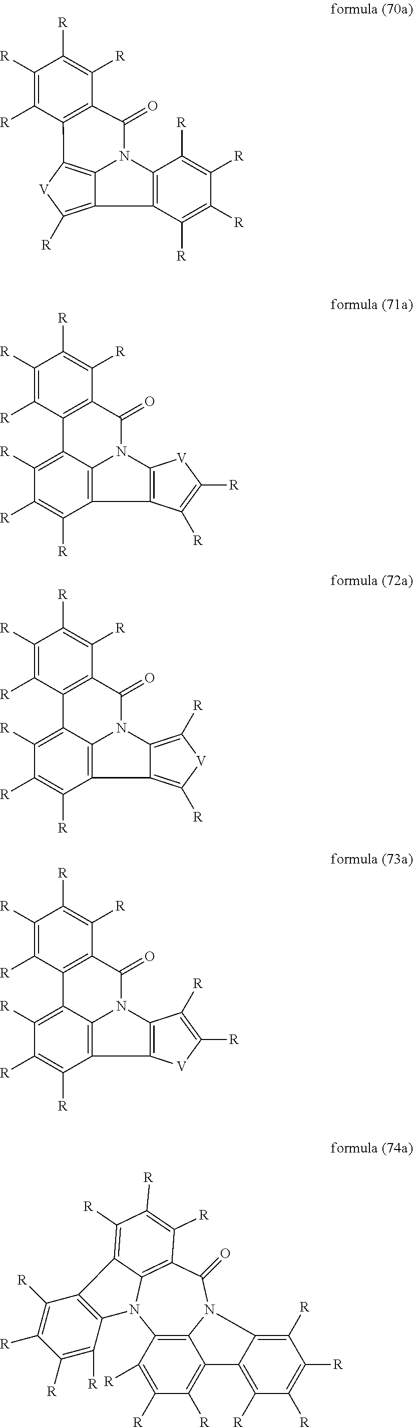

where the symbols used have the meanings given above.

Very particular preference is given to the structures of the formulae (60b) to (69b),

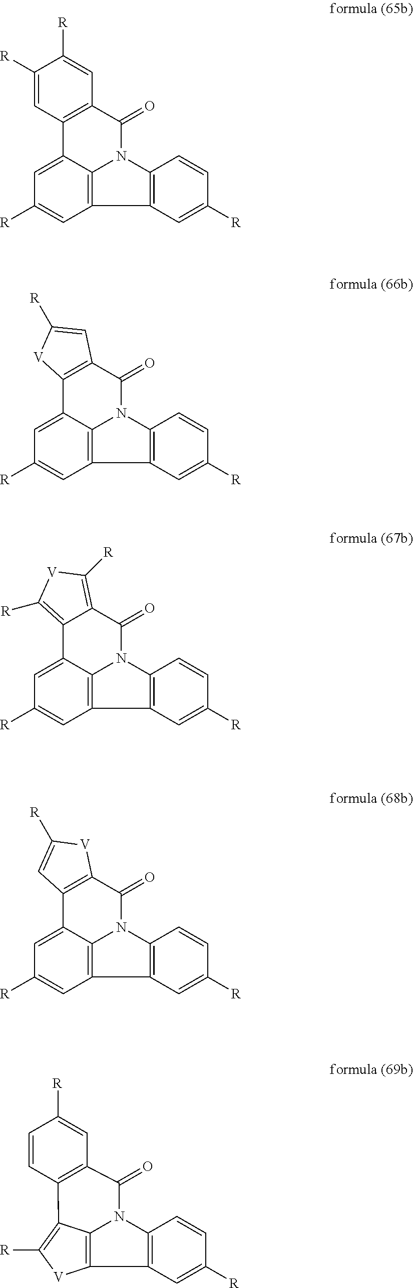

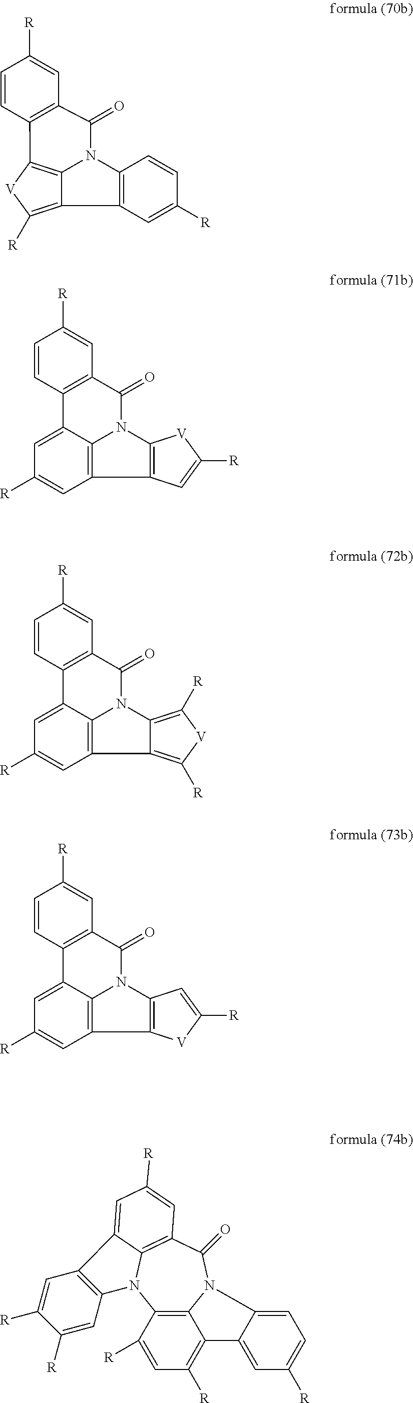

where the symbols used have the meanings given above.

Very particular preference is given to the compounds of the formulae (65) and (65a) and (65b).

The bridging group L in the compounds of the formula (54) is preferably selected from a single bond or an aromatic or heteroaromatic ring system having 5 to 24, preferably 6 to 12 aromatic ring atoms, which may be substituted by one or more radicals R. The aromatic or heteroaromatic ring systems here preferably contain no condensed aryl or heteroaryl groups in which more than two aromatic six-membered rings are condensed directly onto one another. They particularly preferably contain absolutely no aryl or heteroaryl groups in which aromatic six-membered rings are condensed directly onto one another.

In a further preferred embodiment of the invention, the index m in compounds of the formula (54)=2 or 3, in particular equals 2. Very particular preference is given to the use of compounds of the formula (53).

In a preferred embodiment of the invention, R in the lactams of the above-mentioned formulae is selected, identically or differently on each occurrence, from the group consisting of H, D, F, Cl, Br, CN, N(R¹)₂, C(═O)R¹, a straight-chain alkyl or alkoxy group having 1 to 10 C atoms or a branched or cyclic alkyl or alkoxy group having 3 to 10 C atoms or an alkenyl group having 2 to 10 C atoms, each of which may be substituted by one or more radicals R¹, where one or more non-adjacent CH₂ groups may be replaced by O and where one or more H atoms may be replaced by D or F, an aromatic or heteroaromatic ring system having 5 to 30 aromatic ring atoms, which may in each case be substituted by one or more radicals R¹, an aryloxy or heteroaryloxy group having 5 to 30 aromatic ring atoms, which may be substituted by one or more radicals R¹.

In a particularly preferred embodiment of the invention, R in the lactams of the above-mentioned formulae is selected, identically or differently on each occurrence, from the group consisting of H, D, F, Cl, Br, CN, a straight-chain alkyl group having 1 to 10 C atoms, preferably having 1 to 4 C atoms, or a branched or cyclic alkyl group having 3 to 10 C atoms, preferably having 3 to 4 C atoms, each of which may be substituted by one or more radicals R¹, where one or more H atoms may be replaced by D or F, an aromatic or heteroaromatic ring system having 5 to 18 aromatic ring atoms, which may in each case be substituted by one or more radicals R¹.

The radicals R, if these contain aromatic or heteroaromatic ring systems, preferably contain no condensed aryl or heteroaryl groups in which more than two aromatic six-membered rings are condensed directly onto one another. They particularly preferably contain absolutely no aryl or heteroaryl groups in which aromatic six-membered rings are condensed directly onto one another. Especial preference is given here to phenyl, biphenyl, terphenyl, quaterphenyl, carbazole, dibenzothiophene, dibenzofuran, indenocarbazole, indolocarbazole, triazine or pyrimidine, each of which may also be substituted by one or more radicals R¹.

The compounds of the formulae (53) and (54) are known in principle. The synthesis of these compounds can be carried out by the processes described in WO 2011/116865 and WO 2011/137951.

Examples of preferred compounds in accordance with the above-mentioned embodiments are the compounds shown in the following table.

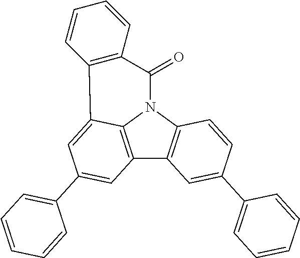 [SMILES: O=c1c2ccccc2c2cc(-c3ccccc3)cc3c4cc(-c5ccccc5)ccc4n1c23]

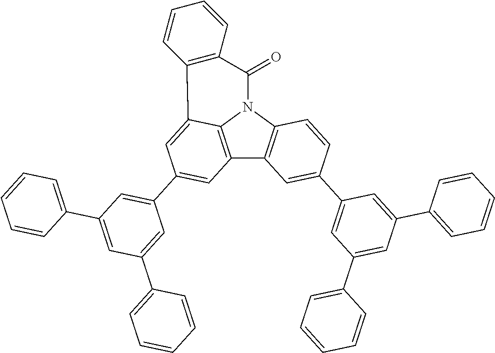 [SMILES: O=c1c2ccccc2c2cc(-c3cc(-c4ccccc4)cc(-c4ccccc4)c3)cc3c4cc(-c5cc(-c6ccccc6)cc(-c6ccccc6)c5)ccc4n1c23]

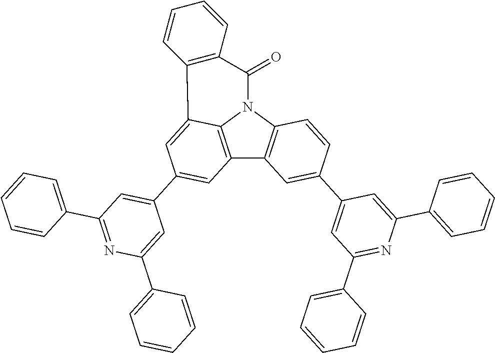 [SMILES: O=c1c2ccccc2c2cc(-c3cc(-c4ccccc4)nc(-c4ccccc4)c3)cc3c4cc(-c5cc(-c6ccccc6)nc(-c6ccccc6)c5)ccc4n1c23]

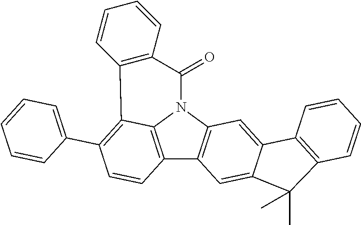 [SMILES: CC1(C)c2ccccc2-c2cc3c(cc21)c1ccc(-c2ccccc2)c2c4ccccc4c(=O)n3c12]

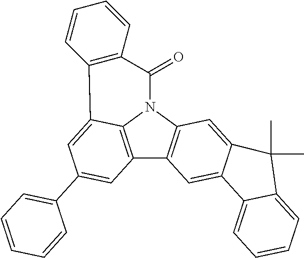 [SMILES: CC1(C)c2ccccc2-c2cc3c4cc(-c5ccccc5)cc5c6ccccc6c(=O)n(c3cc21)c54]

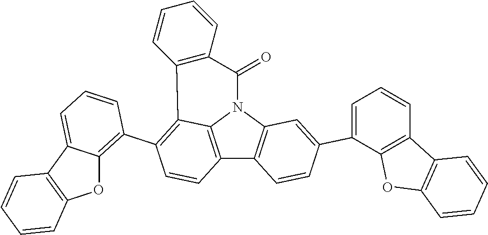 [SMILES: O=c1c2ccccc2c2c(-c3cccc4c3oc3ccccc34)ccc3c4ccc(-c5cccc6c5oc5ccccc56)cc4n1c32]

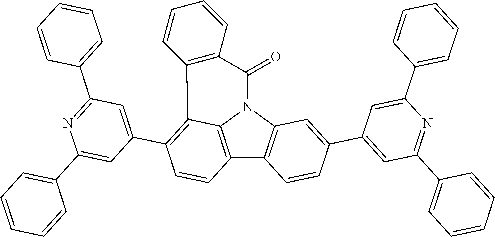 [SMILES: O=c1c2ccccc2c2c(-c3cc(-c4ccccc4)nc(-c4ccccc4)c3)ccc3c4ccc(-c5cc(-c6ccccc6)nc(-c6ccccc6)c5)cc4n1c32]

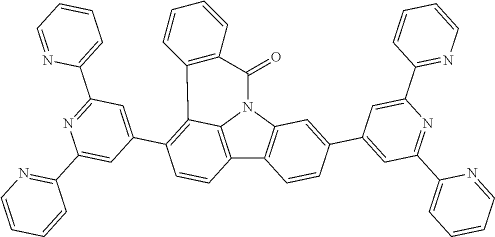 [SMILES: O=c1c2ccccc2c2c(-c3cc(-c4ccccn4)nc(-c4ccccn4)c3)ccc3c4ccc(-c5cc(-c6ccccn6)nc(-c6ccccn6)c5)cc4n1c32]

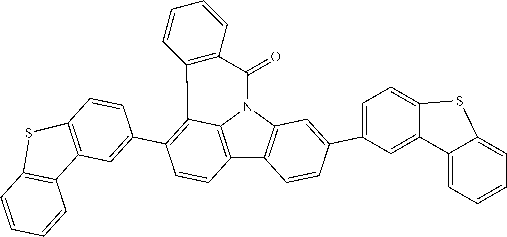 [SMILES: O=c1c2ccccc2c2c(-c3ccc4sc5ccccc5c4c3)ccc3c4ccc(-c5ccc6sc7ccccc7c6c5)cc4n1c32]

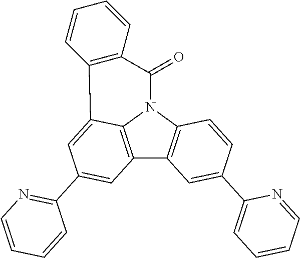 [SMILES: O=c1c2ccccc2c2cc(-c3ccccn3)cc3c4cc(-c5ccccn5)ccc4n1c23]

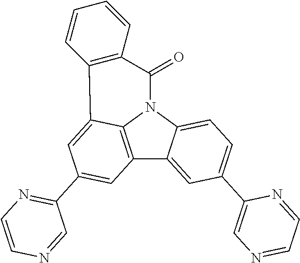 [SMILES: O=c1c2ccccc2c2cc(-c3cnccn3)cc3c4cc(-c5cnccn5)ccc4n1c23]

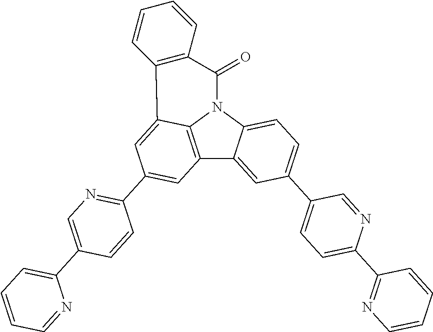 [SMILES: O=c1c2ccccc2c2cc(-c3ccc(-c4ccccn4)cn3)cc3c4cc(-c5ccc(-c6ccccn6)nc5)ccc4n1c23]

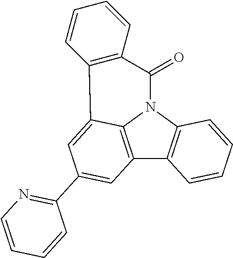 [SMILES: O=c1c2ccccc2c2cc(-c3ccccn3)cc3c4ccccc4n1c23]

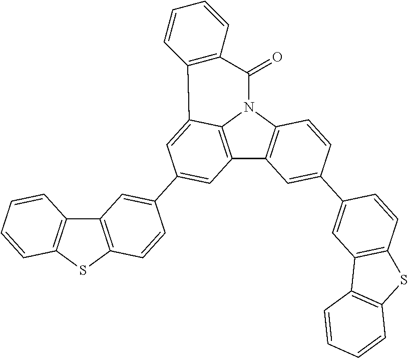 [SMILES: O=c1c2ccccc2c2cc(-c3ccc4sc5ccccc5c4c3)cc3c4cc(-c5ccc6sc7ccccc7c6c5)ccc4n1c23]

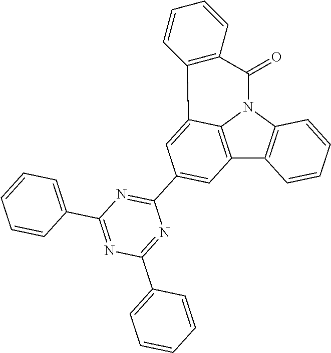 [SMILES: O=c1c2ccccc2c2cc(-c3nc(-c4ccccc4)nc(-c4ccccc4)n3)cc3c4ccccc4n1c23]

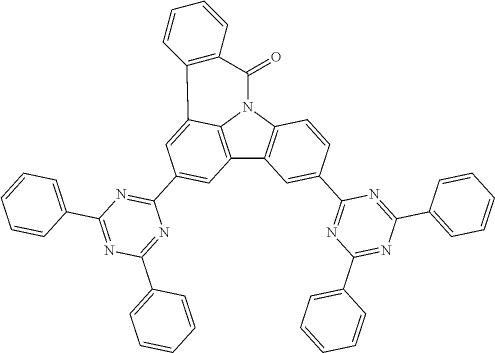 [SMILES: O=c1c2ccccc2c2cc(-c3nc(-c4ccccc4)nc(-c4ccccc4)n3)cc3c4cc(-c5nc(-c6ccccc6)nc(-c6ccccc6)n5)ccc4n1c23]

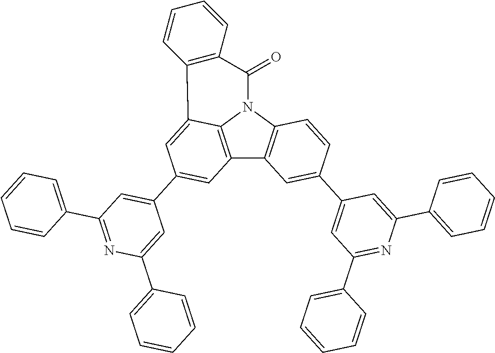 [SMILES: O=c1c2ccccc2c2cc(-c3cc(-c4ccccc4)nc(-c4ccccc4)c3)cc3c4cc(-c5cc(-c6ccccc6)nc(-c6ccccc6)c5)ccc4n1c23]

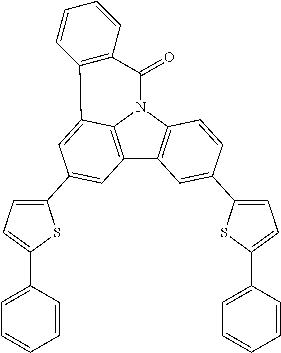 [SMILES: O=c1c2ccccc2c2cc(-c3ccc(-c4ccccc4)s3)cc3c4cc(-c5ccc(-c6ccccc6)s5)ccc4n1c23]

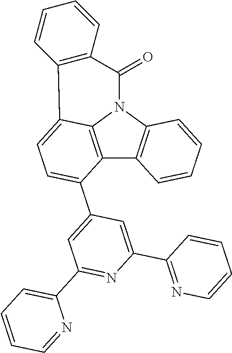 [SMILES: O=c1c2ccccc2c2ccc(-c3cc(-c4ccccn4)nc(-c4ccccn4)c3)c3c4ccccc4n1c23]

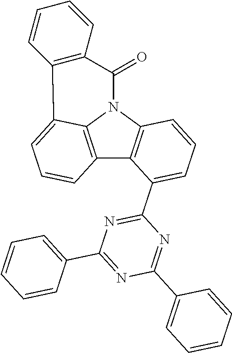 [SMILES: O=c1c2ccccc2c2cccc3c4c(-c5nc(-c6ccccc6)nc(-c6ccccc6)n5)cccc4n1c23]

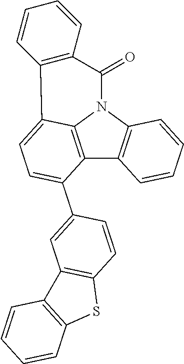 [SMILES: O=c1c2ccccc2c2ccc(-c3ccc4sc5ccccc5c4c3)c3c4ccccc4n1c23]

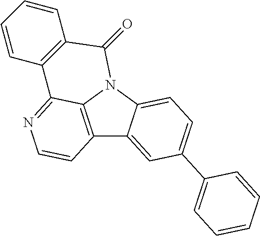 [SMILES: O=c1c2ccccc2c2nccc3c4cc(-c5ccccc5)ccc4n1c32]

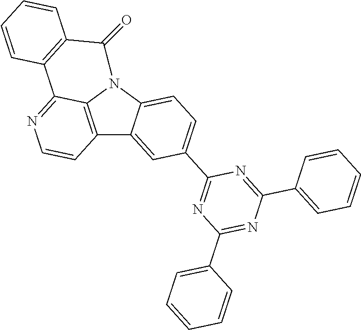 [SMILES: O=c1c2ccccc2c2nccc3c4cc(-c5nc(-c6ccccc6)nc(-c6ccccc6)n5)ccc4n1c32]

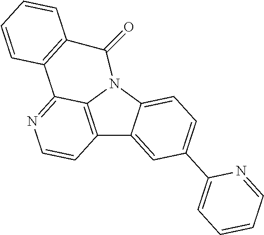 [SMILES: O=c1c2ccccc2c2nccc3c4cc(-c5ccccn5)ccc4n1c32]

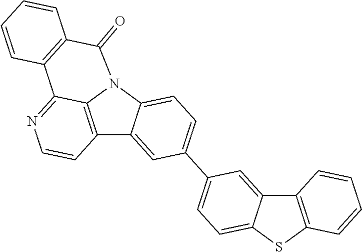 [SMILES: O=c1c2ccccc2c2nccc3c4cc(-c5ccc6sc7ccccc7c6c5)ccc4n1c32]

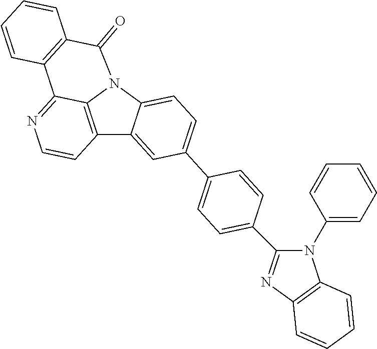 [SMILES: O=c1c2ccccc2c2nccc3c4cc(-c5ccc(-c6nc7ccccc7n6-c6ccccc6)cc5)ccc4n1c32]

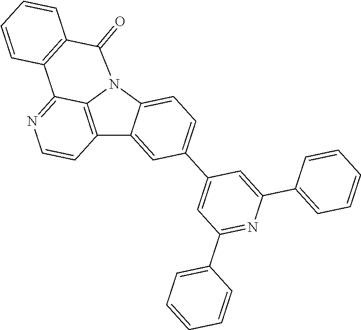 [SMILES: O=c1c2ccccc2c2nccc3c4cc(-c5cc(-c6ccccc6)nc(-c6ccccc6)c5)ccc4n1c32]

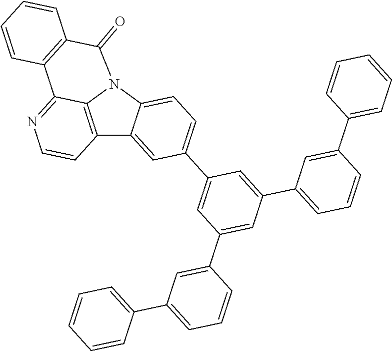 [SMILES: O=c1c2ccccc2c2nccc3c4cc(-c5cc(-c6cccc(-c7ccccc7)c6)cc(-c6cccc(-c7ccccc7)c6)c5)ccc4n1c32]

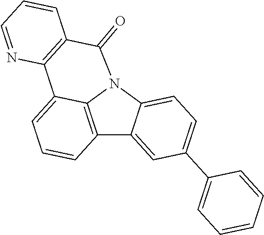 [SMILES: O=c1c2cccnc2c2cccc3c4cc(-c5ccccc5)ccc4n1c32]

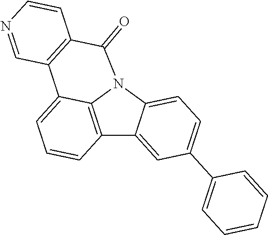 [SMILES: O=c1c2ccncc2c2cccc3c4cc(-c5ccccc5)ccc4n1c23]

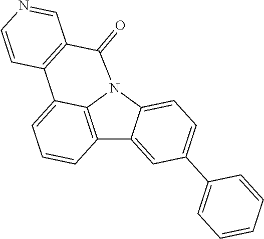 [SMILES: O=c1c2cnccc2c2cccc3c4cc(-c5ccccc5)ccc4n1c23]

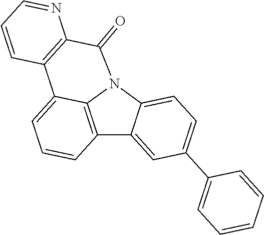 [SMILES: O=c1c2ncccc2c2cccc3c4cc(-c5ccccc5)ccc4n1c23]

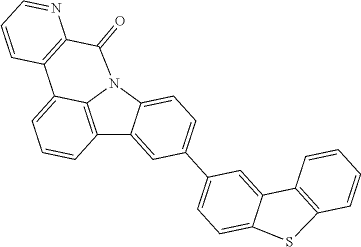 [SMILES: O=c1c2ncccc2c2cccc3c4cc(-c5ccc6sc7ccccc7c6c5)ccc4n1c23]

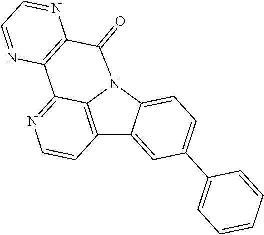 [SMILES: O=c1c2nccnc2c2nccc3c4cc(-c5ccccc5)ccc4n1c32]

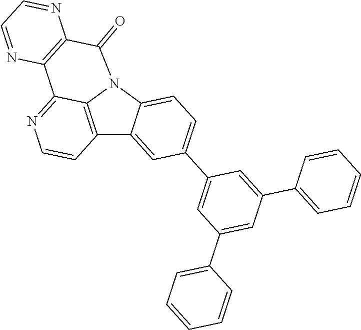 [SMILES: O=c1c2nccnc2c2nccc3c4cc(-c5cc(-c6ccccc6)cc(-c6ccccc6)c5)ccc4n1c32]

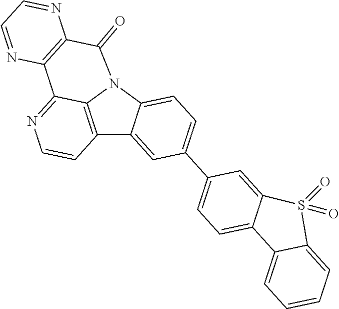 [SMILES: O=c1c2nccnc2c2nccc3c4cc(-c5ccc6c(c5)S(=O)(=O)c5ccccc5-6)ccc4n1c32]

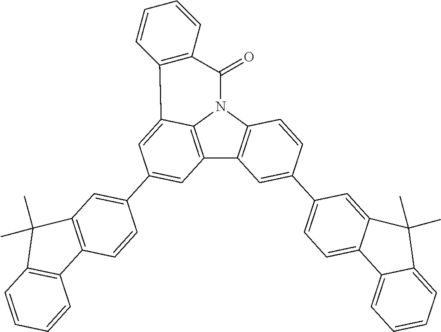

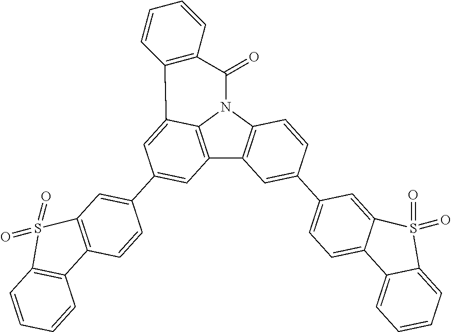 [SMILES: O=c1c2ccccc2c2cc(-c3ccc4c(c3)S(=O)(=O)c3ccccc3-4)cc3c4cc(-c5ccc6c(c5)S(=O)(=O)c5ccccc5-6)ccc4n1c23]

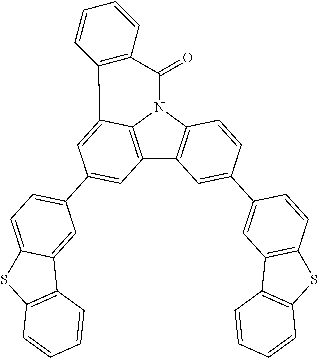 [SMILES: O=c1c2ccccc2c2cc(-c3ccc4sc5ccccc5c4c3)cc3c4cc(-c5ccc6sc7ccccc7c6c5)ccc4n1c23]

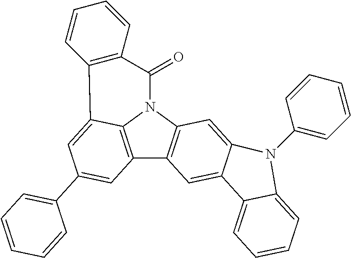 [SMILES: O=c1c2ccccc2c2cc(-c3ccccc3)cc3c4cc5c6ccccc6n(-c6ccccc6)c5cc4n1c23]

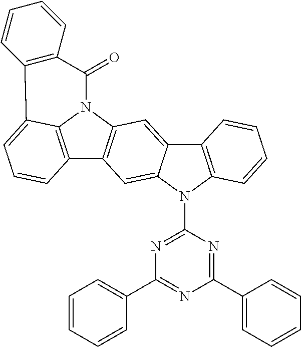 [SMILES: O=c1c2ccccc2c2cccc3c4cc5c(cc4n1c23)c1ccccc1n5-c1nc(-c2ccccc2)nc(-c2ccccc2)n1]

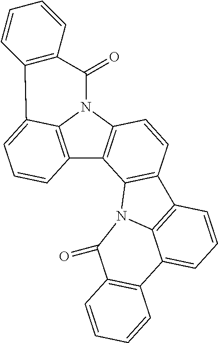 [SMILES: O=c1c2ccccc2c2cccc3c4c(ccc5c6cccc7c8ccccc8c(=O)n(c76)c54)n1c23]

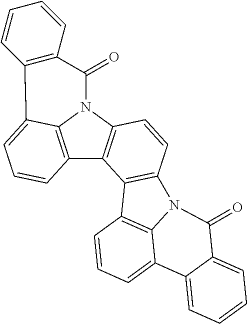 [SMILES: O=c1c2ccccc2c2cccc3c4c5c6cccc7c8ccccc8c(=O)n(c5ccc4n1c23)c76]

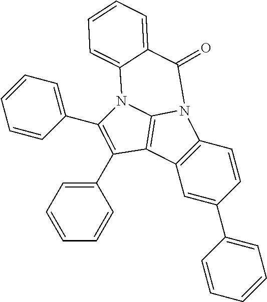 [SMILES: O=c1c2ccccc2n2c(-c3ccccc3)c(-c3ccccc3)c3c4cc(-c5ccccc5)ccc4n1c32]

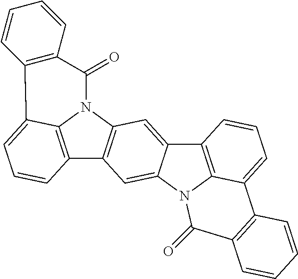 [SMILES: O=c1c2ccccc2c2cccc3c4cc5c(cc4n1c23)c1cccc2c3ccccc3c(=O)n5c21]

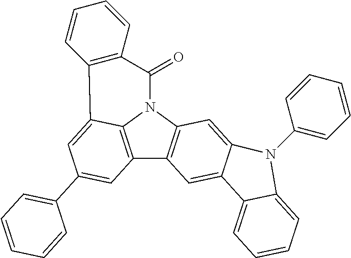 [SMILES: O=c1c2ccccc2c2cc(-c3ccccc3)cc3c4cc5c6ccccc6n(-c6ccccc6)c5cc4n1c23]

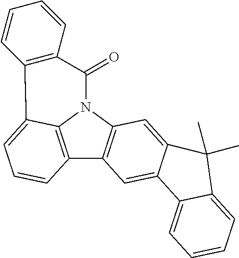 [SMILES: CC1(C)c2ccccc2-c2cc3c4cccc5c6ccccc6c(=O)n(c3cc21)c54]

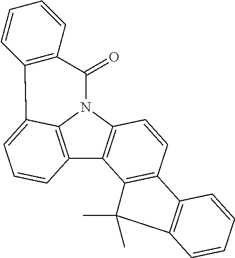 [SMILES: CC1(C)c2ccccc2-c2ccc3c(c21)c1cccc2c4ccccc4c(=O)n3c21]

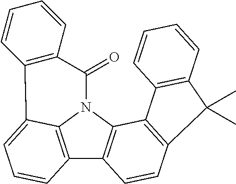 [SMILES: CC1(C)c2ccccc2-c2c1ccc1c3cccc4c5ccccc5c(=O)n(c21)c43]

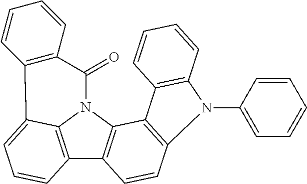 [SMILES: O=c1c2ccccc2c2cccc3c4ccc5c(c6ccccc6n5-c5ccccc5)c4n1c23]

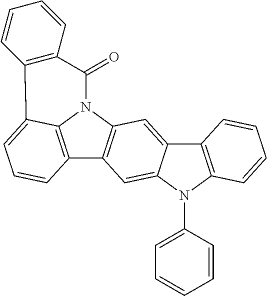 [SMILES: O=c1c2ccccc2c2cccc3c4cc5c(cc4n1c23)c1ccccc1n5-c1ccccc1]

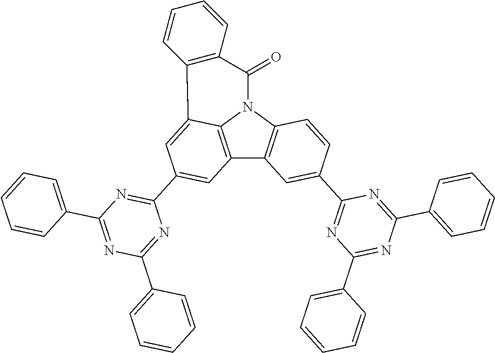 [SMILES: O=c1c2ccccc2c2cc(-c3nc(-c4ccccc4)nc(-c4ccccc4)n3)cc3c4cc(-c5nc(-c6ccccc6)nc(-c6ccccc6)n5)ccc4n1c23]

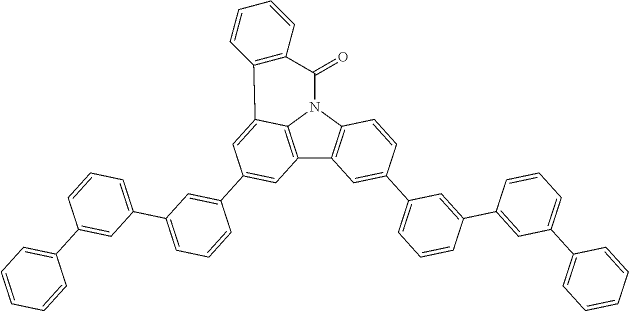 [SMILES: O=c1c2ccccc2c2cc(-c3cccc(-c4cccc(-c5ccccc5)c4)c3)cc3c4cc(-c5cccc(-c6cccc(-c7ccccc7)c6)c5)ccc4n1c23]

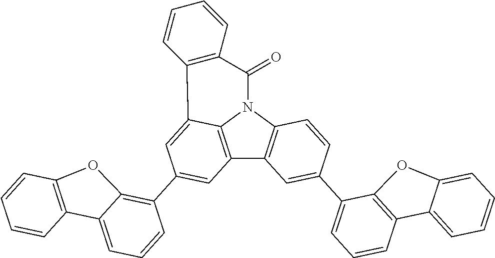 [SMILES: O=c1c2ccccc2c2cc(-c3cccc4c3oc3ccccc34)cc3c4cc(-c5cccc6c5oc5ccccc56)ccc4n1c23]

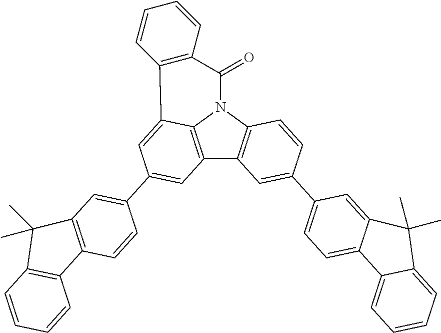

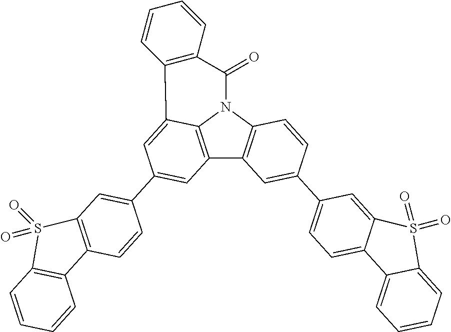 [SMILES: O=c1c2ccccc2c2cc(-c3ccc4c(c3)S(=O)(=O)c3ccccc3-4)cc3c4cc(-c5ccc6c(c5)S(=O)(=O)c5ccccc5-6)ccc4n1c23]

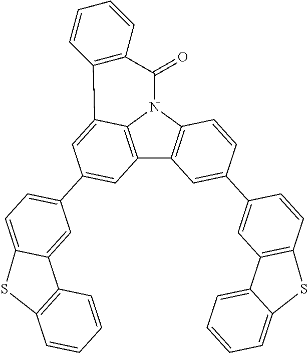 [SMILES: O=c1c2ccccc2c2cc(-c3ccc4sc5ccccc5c4c3)cc3c4cc(-c5ccc6sc7ccccc7c6c5)ccc4n1c23]

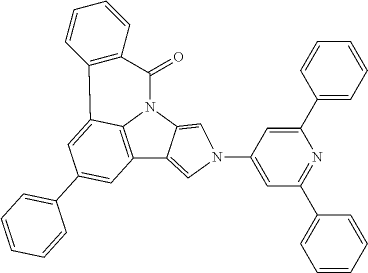 [SMILES: O=c1c2ccccc2c2cc(-c3ccccc3)cc3c4cn(-c5cc(-c6ccccc6)nc(-c6ccccc6)c5)cc4n1c23]

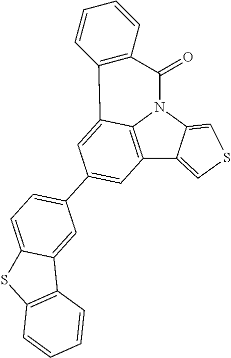 [SMILES: O=c1c2ccccc2c2cc(-c3ccc4sc5ccccc5c4c3)cc3c4cscc4n1c23]

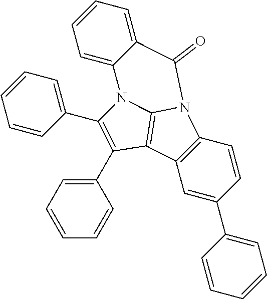 [SMILES: O=c1c2ccccc2n2c(-c3ccccc3)c(-c3ccccc3)c3c4cc(-c5ccccc5)ccc4n1c32]

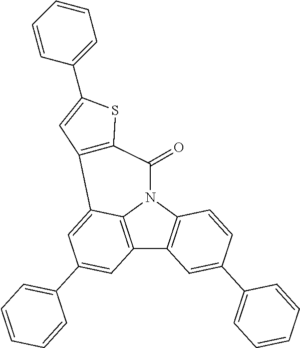 [SMILES: O=c1c2sc(-c3ccccc3)cc2c2cc(-c3ccccc3)cc3c4cc(-c5ccccc5)ccc4n1c23]

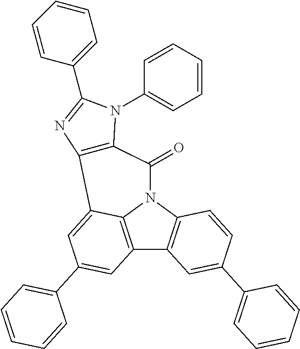 [SMILES: O=c1c2c(nc(-c3ccccc3)n2-c2ccccc2)c2cc(-c3ccccc3)cc3c4cc(-c5ccccc5)ccc4n1c32]

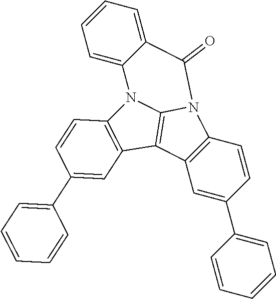 [SMILES: O=c1c2ccccc2n2c3ccc(-c4ccccc4)cc3c3c4cc(-c5ccccc5)ccc4n1c32]

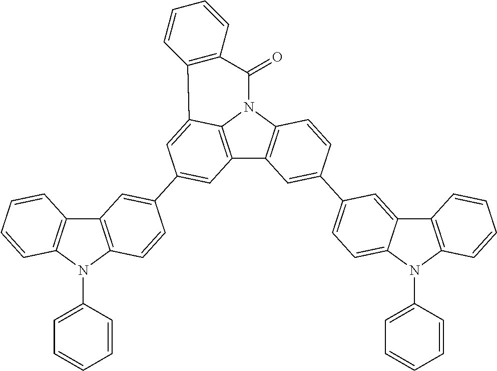 [SMILES: O=c1c2ccccc2c2cc(-c3ccc4c(c3)c3ccccc3n4-c3ccccc3)cc3c4cc(-c5ccc6c(c5)c5ccccc5n6-c5ccccc5)ccc4n1c23]

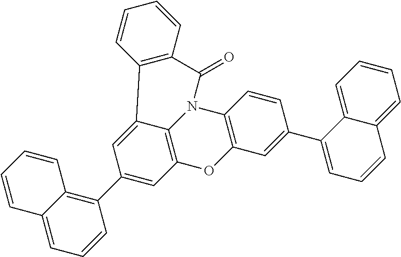 [SMILES: O=c1c2ccccc2c2cc(-c3cccc4ccccc34)cc3c2n1-c1ccc(-c2cccc4ccccc24)cc1O3]

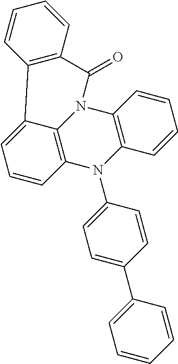 [SMILES: O=c1c2ccccc2c2cccc3c2n1-c1ccccc1N3c1ccc(-c2ccccc2)cc1]

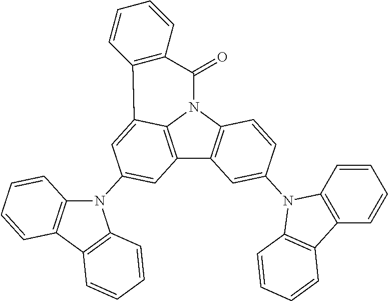 [SMILES: O=c1c2ccccc2c2cc(-n3c4ccccc4c4ccccc43)cc3c4cc(-n5c6ccccc6c6ccccc65)ccc4n1c23]

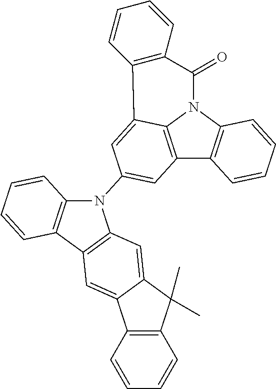 [SMILES: CC1(C)c2ccccc2-c2cc3c4ccccc4n(-c4cc5c6ccccc6c(=O)n6c7ccccc7c(c4)c56)c3cc21]

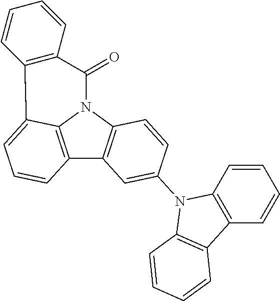 [SMILES: O=c1c2ccccc2c2cccc3c4cc(-n5c6ccccc6c6ccccc65)ccc4n1c23]

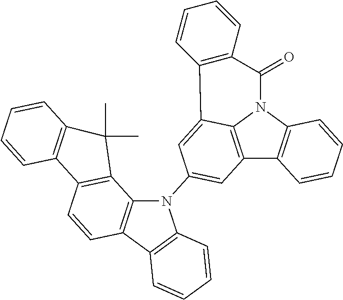 [SMILES: CC1(C)c2ccccc2-c2ccc3c4ccccc4n(-c4cc5c6ccccc6c(=O)n6c7ccccc7c(c4)c56)c3c21]

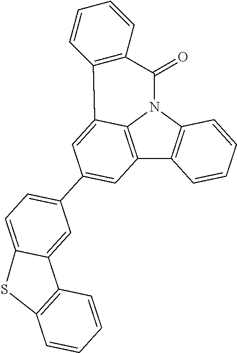 [SMILES: O=c1c2ccccc2c2cc(-c3ccc4sc5ccccc5c4c3)cc3c4ccccc4n1c23]

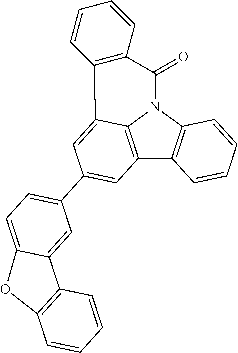 [SMILES: O=c1c2ccccc2c2cc(-c3ccc4oc5ccccc5c4c3)cc3c4ccccc4n1c23]

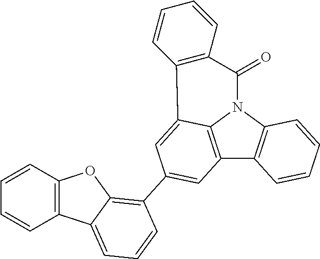 [SMILES: O=c1c2ccccc2c2cc(-c3cccc4c3oc3ccccc34)cc3c4ccccc4n1c23]

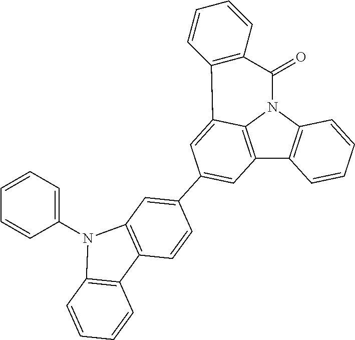 [SMILES: O=c1c2ccccc2c2cc(-c3ccc4c5ccccc5n(-c5ccccc5)c4c3)cc3c4ccccc4n1c23]

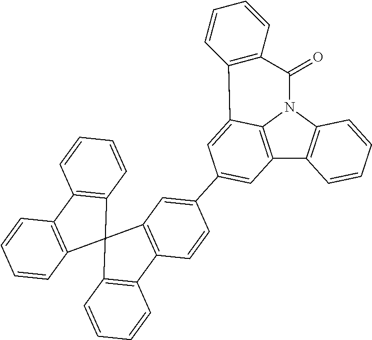 [SMILES: O=c1c2ccccc2c2cc(-c3ccc4c(c3)C3(c5ccccc5-c5ccccc53)c3ccccc3-4)cc3c4ccccc4n1c23]

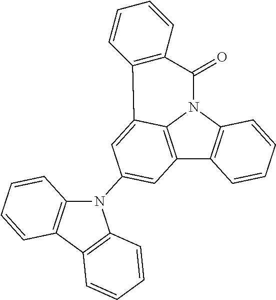 [SMILES: O=c1c2ccccc2c2cc(-n3c4ccccc4c4ccccc43)cc3c4ccccc4n1c23]

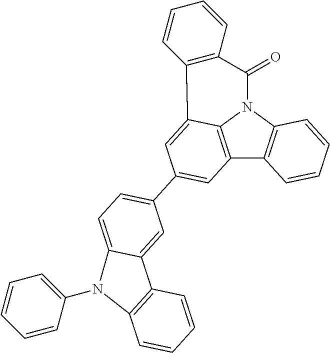 [SMILES: O=c1c2ccccc2c2cc(-c3ccc4c(c3)c3ccccc3n4-c3ccccc3)cc3c4ccccc4n1c23]

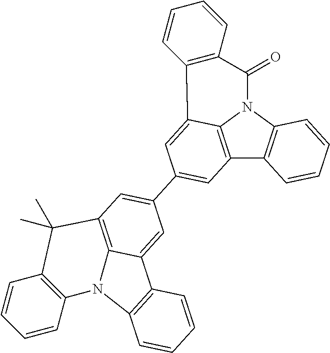 [SMILES: CC1(C)c2ccccc2-n2c3ccccc3c3cc(-c4cc5c6ccccc6c(=O)n6c7ccccc7c(c4)c56)cc1c32]

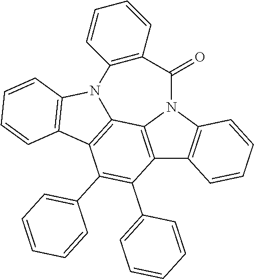 [SMILES: O=c1c2ccccc2n2c3ccccc3c3c(-c4ccccc4)c(-c4ccccc4)c4c5ccccc5n1c4c32]

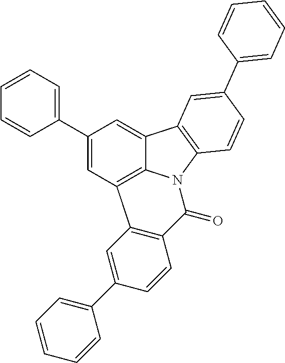 [SMILES: O=c1c2ccc(-c3ccccc3)cc2c2cc(-c3ccccc3)cc3c4cc(-c5ccccc5)ccc4n1c23]

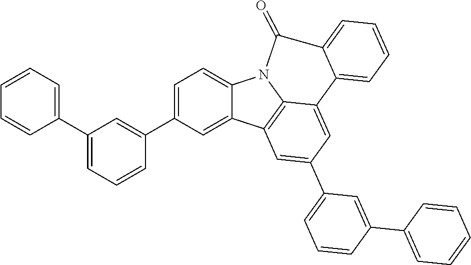 [SMILES: O=c1c2ccccc2c2cc(-c3cccc(-c4ccccc4)c3)cc3c4cc(-c5cccc(-c6ccccc6)c5)ccc4n1c23]

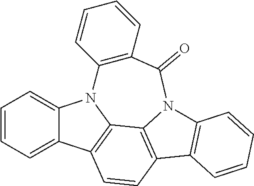 [SMILES: O=c1c2ccccc2n2c3ccccc3c3ccc4c5ccccc5n1c4c32]

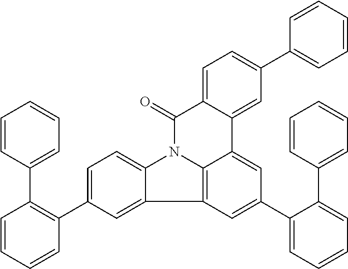 [SMILES: O=c1c2ccc(-c3ccccc3)cc2c2cc(-c3ccccc3-c3ccccc3)cc3c4cc(-c5ccccc5-c5ccccc5)ccc4n1c23]

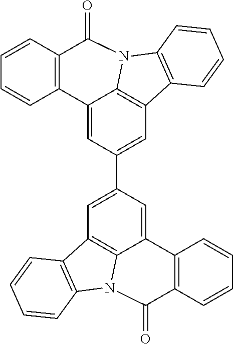 [SMILES: O=c1c2ccccc2c2cc(-c3cc4c5ccccc5c(=O)n5c6ccccc6c(c3)c45)cc3c4ccccc4n1c23]

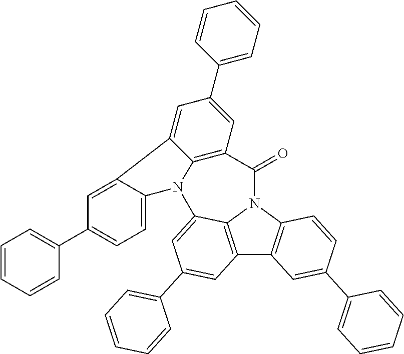 [SMILES: O=c1c2cc(-c3ccccc3)cc3c4cc(-c5ccccc5)ccc4n(c4cc(-c5ccccc5)cc5c6cc(-c7ccccc7)ccc6n1c54)c23]

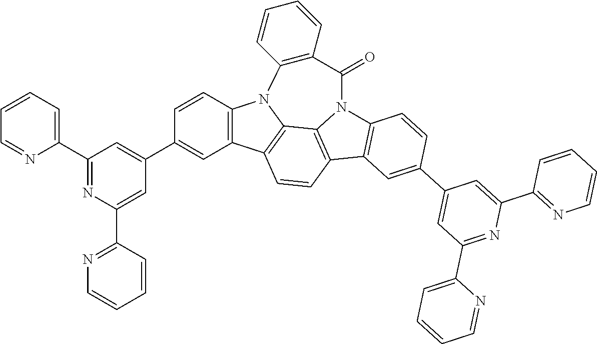 [SMILES: O=c1c2ccccc2n2c3ccc(-c4cc(-c5ccccn5)nc(-c5ccccn5)c4)cc3c3ccc4c5cc(-c6cc(-c7ccccn7)nc(-c7ccccn7)c6)ccc5n1c4c32]

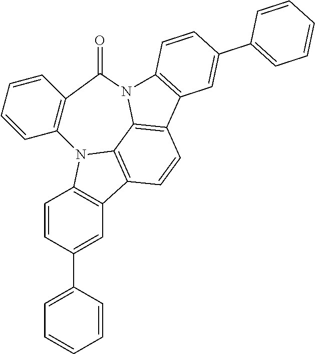 [SMILES: O=c1c2ccccc2n2c3ccc(-c4ccccc4)cc3c3ccc4c5cc(-c6ccccc6)ccc5n1c4c32]

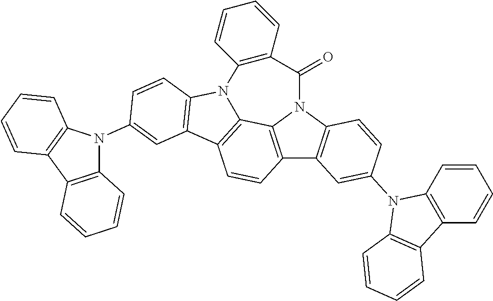 [SMILES: O=c1c2ccccc2n2c3ccc(-n4c5ccccc5c5ccccc54)cc3c3ccc4c5cc(-n6c7ccccc7c7ccccc76)ccc5n1c4c32]

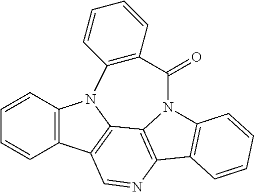 [SMILES: O=c1c2ccccc2n2c3ccccc3c3cnc4c5ccccc5n1c4c32]

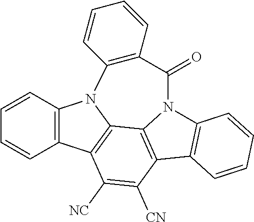 [SMILES: N#Cc1c(C#N)c2c3ccccc3n3c4ccccc4c(=O)n4c5ccccc5c1c4c23]

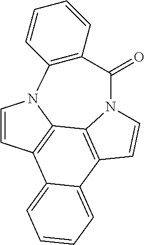 [SMILES: O=c1c2ccccc2n2ccc3c4ccccc4c4ccn1c4c32]

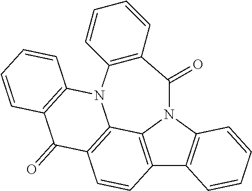 [SMILES: O=c1c2ccccc2n2c3ccccc3c(=O)n3c4ccccc4c4ccc1c2c43]

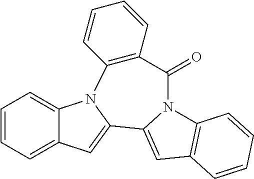 [SMILES: O=c1c2ccccc2n2c3ccccc3cc2c2cc3ccccc3n12]

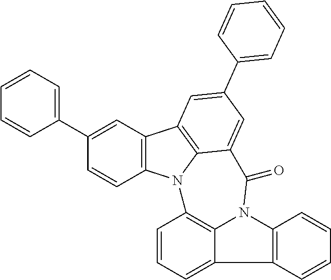 [SMILES: O=c1c2cc(-c3ccccc3)cc3c4cc(-c5ccccc5)ccc4n(c4cccc5c6ccccc6n1c54)c23]

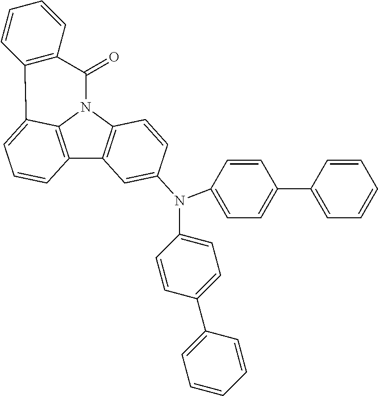 [SMILES: O=c1c2ccccc2c2cccc3c4cc(N(c5ccc(-c6ccccc6)cc5)c5ccc(-c6ccccc6)cc5)ccc4n1c23]

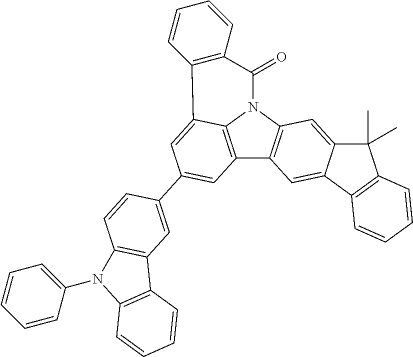 [SMILES: CC1(C)c2ccccc2-c2cc3c4cc(-c5ccc6c(c5)c5ccccc5n6-c5ccccc5)cc5c6ccccc6c(=O)n(c3cc21)c54]

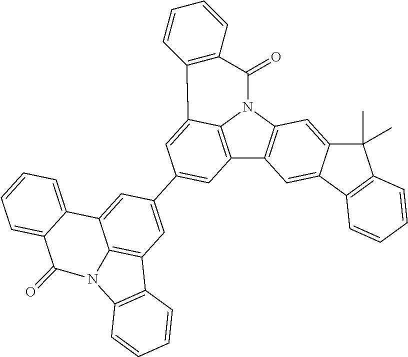 [SMILES: CC1(C)c2ccccc2-c2cc3c4cc(-c5cc6c7ccccc7c(=O)n7c8ccccc8c(c5)c67)cc5c6ccccc6c(=O)n(c3cc21)c54]

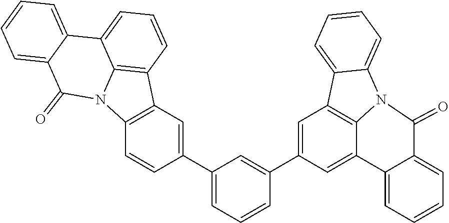 [SMILES: O=c1c2ccccc2c2cccc3c4cc(-c5cccc(-c6cc7c8ccccc8c(=O)n8c9ccccc9c(c6)c78)c5)ccc4n1c23]

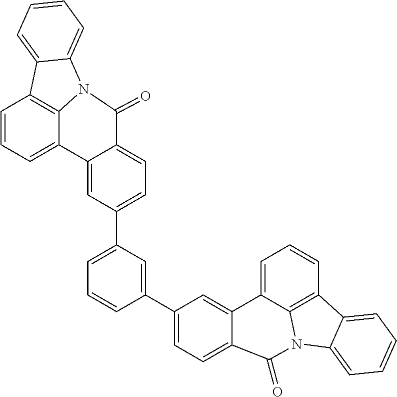 [SMILES: O=c1c2ccc(-c3cccc(-c4ccc5c(=O)n6c7ccccc7c7cccc(c5c4)c76)c3)cc2c2cccc3c4ccccc4n1c23]

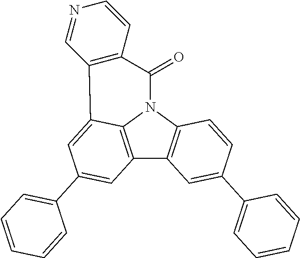 [SMILES: O=c1c2ccncc2c2cc(-c3ccccc3)cc3c4cc(-c5ccccc5)ccc4n1c23]

Furthermore, aromatic ketones or aromatic phosphine oxides are suitable as electron-transporting compound, so long as the LUMO of these compounds is ≦−2.4 eV. An aromatic ketone in the sense of this application is taken to mean a carbonyl group to which two aromatic or heteroaromatic groups or aromatic or heteroaromatic ring systems are bonded directly. An aromatic phosphine oxide in the sense of this application is taken to mean a P═O group to which three aromatic or heteroaromatic groups or aromatic or heteroaromatic ring systems are bonded directly. Examples of suitable ketones and phosphine oxides are revealed by the applications WO 2004/093207, WO 2005/003253 and WO 2010/006680.

Suitable azaphospholes which can be employed as electron-transporting compound in the organic electroluminescent device according to the invention are compounds as disclosed in WO 2010/054730 so long as the LUMO of these compounds is ≦−2.4 eV.

Suitable azaboroles which can be employed as electron-transporting compound in the organic electroluminescent device according to the invention are azaborole derivatives which are substituted by at least one electron-transporting substituent so long as the LUMO of these compounds is ≦−2.4 eV. Compounds of this type are disclosed in WO 2013/091762.

The phosphorescent iridium compound is described in greater detail below.

As described above, the phosphorescent iridium compound contains a group of one of the formulae (1) to (7) shown above.

In the structures of the formulae (1) to (7) and the embodiments of these structures mentioned as preferred below, a double bond is formally depicted between the two carbon atoms. This represents a simplification of the chemical structure if these two carbon atoms are bonded into an aromatic system and the bond between these two carbon atoms is thus formally between the bond order of a single bond and that of a double bond. The drawing-in of the formal double bond should thus not be interpreted as limiting for the structure, but instead it is apparent to the person skilled in the art that this is an aromatic bond.

It is essential in the groups of the formulae (1) to (7) that these do not contain any acidic benzylic protons. Benzylic protons are taken to mean protons which are bonded to a carbon atom which is bonded directly to the ligand. The absence of acidic benzylic protons is achieved in the formulae (1) to (3) through A¹ and A³, if they stand for C(R³)₂, being defined in such a way that R³ is not equal to hydrogen. The absence of acidic benzylic protons is achieved in formulae (4) to (7) through it being a bicyclic structure. Owing to the rigid spatial arrangement, R¹, if it stands for H, is significantly less acidic than benzylic protons, since the corresponding anion of the bicyclic structure is not mesomerism-stabilised. Even if R¹ in formulae (4) to (7) stands for H, this is therefore a non-acidic proton in the sense of the present application.

In a preferred embodiment of the structure of the formulae (1) to (7), a maximum of one of the groups A¹, A² and A³ stands for a heteroatom, in particular for O or NR³, and the other groups stand for C(R³)₂ or C(R¹)₂, or A¹ and A³ stand, identically or differently on each occurrence, for O or NR³ and A² stands for C(R¹)₂. In a particularly preferred embodiment of the invention, A¹ and A³ stand, identically or differently on each occurrence, for C(R³)₂ and A² stands for C(R¹)₂ and particularly preferably for C(R³)₂ or CH₂.

Preferred embodiments of the formula (1) are thus the structures of the formulae (1-A), (1-B), (1-C) and (1-D), and a particularly preferred embodiment of the formula (1-A) are the structures of the formulae (1-E) and (1-F),

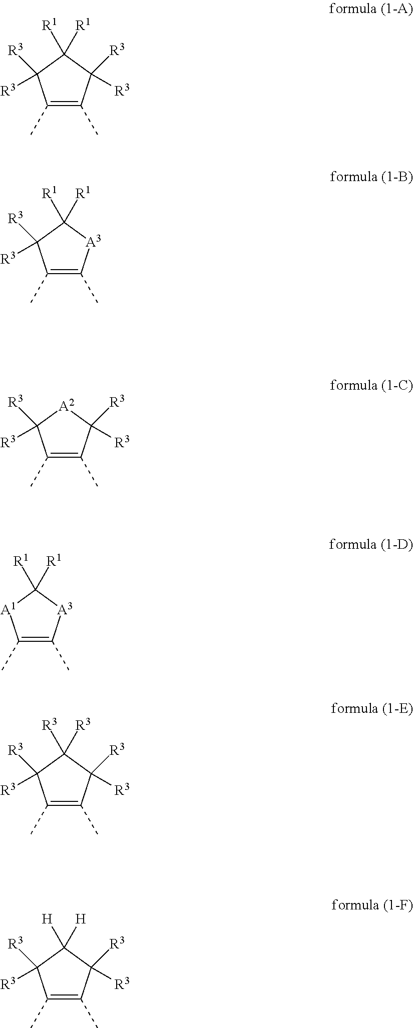

where R¹ and R³ have the meanings given above, and A¹, A² and A³ stand, identically or differently on each occurrence, for O or NR³.

Preferred embodiments of the formula (2) are the structures of the following formulae (2-A) to (2-F),

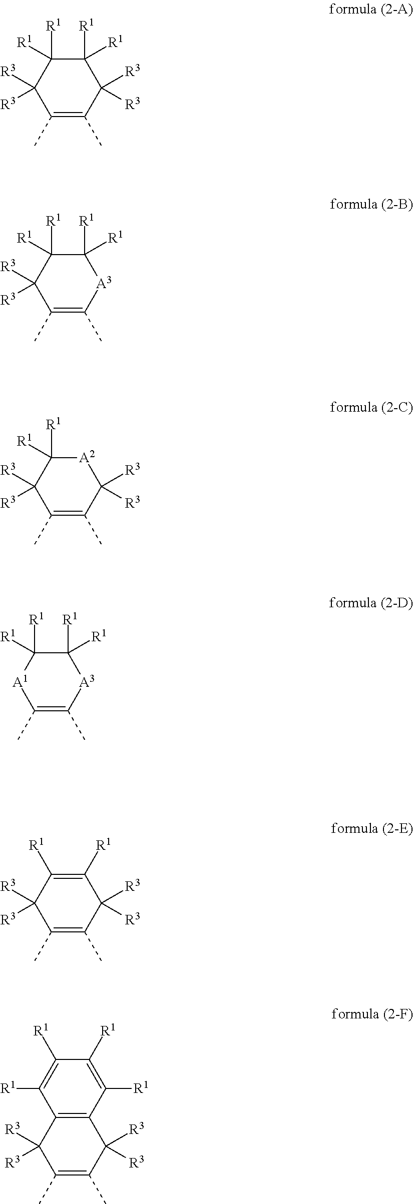

where R¹ and R³ have the meanings given above, and A¹, A² and A³ stand, identically or differently on each occurrence, for O or NR³.

Preferred embodiments of the formula (3) are the structures of the following formulae (3-A) to (3-E),

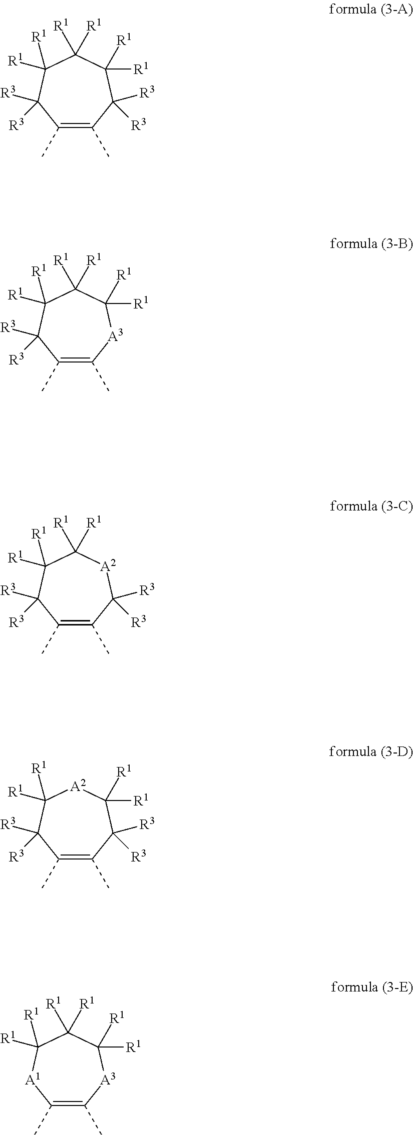

where R¹ and R³ have the meanings given above, and A¹, A² and A³ stand, identically or differently on each occurrence, for O or NR³.

In a preferred embodiment of the structure of the formula (4), the radicals R⁷ which are bonded to the bridgehead stand for H, D, F or CH₃. A² furthermore preferably stands for C(R¹)₂ or O, and particularly preferably for C(R³)₂. Preferred embodiments of the formula (4) are thus the structures of the formulae (4-A) and (4-B), and a particularly preferred embodiment of the formula (4-A) is a structure of the formula (4-C),

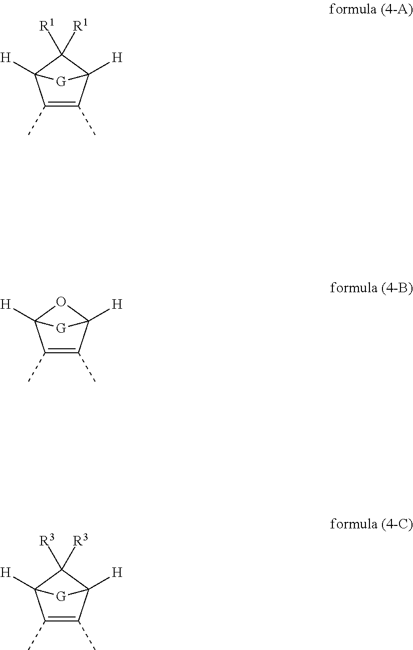

where the symbols used have the meanings given above.

In a preferred embodiment of the structure of the formulae (5), (6) and (7), the radicals R¹ which are bonded to the bridgehead stand for H, D, F or CH₃. Furthermore preferably, A² stands for C(R¹)₂. Preferred embodiments of the formulae (5), (6) and (7) are thus the structures of the formulae (5-A), (6-A) and (7-A),

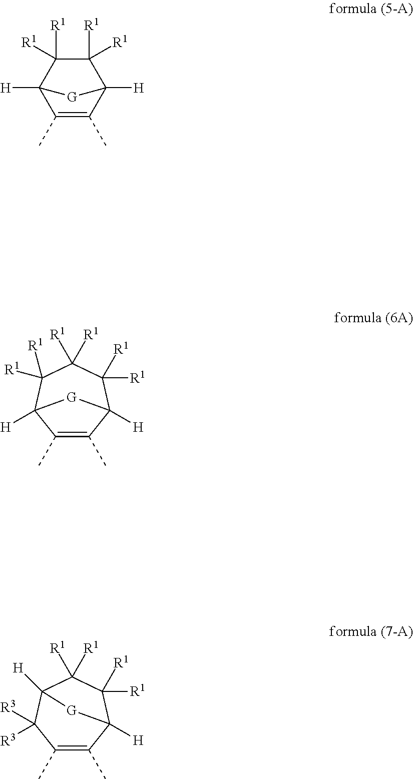

where the symbols used have the meanings given above.

The group G in the formulae (4), (4-A), (4-B), (4-C), (5), (5-A), (6), (6-A), (7) and (7-A) furthermore preferably stands for a 1,2-ethylene group, which may be substituted by one or more radicals R², where R² preferably stands, identically or differently on each occurrence, for H or an alkyl group having 1 to 4 C atoms, or an ortho-arylene group having 6 to 10 C atoms, which may be substituted by one or more radicals R², but is preferably unsubstituted, in particular an ortho-phenylene group, which may be substituted by one or more radicals R², but is preferably unsubstituted.

In a further preferred embodiment of the invention, R³ in the groups of the formulae (1) to (7) and in the preferred embodiments stands, identically or differently on each occurrence, for F, a straight-chain alkyl group having 1 to 10 C atoms or a branched or cyclic alkyl group having 3 to 10 C atoms, where in each case one or more non-adjacent CH₂ groups may be replaced by R²C═CR² and one or more H atoms may be replaced by D or F, or an aromatic or heteroaromatic ring system having 5 to 14 aromatic ring atoms, which may in each case be substituted by one or more radicals R²; two radicals R³ here which are bonded to the same carbon atom may form an aliphatic or aromatic ring system with one another and thus form a spiro system; furthermore, R³ may form an aliphatic ring system with an adjacent radical R or R¹.

In a particularly preferred embodiment of the invention, R³ in the groups of the formulae (1) to (7) and in the preferred embodiments stands, identically or differently on each occurrence, for F, a straight-chain alkyl group having 1 to 3 C atoms, in particular methyl, or an aromatic or heteroaromatic ring system having 5 to 12 aromatic ring atoms, each of which may be substituted by one or more radicals R², but is preferably unsubstituted; two radicals R³ here which are bonded to the same carbon atom may form an aliphatic or aromatic ring system with one another and thus form a spiro system; furthermore, R³ may form an aliphatic ring system with an adjacent radical R or R¹. If two radicals R³ which are bonded to the same carbon atom form an aliphatic ring system with one another, this is preferably a cyclopentyl group or a cyclohexyl group.

Examples of particularly suitable groups of the formula (1) are the groups (1-1) to (1-69) shown below:

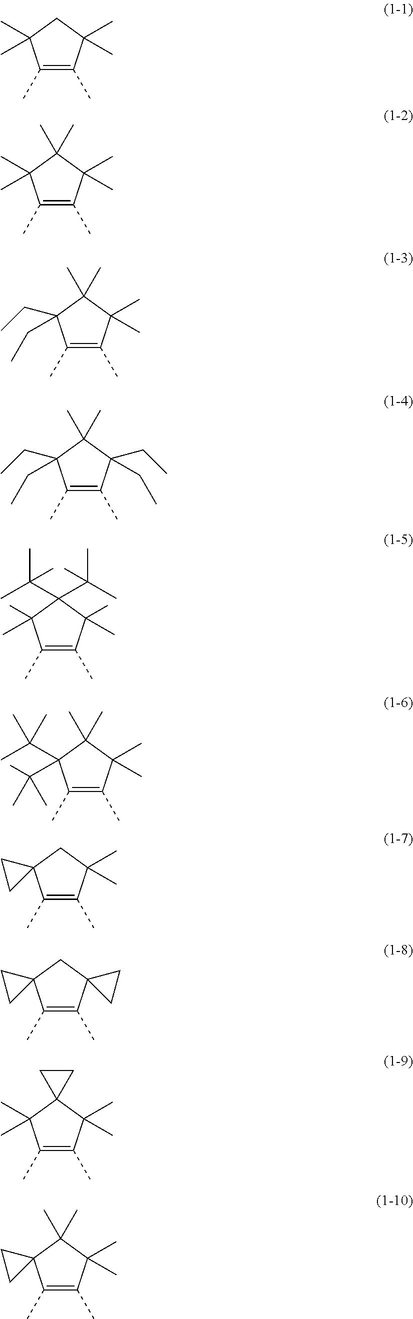

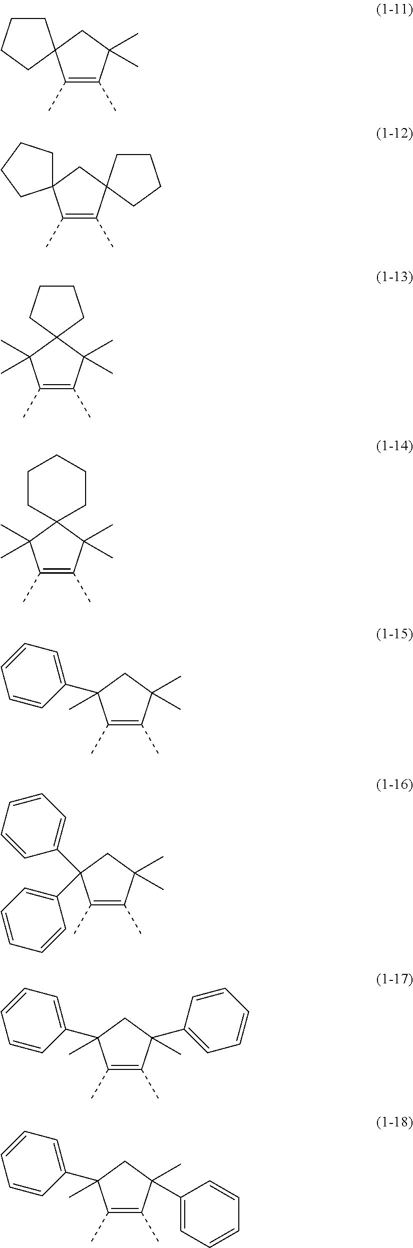

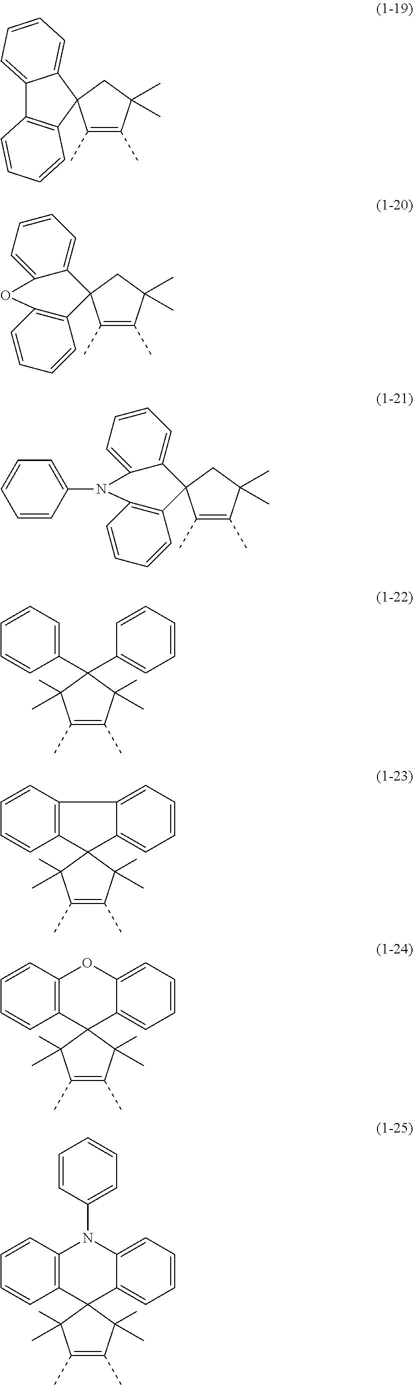

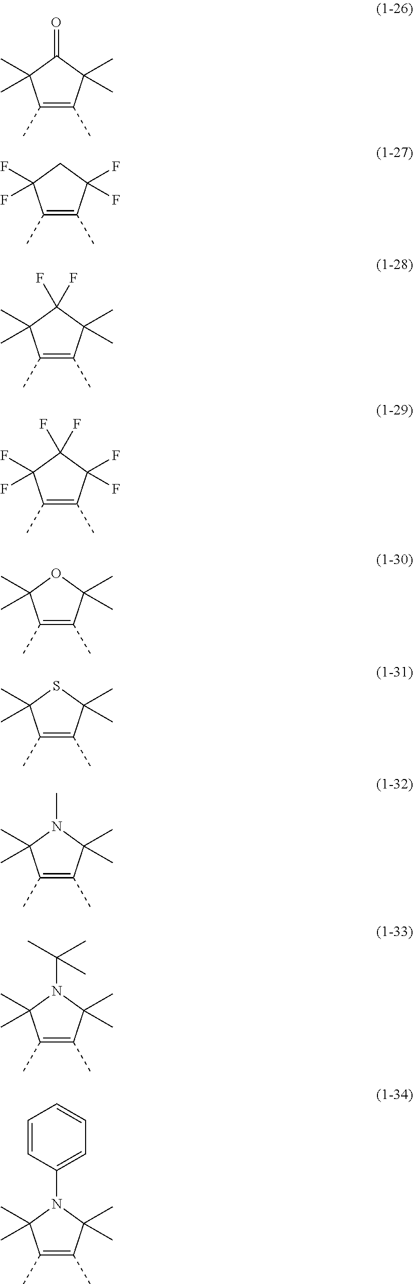

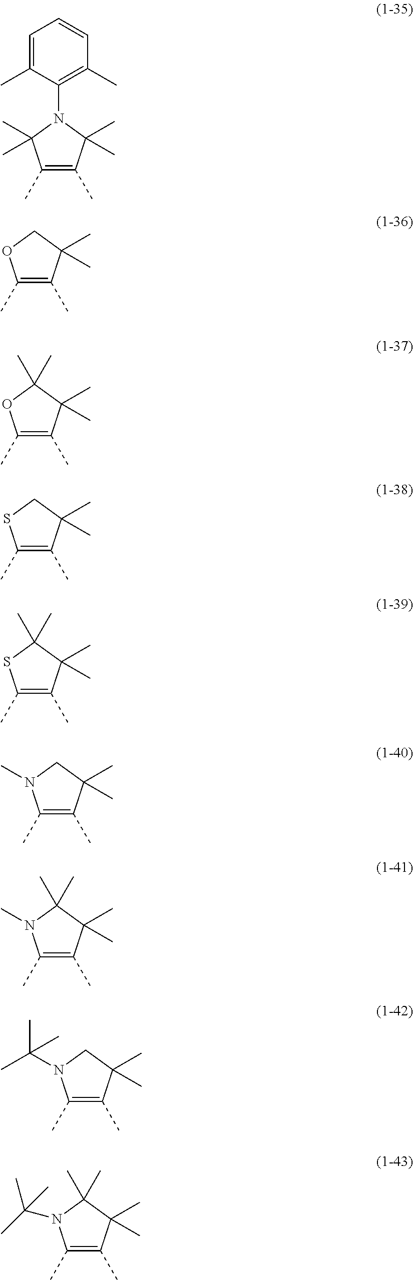

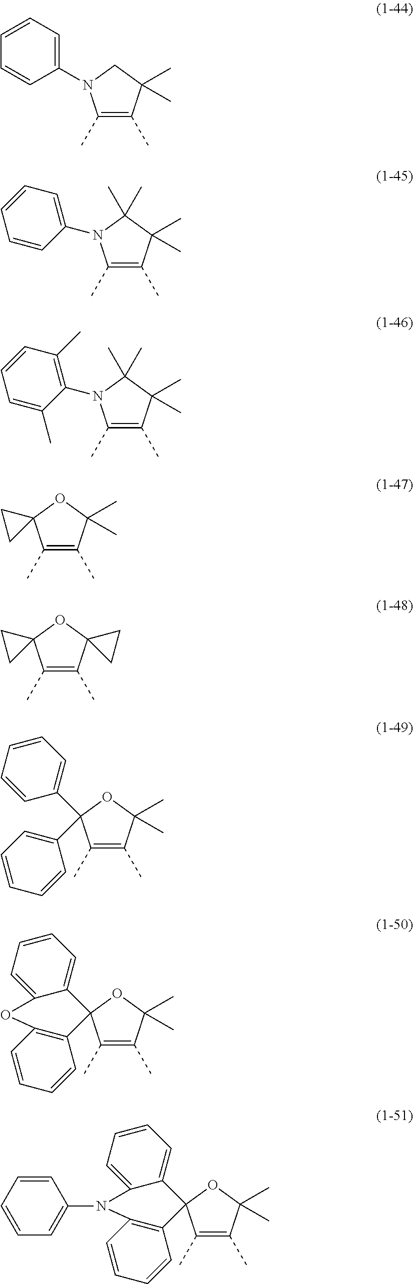

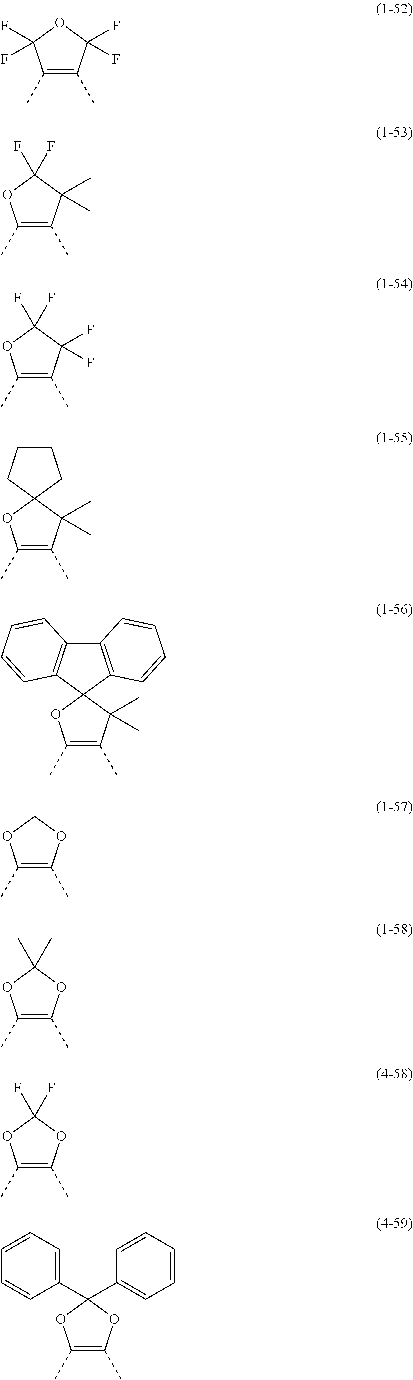

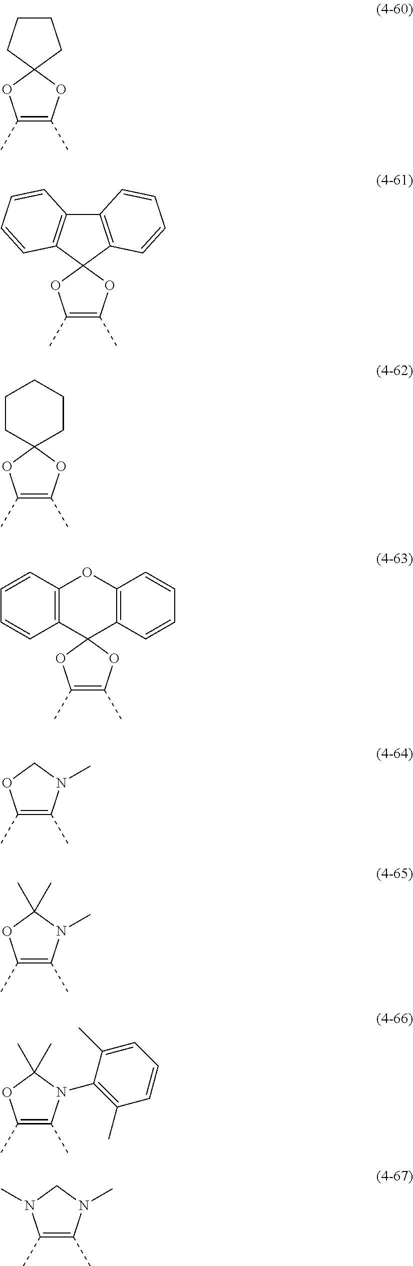

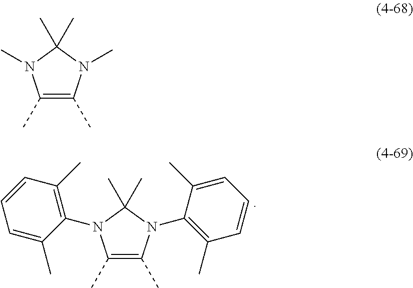

Examples of particularly suitable groups of the formula (2) are the groups (2-1) to (2-14) shown below:

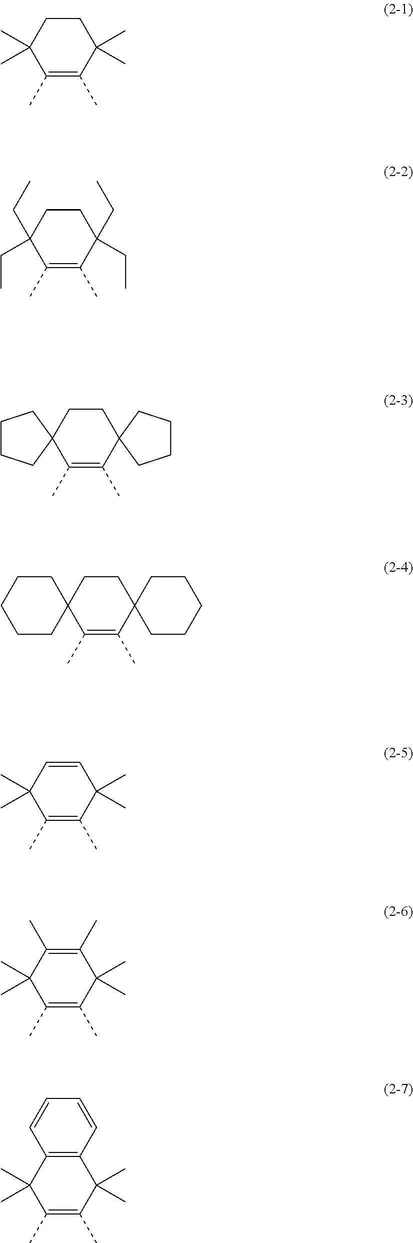

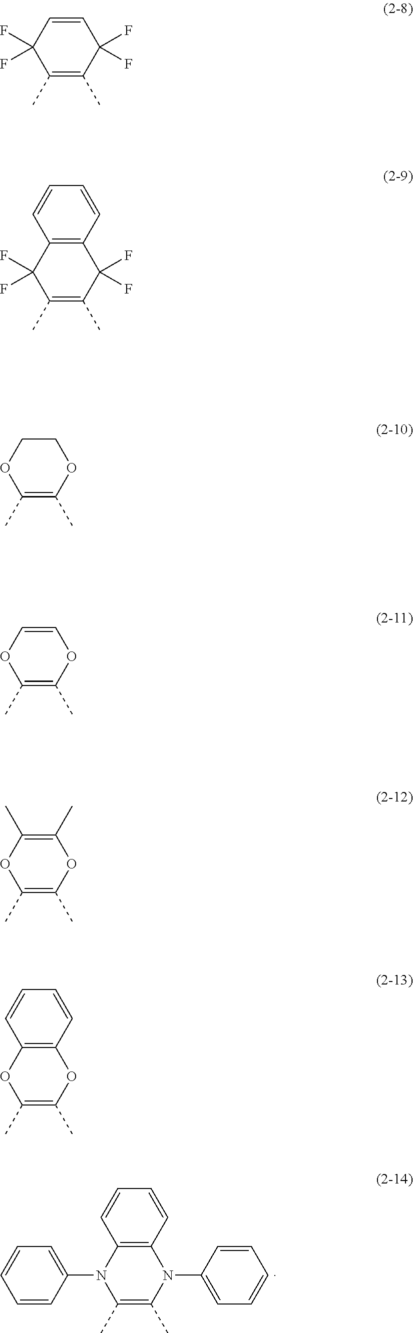

Examples of particularly suitable groups of the formulae (3), (6) and (7) are the groups (3-1), (6-1), (7-1) and (7-2) shown below:

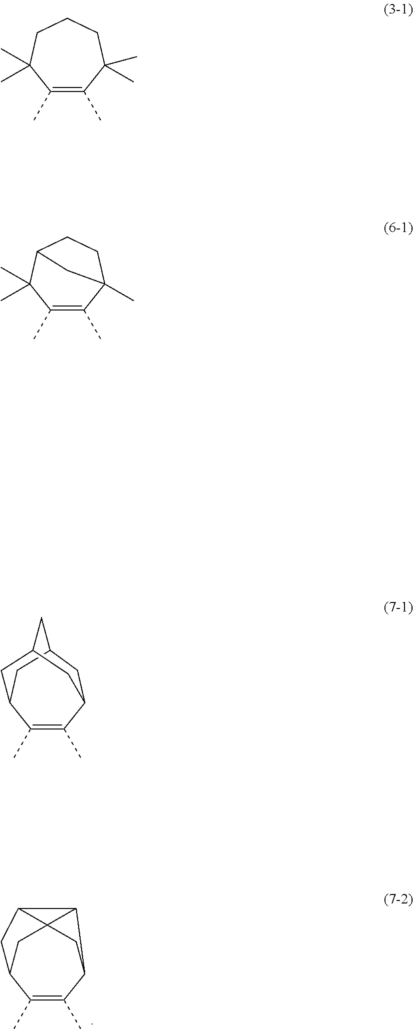

Examples of particularly suitable groups of the formula (4) are the groups (4-1) to (4-22) shown below:

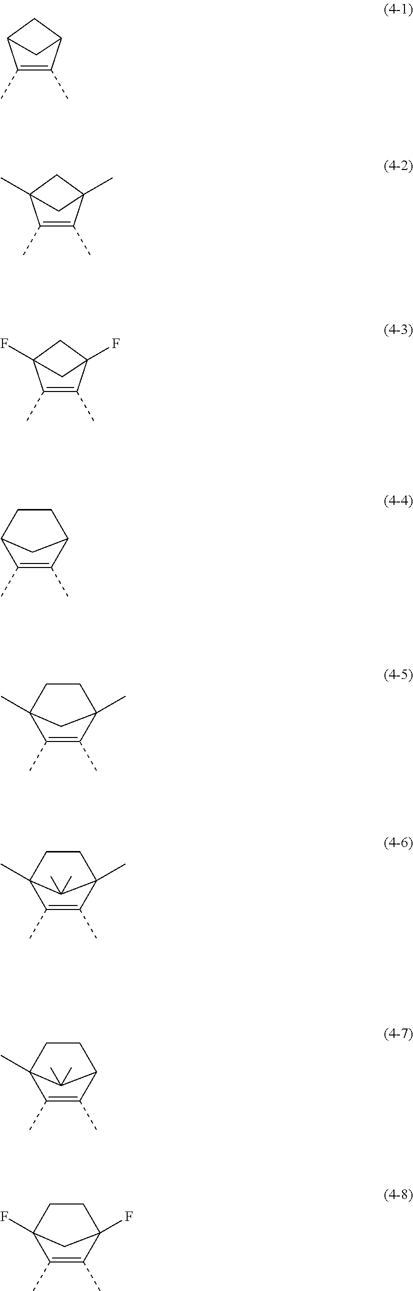

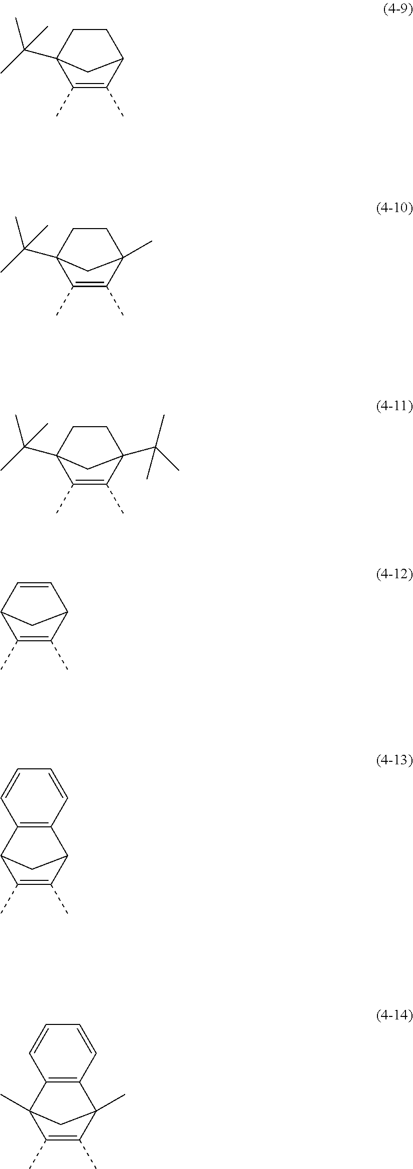

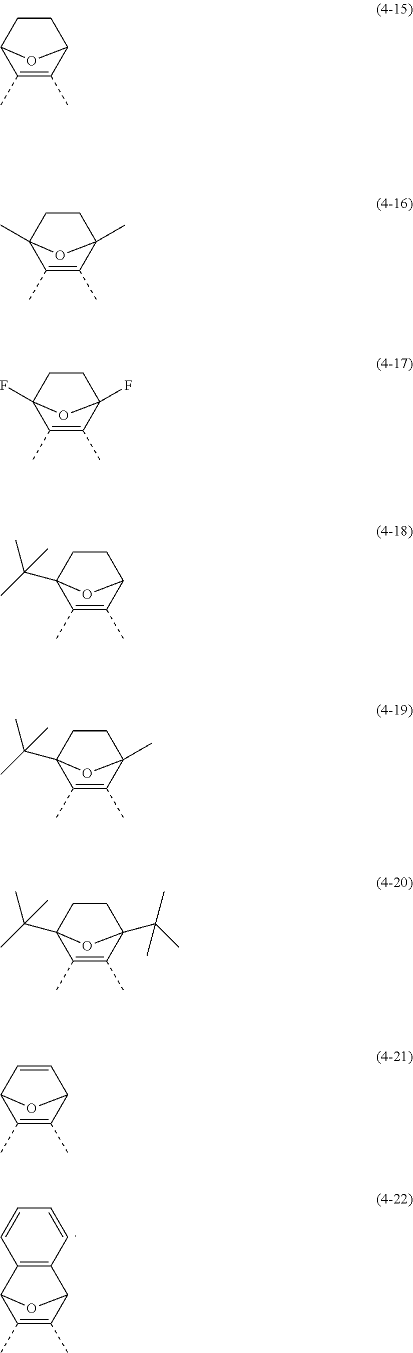

Examples of particularly suitable groups of the formula (5) are the groups (5-1) to (5-5) shown below:

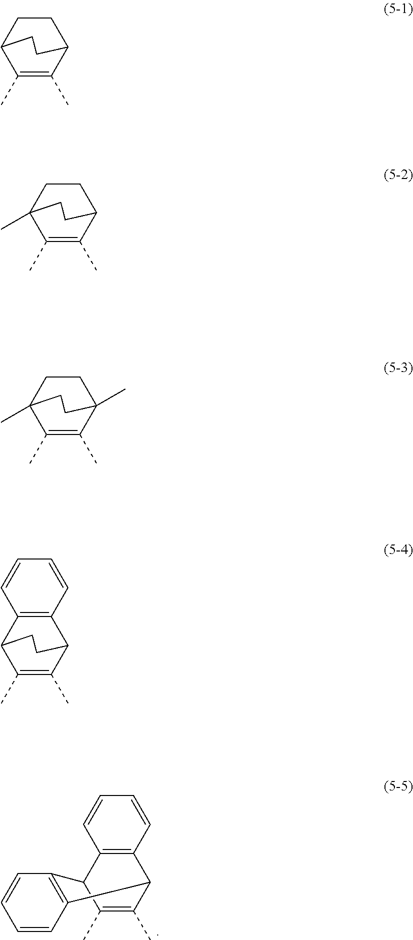

In particular, the use of condensed-on bicyclic structures of this type may also result in chiral ligands L owing to the chirality of the structures. Both the use of enantiomerically pure ligands and also the use of the racemate may be suitable here. It may also be suitable, in particular, to use not only one enantiomer of a ligand in the metal complex, but intentionally both enantiomers. This may have advantages with respect to the solubility of the corresponding complex compared with complexes which contain only one or other enantiomer of the ligand.

As described above, the phosphorescent iridium compound contains at least one ligand which is at least bidentate and which is bonded to the iridium via one carbon atom and one nitrogen atom or via two carbon atoms and which contains at least one of the groups (1) to (7) shown above. The ligands are preferably anionic ligands, which may be monoanionic or polyanionic. In the case of bidentate ligands, preference is given to monoanionic ligands. The iridium compound particularly preferably contains three bidentate, monoanionic ligands, at least two of which are coordinated via one carbon atom and one nitrogen atom or via two carbon atoms; the ligands here may also be connected via a linking group to form a polypodal ligand.

In a preferred embodiment of the invention, the phosphorescent iridium compound is a compound of the following formula (75),

Ir(L¹)ₚ(L²)_{q} formula (75)

where the following applies to the symbols and indices used:
L¹ is a bidentate monoanionic ligand which contains at least one aryl or heteroaryl group which is bonded to the iridium via a carbon or nitrogen atom and which contains a group of one of the formulae (1) to (7);
L² is, identically or differently on each occurrence, a monoanionic bidentate ligand;
p is 1, 2 or 3;
q is (3−p).

The ligands L¹ and L² here may also be connected via a linking group to form a polypodal ligand.

Preferred ligands L¹ are described below. In an embodiment of the invention, the structure Ir(L¹)ₚ is a structure of the following formula (76):

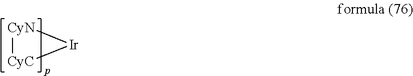

where R and p have the meanings given above and the following applies to the symbols and indices used:
CyC is an aryl or heteroaryl group having 5 to 18 aromatic ring atoms or a fluorene group, each of which is coordinated to Ir via a carbon atom and each of which may be substituted by one or more radicals R and each of which is connected to CyN via a covalent bond;
CyN is a heteroaryl group having 5 to 18 aromatic ring atoms which is coordinated to Ir via a neutral nitrogen atom or via a carbene carbon atom and which may be substituted by one or more radicals R and which is connected to CyC via a covalent bond;

CyC and CyN here may also be linked to one another via a group selected from C(R¹)═C(R¹), C(R¹)₂, C(R¹)₂—C(R¹)₂—, NR¹, O or S;

two directly adjacent radicals R on CyC and/or on CyN, together with the carbon atoms to which they are bonded, form a group of one of the formulae (1) to (7) shown above.

In a preferred embodiment of the present invention, CyC is an aryl or heteroaryl group having 5 to 14 aromatic ring atoms, particularly preferably 6 to 13 aromatic ring atoms, very particularly preferably having 6 to 10 aromatic ring atoms, especially preferably having 6 aromatic ring atoms, which is coordinated to Ir via a carbon atom and which may be substituted by one or more radicals R and which is connected to CyN via a covalent bond.

Preferred embodiments of the group CyC are the structures of the following formulae (CyC-1) to (CyC-19), where the group CyC is in each case bonded to CyN at the position denoted by # and is coordinated to the metal M at the position denoted by *,

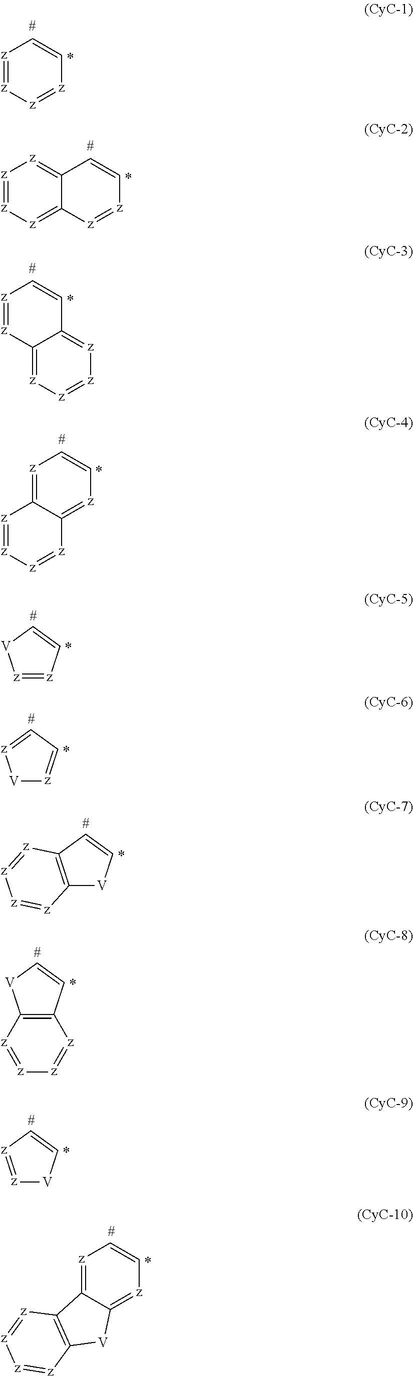

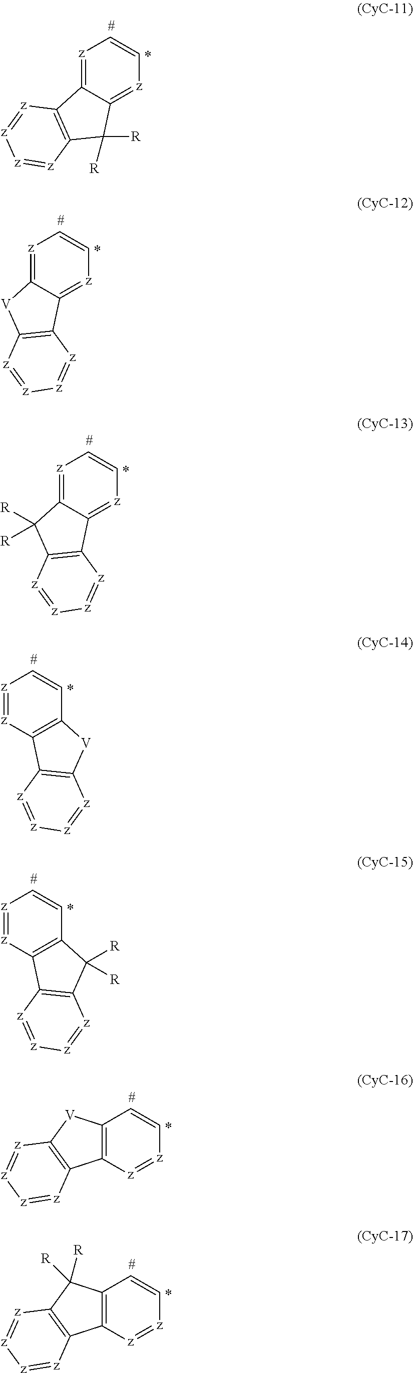

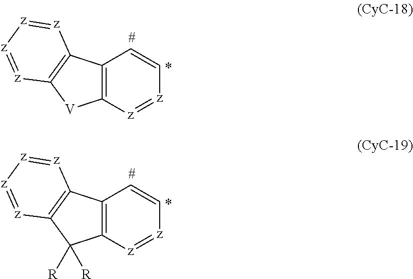

where R has the meanings given above and the following applies to the other symbols used:

Z is on each occurrence, identically or differently, CR or N;

V is on each occurrence, identically or differently, NR, O or S.

If the group of one of the formulae (1) to (7) is bonded to CyC, two adjacent groups Z in CyC stand for CR and, together with the radicals R which are bonded to these carbon atoms, form a group of one of the formulae (1) to (7) shown above.

Preferably a maximum of three symbols Z in CyC stand for N, particularly preferably a maximum of two symbols Z in CyC stand for N, very particularly preferably a maximum of one symbol Z in CyC stands for N. Especially preferably all symbols Z stand for CR.

Particularly preferred groups CyC are the groups of the following formulae (CyC-1a) to (CyC-19a),

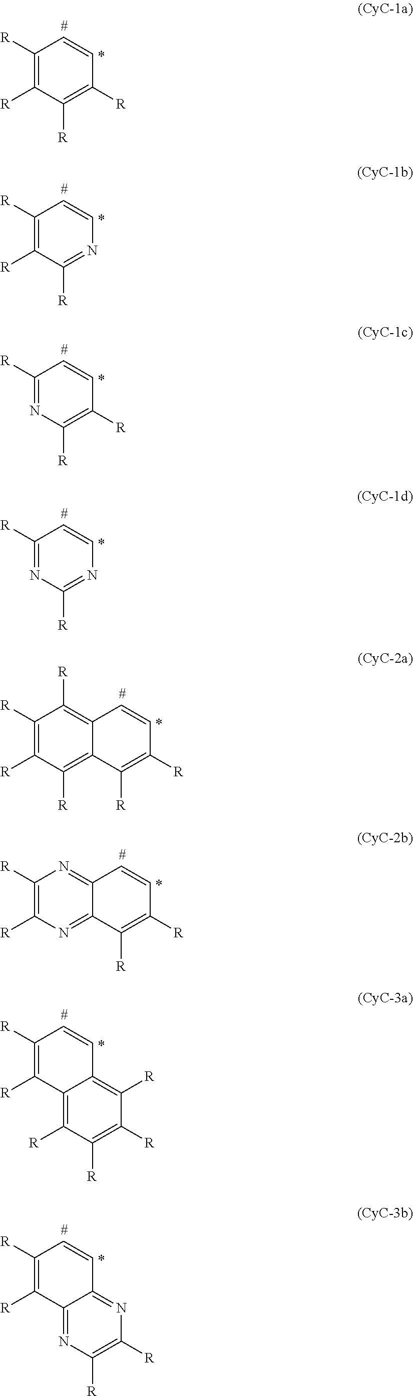

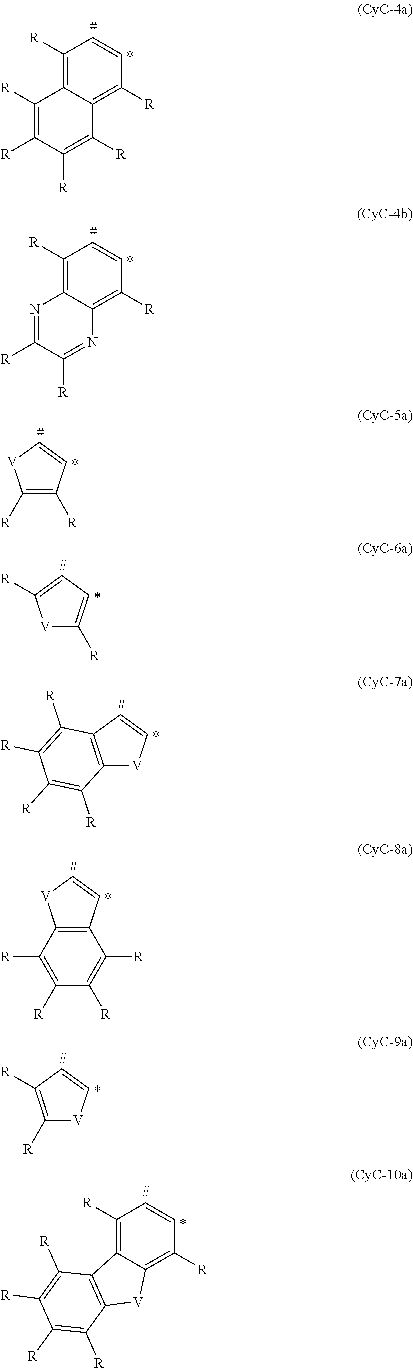

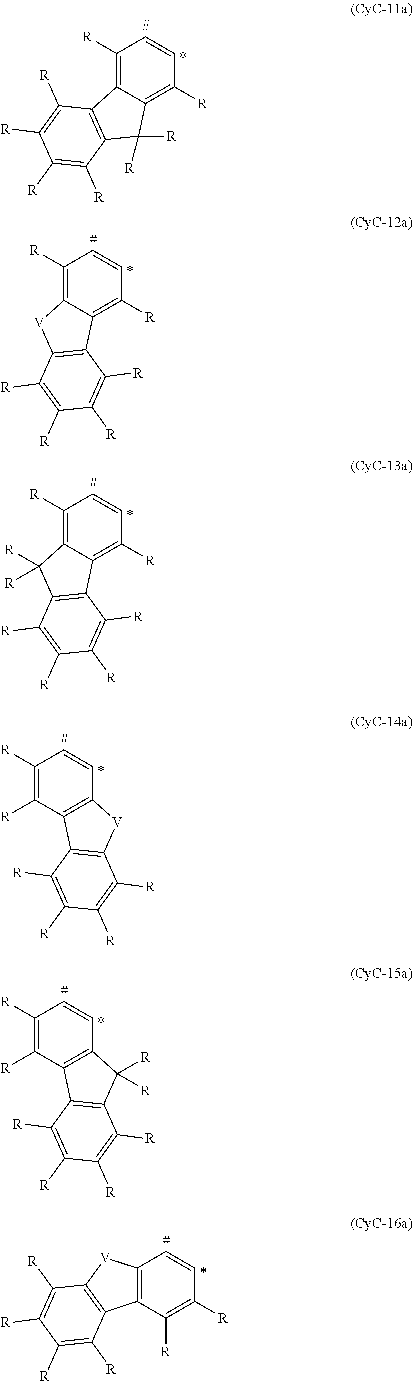

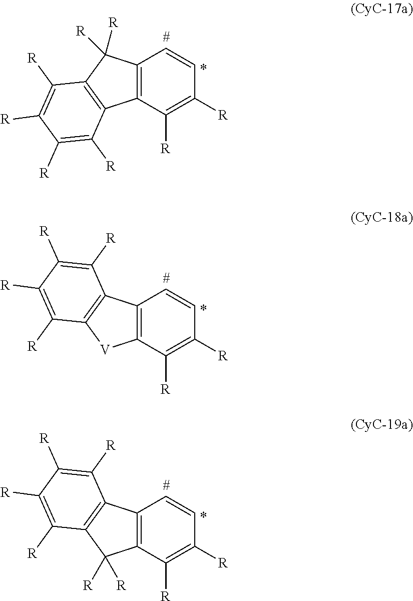

where the symbols used have the meanings given above. If the group of one of the formulae (1) to (7) is present on CyC, two adjacent radicals R, together with the carbon atoms to which they are bonded, form a ring of one of the formulae (1) to (7).

Preferred groups amongst the groups (CyC-1) to (CyC-19) are the groups (CyC-1), (CyC-3), (CyC-8), (CyC-10), (CyC-12), (CyC-13) and (CyC-16), and particular preference is given to the groups (CyC-1a), (CyC-3a), (CyC-8a), (CyC-10a), (CyC-12a), (CyC-13a) and (CyC-16a).

In a further preferred embodiment of the invention, CyN is a heteroaryl group having 5 to 13 aromatic ring atoms, particularly preferably having 5 to 10 aromatic ring atoms, which is coordinated to M via a neutral nitrogen atom or via a carbene carbon atom and which may be substituted by one or more radicals R and which is connected to CyC via a covalent bond.

Preferred embodiments of the group CyN are the structures of the following formulae (CyN-1) to (CyN-10), where the group CyN is in each case bonded to CyC at the position denoted by # and is coordinated to the metal M at the position denoted by *,

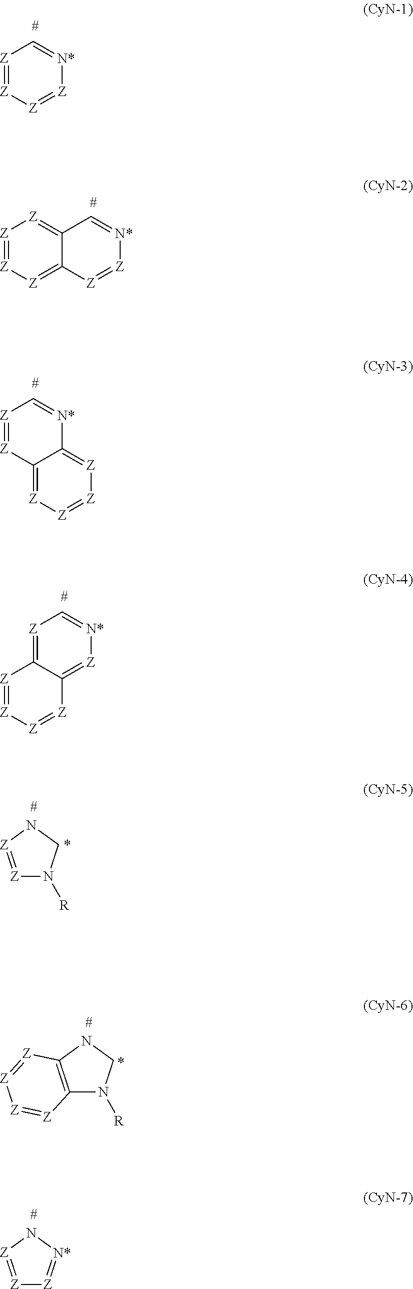

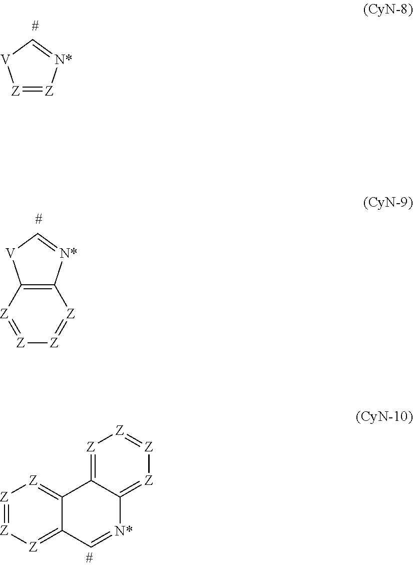

where Z, V and R have the meanings given above.

If the group of one of the formulae (1) to (7) is bonded to CyN, two adjacent groups Z in CyN stand for CR and, together with the radicals R which are bonded to these carbon atoms, form a group of one of the formulae (1) to (7) shown above.

Preferably a maximum of three symbols Z in CyN stand for N, particularly preferably a maximum of two symbols Z in CyN stand for N, very particularly preferably a maximum of one symbol Z in CyN stands for N. Especially preferably all symbols Z stand for CR.

Particularly preferred groups CyN are the groups of the following formulae (CyN-1a) to (CyN-10a),

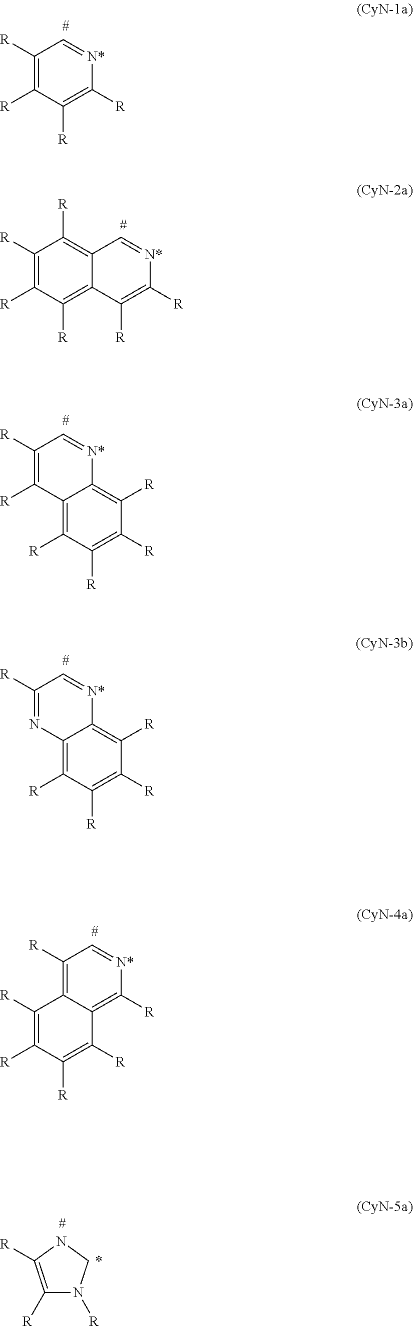

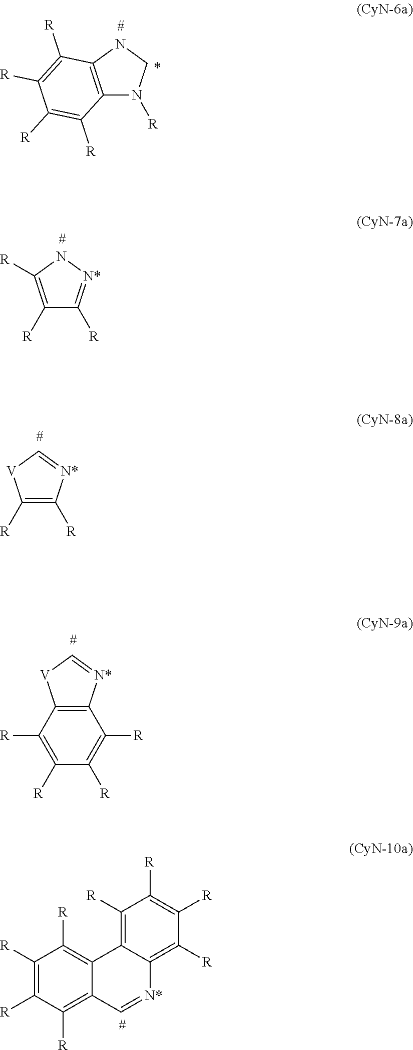

where the symbols used have the meanings given above. If the group of one of the formulae (1) to (7) is present on CyN, two adjacent radicals R, together with the carbon atoms to which they are bonded, form a ring of one of the formulae (1) to (7).

Preferred groups amongst the groups (CyN-1) to (CyN-10) are the groups (CyN-1), (CyN-3), (CyN-4), (CyN-5) and (CyN-6), and particular preference is given to the groups (CyN-1a), (CyN-3a), (CyN-4a), (CyN-5a) and (CyN-6a).

In a preferred embodiment of the present invention, CyC is an aryl or heteroaryl group having 5 to 14 aromatic ring atoms and at the same time CyN is a heteroaryl group having 5 to 13 aromatic ring atoms. Particularly preferably, CyC is an aryl or heteroaryl group having 6 to 13 aromatic ring atoms, preferably having 6 to 10 aromatic ring atoms, in particular having 6 aromatic ring atoms, and at the same time CyN is a heteroaryl group having 5 to 10 aromatic ring atoms. CyC and CyN here may be substituted by one or more radicals R. The above-mentioned preferred groups CyC and CyN can be combined with one another as desired.

In a preferred embodiment of the invention, the ligand contains either precisely one group of one of the formulae (1) to (7), or it contains two groups of one or more of the formulae (1) to (7), one of which is bonded to CyC and the other of which is bonded to CyN. In a particularly preferred embodiment, the ligand L contains precisely one group of one of the formulae (1) to (7). This group may be present here either on CyC or on CyN, where it may be bonded to CyC or CyN in any possible position. This group is preferably bonded to CyC.

In the following groups (CyC-1-1) to (CyC-19-1) and (CyN-1-1) to (CyN-10-4), the preferred positions for adjacent groups Z which stand for CR are depicted in each case, where the respective radicals R, together with the C atoms to which they are bonded, form a ring of one of the formulae (1) to (7) shown above,

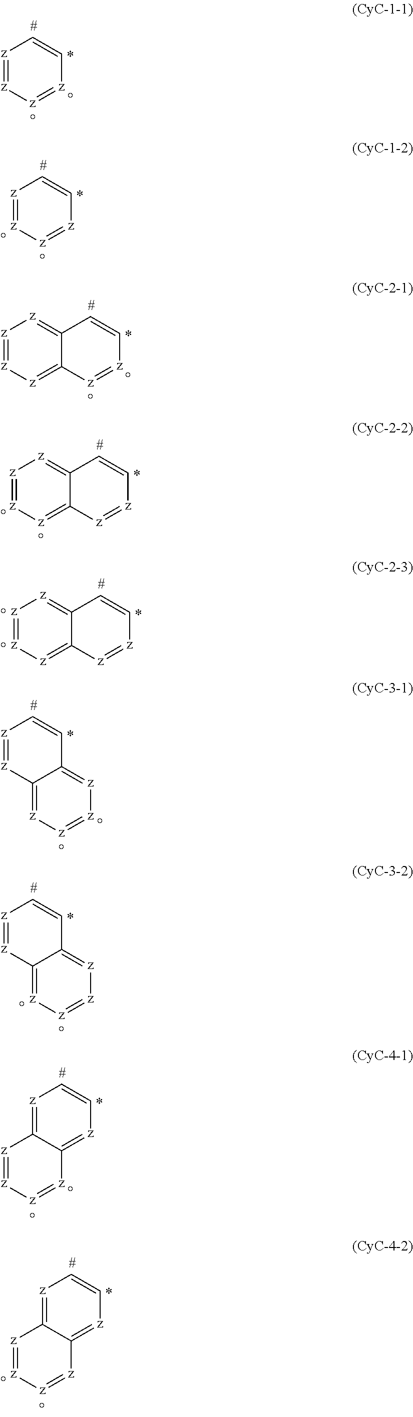

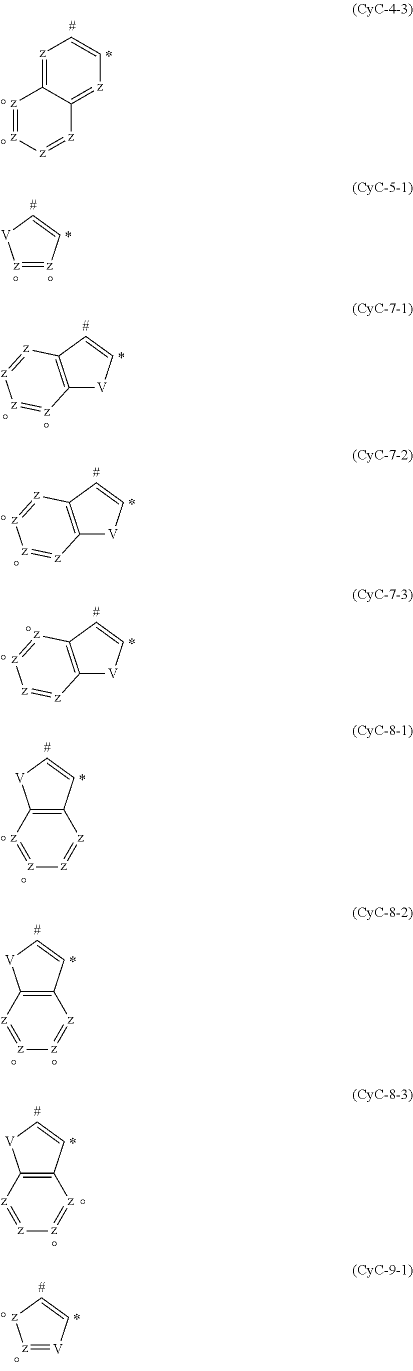

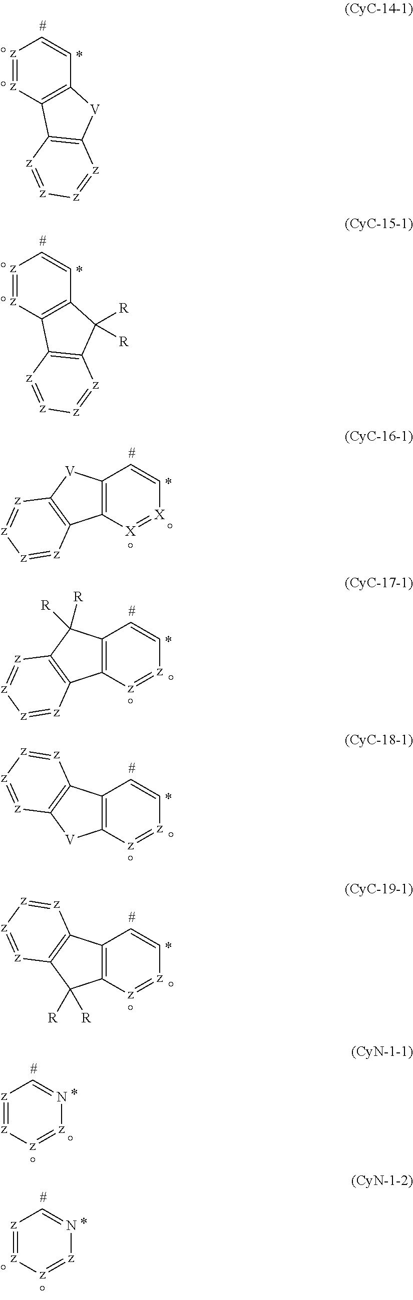

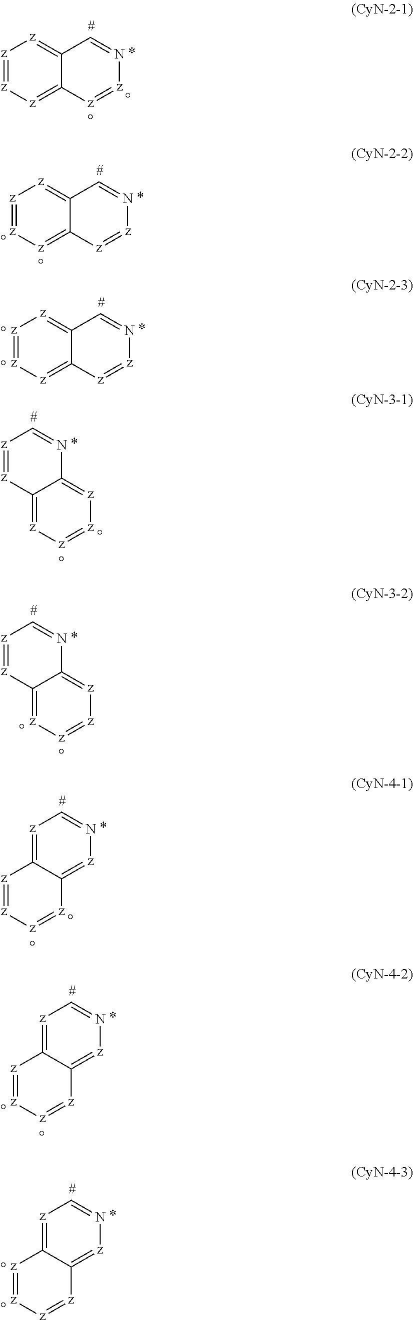

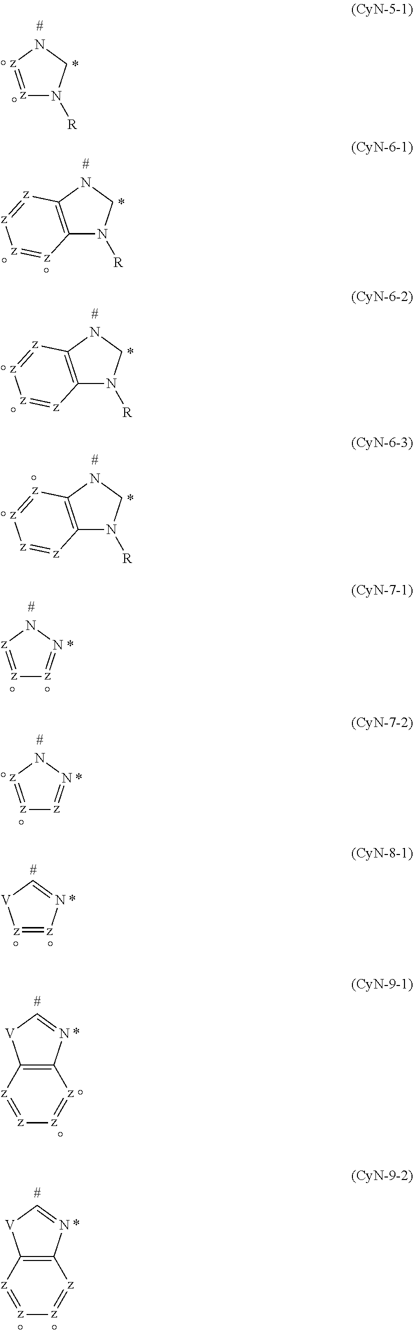

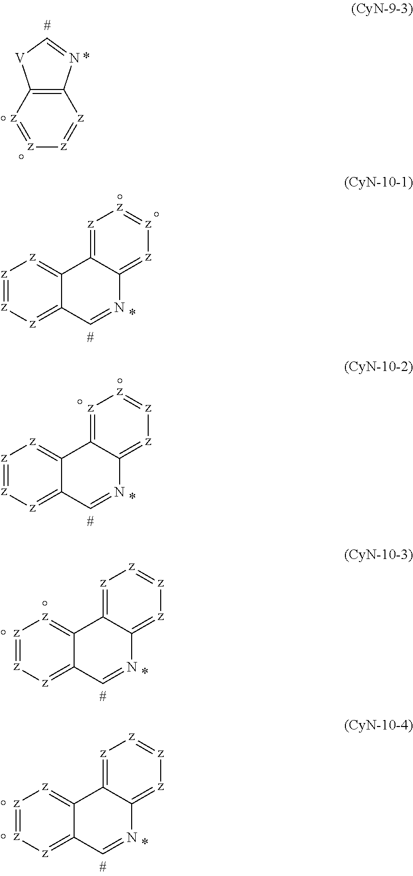

where the symbols used have the meanings given above and ° in each case denotes the positions which stand for CR, where the respective radicals R, together with the C atoms to which they are bonded, form a ring of one of the formulae (1) to (7) shown above.

In a further embodiment of the invention, the group of the formula Ir(L¹)ₚ is a group of the following formula (77),

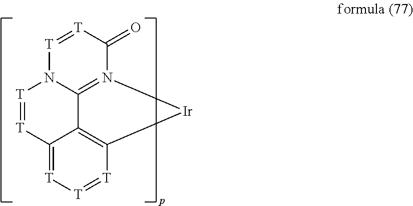

where the following applies to the symbols and indices used:
T is on each occurrence, identically or differently, CR or N, with the proviso that a maximum of one symbol T per ring stands for N, or two adjacent symbols T together stand for a group of the following formula (78),

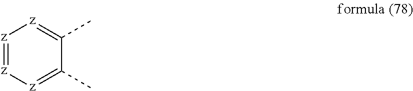

where the dashed bonds symbolise the linking of this group in the ligand;
Z is on each occurrence, identically or differently, CR or N, with the proviso that a maximum of two symbols Z per ligand stand for N;

characterised in that adjacent groups T or Z stand for CR and the respective radicals R, together with the C atoms, form a ring of one of the formulae (1) to (7).

In a further preferred embodiment of the invention, a maximum of one group of the formula (78) is present in the compounds according to the invention. These are thus preferably compounds of the following formulae (79), (80), (81) or (82),

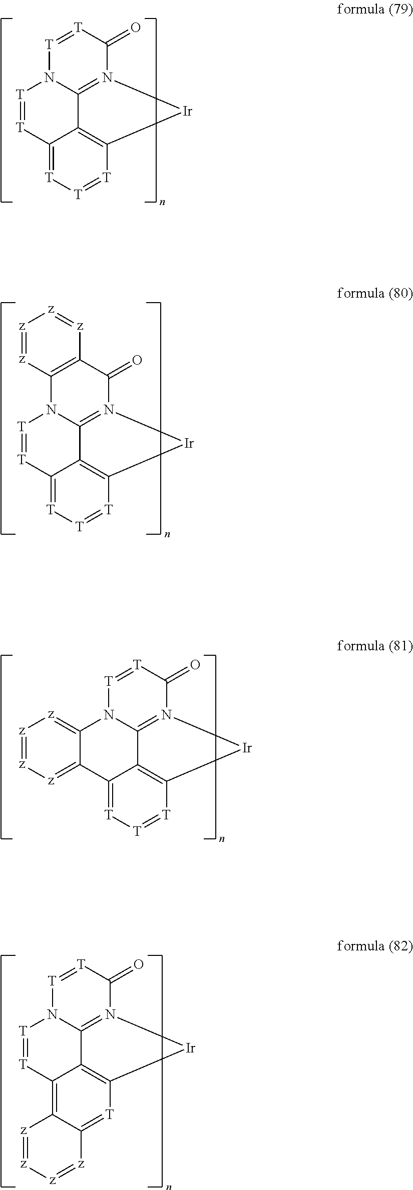

where T stands on each occurrence, identically or differently, for CR or N and the other symbols and indices have the meanings given above.

In a preferred embodiment of the invention, a total of 0, 1 or 2 of the symbols T and, if present, Z in the above-mentioned ligand L¹ stand for N. Particularly preferably, a total of 0 or 1 of the symbols T and, if present, Z in the ligand L¹ stands for N. Especially preferably, the symbols T in the ring which is coordinated to the iridium via the carbon atom stand, identically or differently on each occurrence, for CR.

Preferred embodiments of the formula (79) are the structures of the following formulae (79-1) to (79-5), preferred embodiments of the formula (80) are the structures of the following formulae (80-1) to (80-8), preferred embodiments of the formula (81) are the structures of the following formulae (81-1) to (81-8), and preferred embodiments of the formula (82) are the structures of the following formulae (82-1) to (82-7),

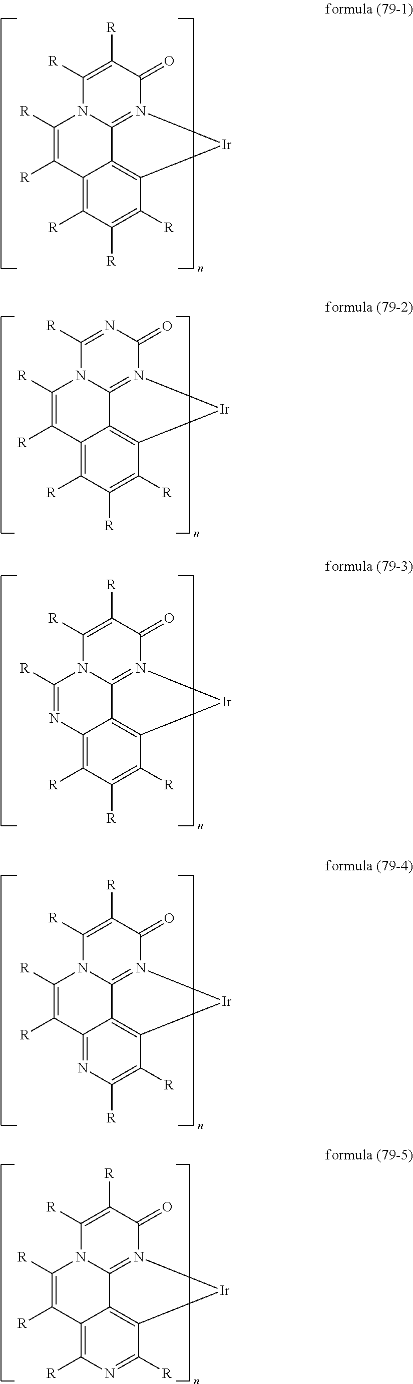

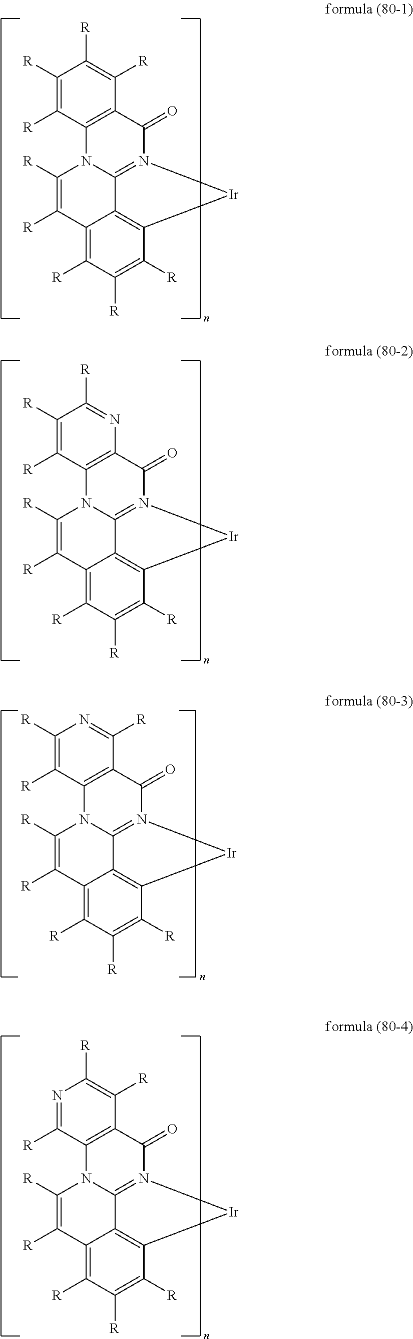

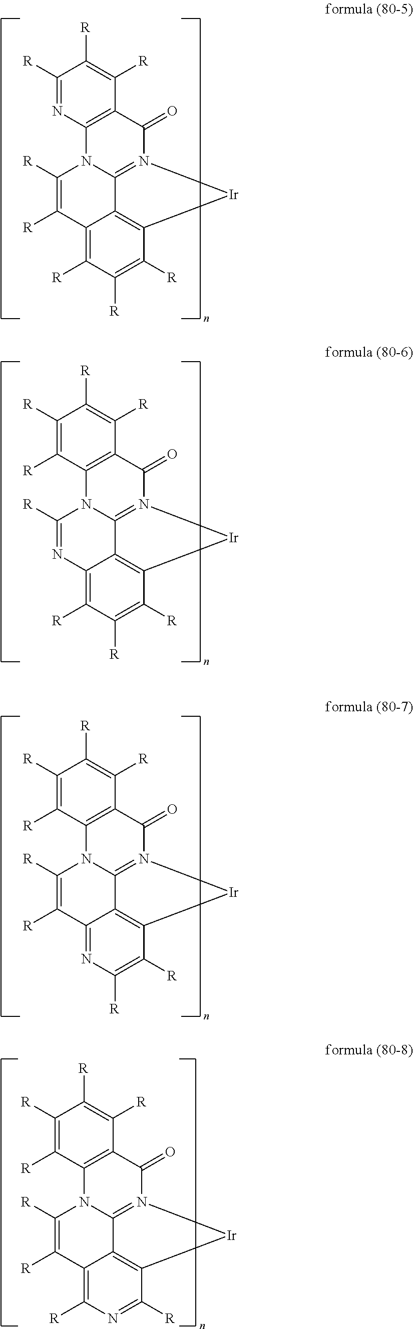

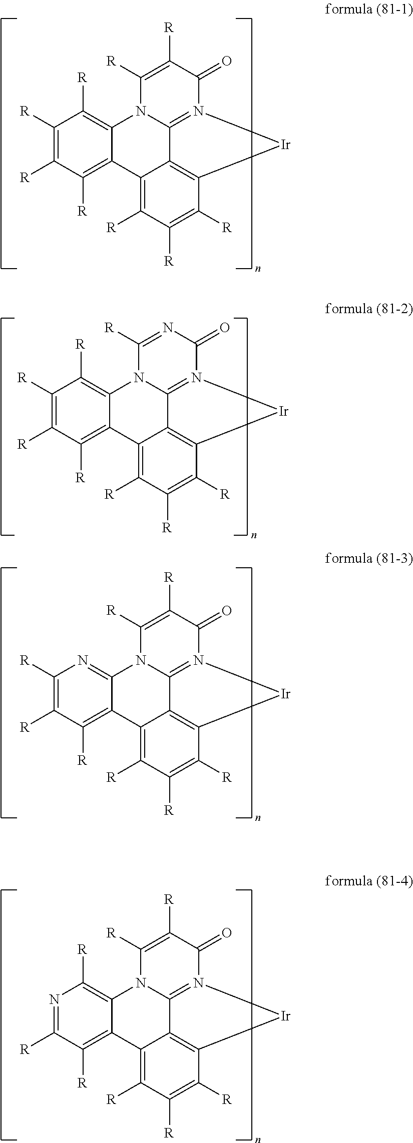

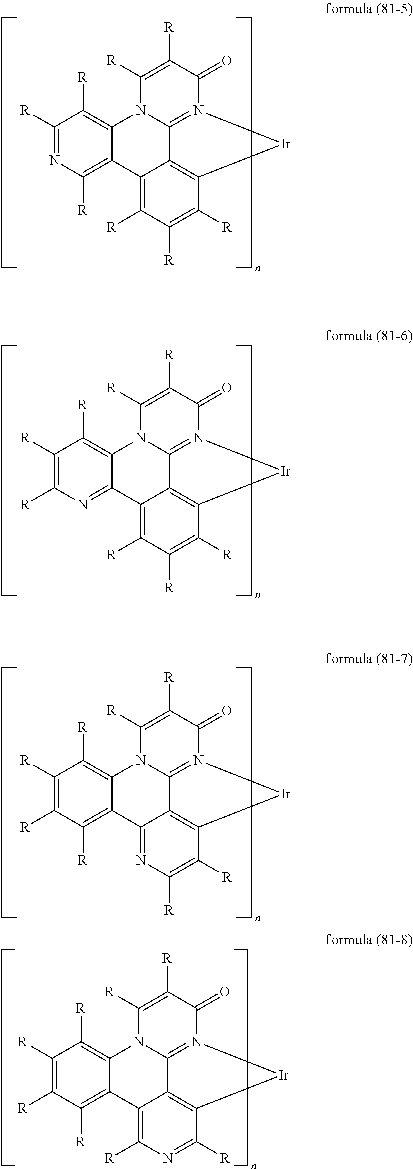

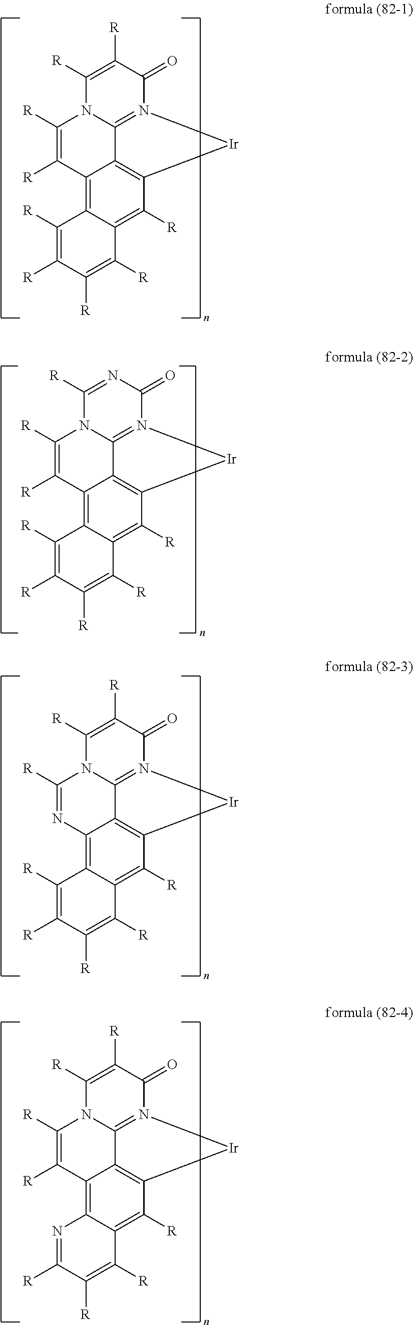

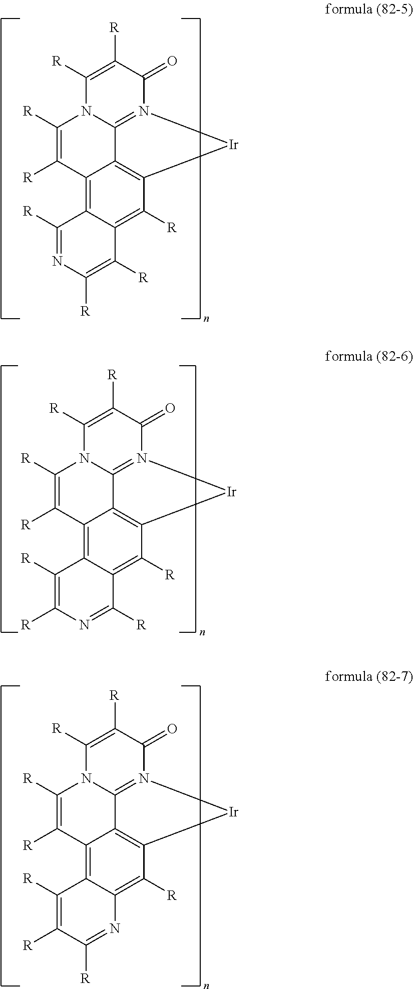

where the symbols and indices used have the meanings given above.

In a preferred embodiment of the invention, the group T which is in the ortho-position to the coordination to the iridium stands for CR. This radical R which is bonded in the ortho-position to the coordination to the iridium is preferably selected from the group consisting of H, D, F and methyl. This applies, in particular, in the case of facial, homoleptic complexes, whereas other radicals R may also be preferred in this position in the case of meridional or heteroleptic complexes.

The groups of the formulae (1) to (7) may be present in any position of the above-mentioned moiety in which two groups T or, if present, two groups Z are bonded directly to one another.

Preferred ligands L² as may occur in the iridium compounds of the formula (75) are described below. The ligands L² are by definition bidentate, monoanionic ligands.

Preferred monoanionic, bidentate ligands L² are selected from 1,3-diketonates derived from 1,3-diketones, such as, for example, acetylacetone, benzoylacetone, 1,5-diphenylacetylacetone, dibenzoylmethane, bis(1,1,1-trifluoroacetyl)methane, 2,2,6,6-tetramethyl-3,5-heptanedione, 3-ketonates derived from 3-ketoesters, such as, for example, acetyl acetate, carboxylates derived from aminocarboxylic acids, such as, for example, pyridine-2-carboxylic acid, quinoline-2-carboxylic acid, glycine, N,N-dimethylglycine, alanine, N,N-dimethylaminoalanine, and salicyliminates derived from salicylimines, such as, for example, methylsalicylimine, ethylsalicylimine or phenylsalicylimine.

In a further preferred embodiment of the invention, the ligands L² are bidentate monoanionic ligands which, with the iridium, form a cyclometallated five-membered ring or six-membered ring having at least one iridiumcarbon bond, in particular a cyclometallated five-membered ring. These are, in particular, ligands as are generally used in the area of phosphorescent metal complexes for organic electroluminescent devices, i.e. ligands of the phenylpyridine, naphthylpyridine, phenylquinoline, phenylisoquinoline, etc., type, each of which may be substituted by one or more radicals R.

A multiplicity of ligands of this type is known to the person skilled in the art in the area of phosphorescent electroluminescent devices, and he will be able to select further ligands of this type as ligand L² for compounds of the formula (75) without inventive step. In general, the combination of two groups as are depicted by the following formulae (83) to (105) is particularly suitable for this purpose, where one group is bonded via a neutral atom and the other group is bonded via a negatively charged atom. The neutral atom here is, in particular, a neutral nitrogen atom or a carbene carbon atom and the negatively charged atom is, in particular, a negatively charged carbon atom, a negatively charged nitrogen atom or a negatively charged oxygen atom. The ligand L² can then be formed from the groups of the formulae (83) to (105) through these groups bonding to one another in each case at the position denoted by #. The position at which the groups are coordinated to the metal is denoted by*. Furthermore, two adjacent radicals R which are each bonded to the two groups of the formulae (83) to (105) may also form an aliphatic or aromatic ring system with one another here.

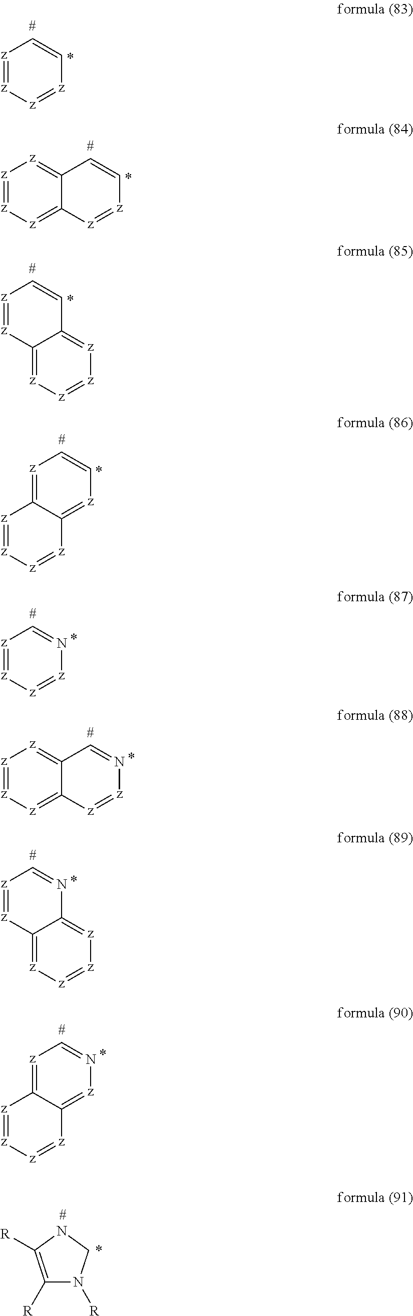

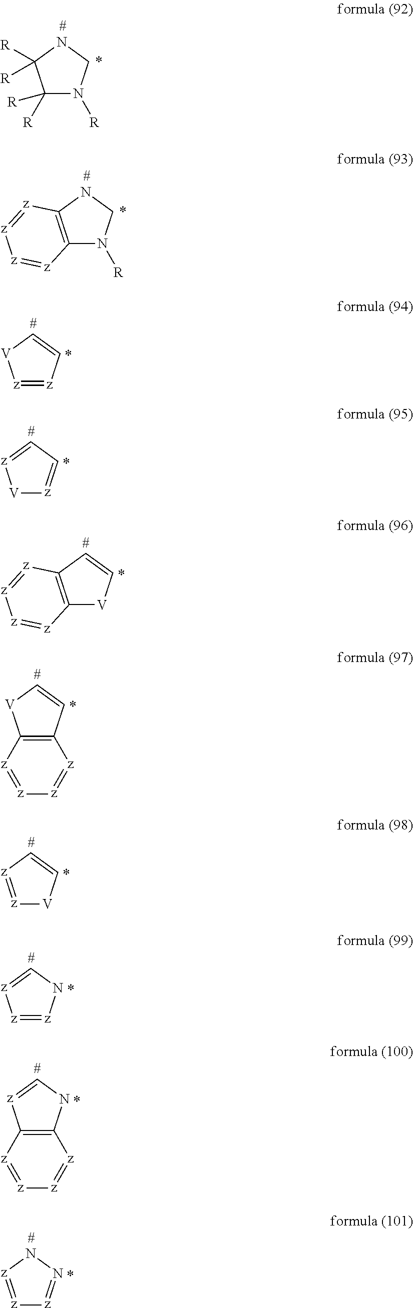

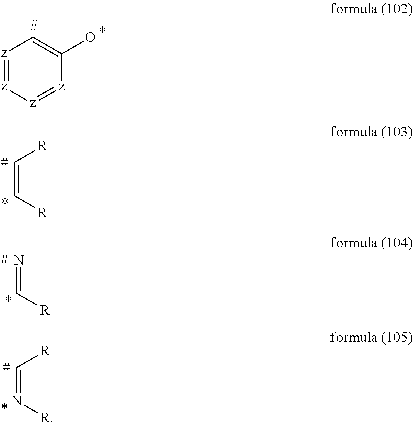

The symbols used here have the same meaning as described above, and preferably a maximum of two symbols Z in each group stand for N, particularly preferably a maximum of one symbol Z in each group stands for N. Very particularly preferably, all symbols Z stand for CR.

In a very particularly preferred embodiment of the invention, the ligand L² is a monoanionic bidentate ligand which is formed from two of the groups of the formulae (83) to (105), where one of these groups is coordinated to the iridium via a negatively charged carbon atom and the other of these groups is coordinated to the iridium via a neutral nitrogen atom.

The further preferred radicals R in the structures shown above are defined as above.

Examples of suitable iridium compounds are the structures shown in the following table:

| | |
|---|---|
| 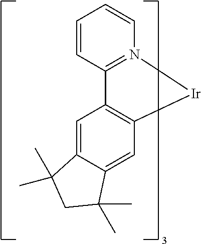 | 1 |
| 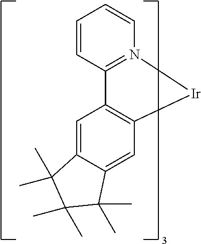 | 2 |
| 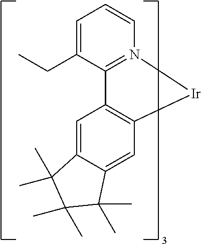 | 3 |
| 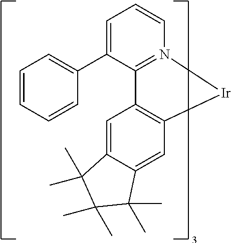 | 4 |
| 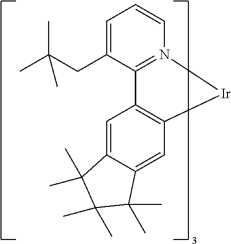 | 5 |
| 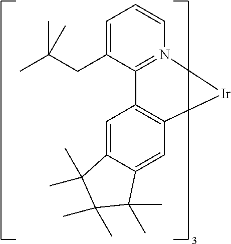 | 6 |
| 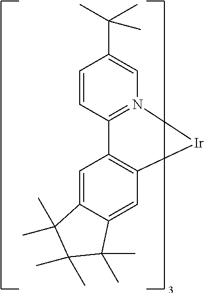 | 7 |
| 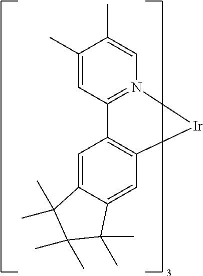 | 8 |
| 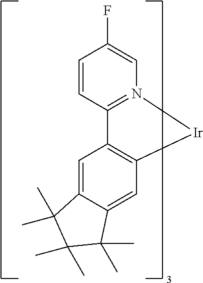 | 9 |
| 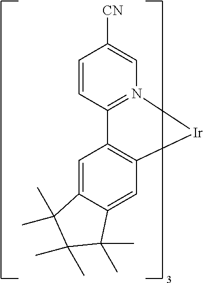 | 10 |
| 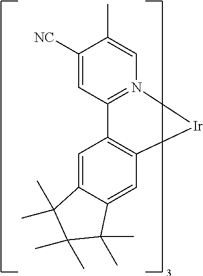 | 11 |
| 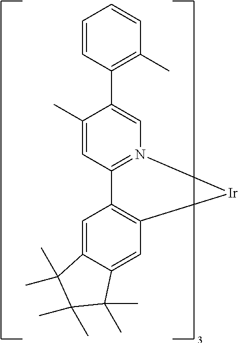 | 12 |
| 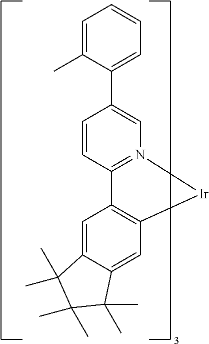 | 13 |
| 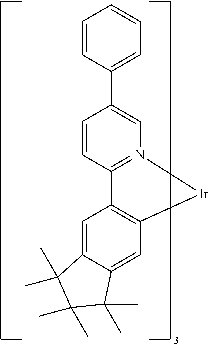 | 14 |
| 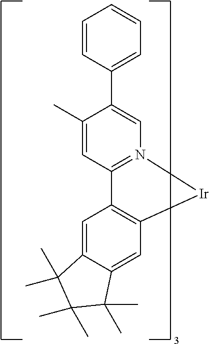 | 15 |
| 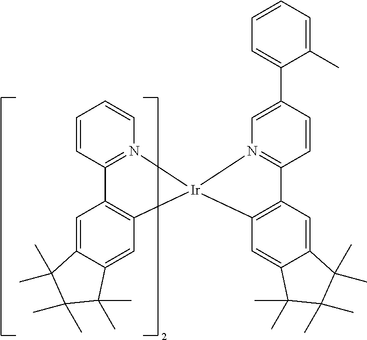 | 16 |
| 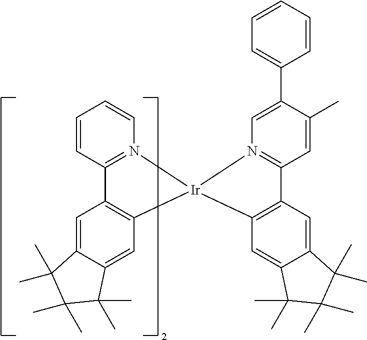 | 17 |
| 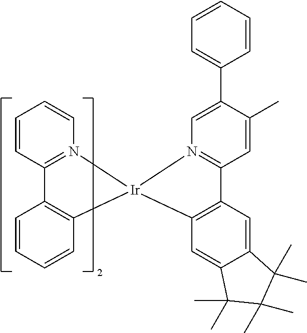 | 18 |
| 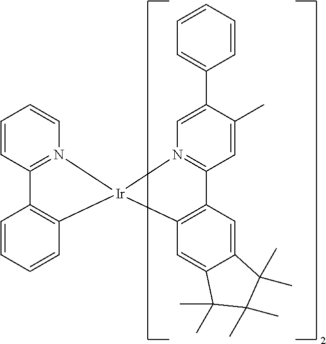 | 19 |
| 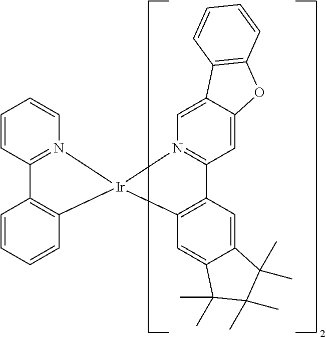 | 20 |
| 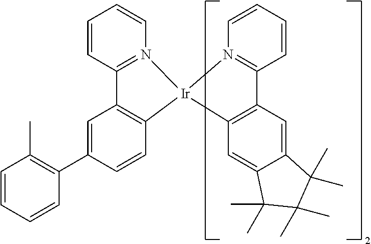 | 21 |
| 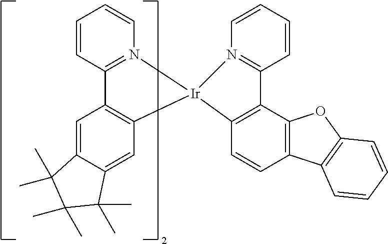 | 22 |
| 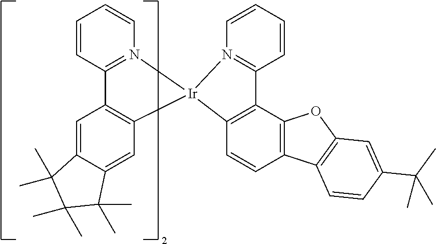 | 23 |
| 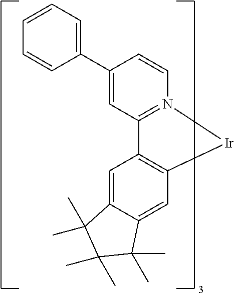 | 24 |
| 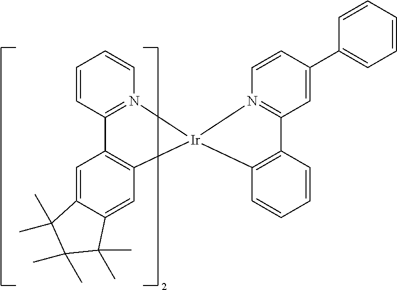 | 25 |
| 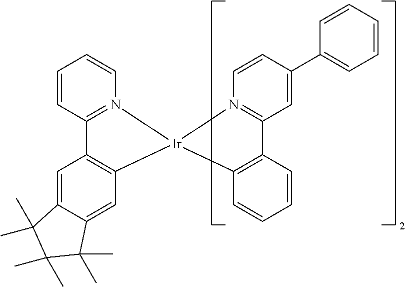 | 26 |
| 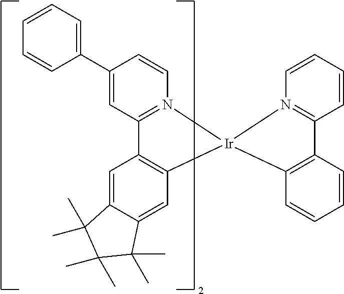 | 27 |
| 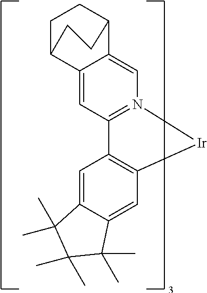 | 28 |
| 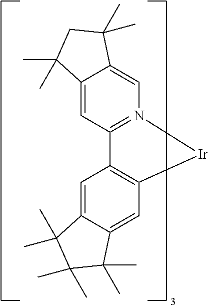 | 29 |
| 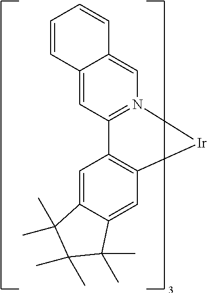 | 30 |
| 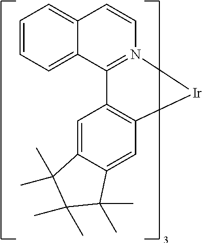 | 31 |
| 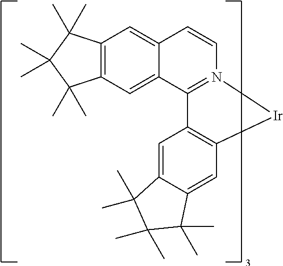 | 32 |
| 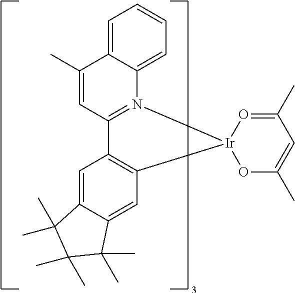 | 33 |
| 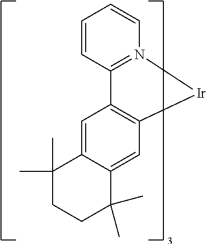 | 34 |
| 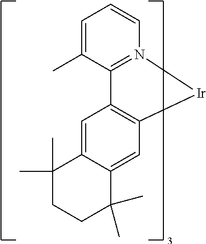 | 35 |
| 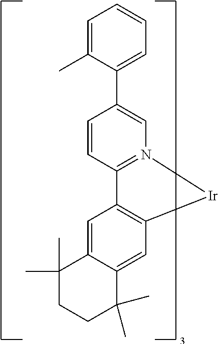 | 36 |
| 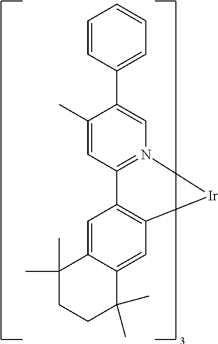 | 37 |
| 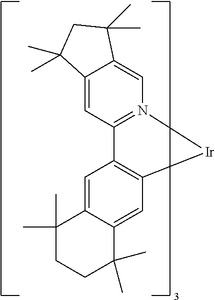 | 38 |
| 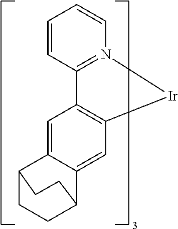 | 39 |
| 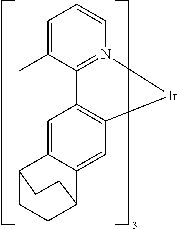 | 40 |
| 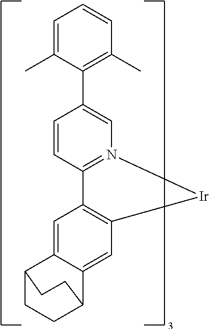 | 41 |
| 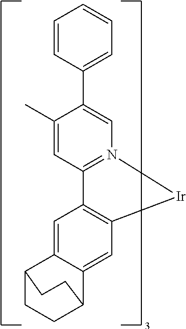 | 42 |
| 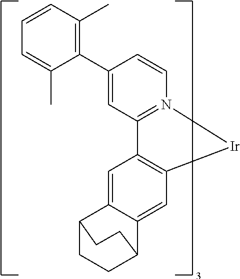 | 43 |
| 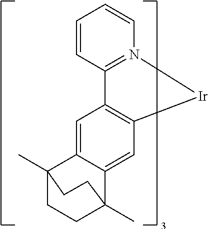 | 44 |
| 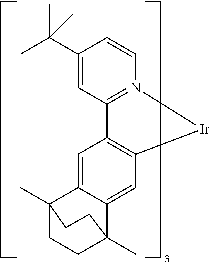 | 45 |
| 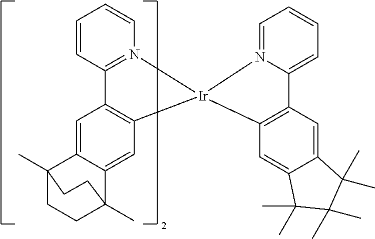 | 46 |
| 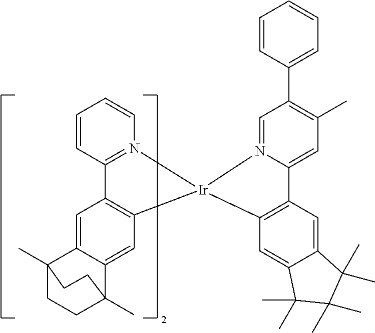 | 47 |
| 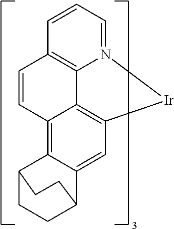 | 48 |
| 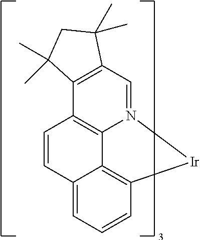 | 49 |
| 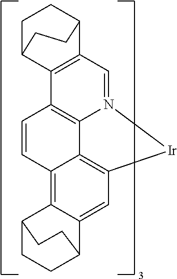 | 50 |
| 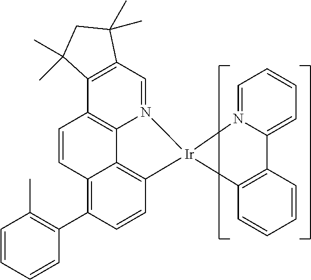 | 51 |
| 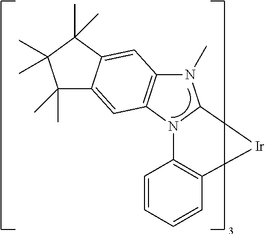 | 52 |
| 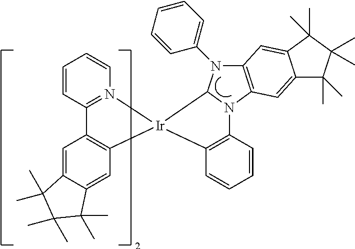 | 53 |
| 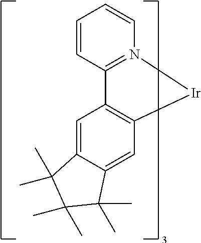 | 54 |
| 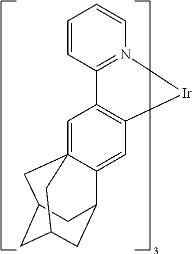 | 55 |
| 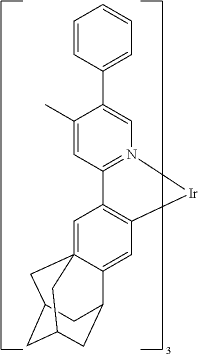 | 56 |
| 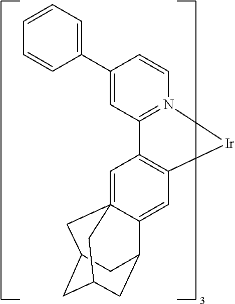 | 57 |
| 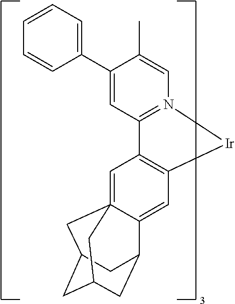 | 58 |
| 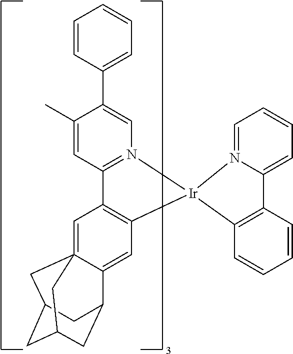 | 59 |
| 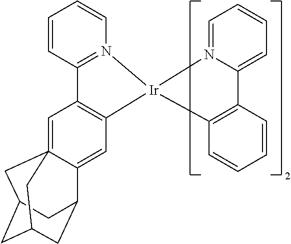 | 60 |

Further examples of suitable phosphorescent iridium compounds and the syntheses thereof can be found in the applications WO 2014/008982, WO 2014/023377 and WO 2014/094960, and the as yet unpublished applications EP 13004411.8, EP 14000345.0, EP 14000417.7 and EP 14002623.8. These are incorporated into the present application by way of reference.

The organic electroluminescent device is described in greater detail below.

The organic electroluminescent device comprises cathode, anode and emitting layer. Apart from these layers, it may also comprise further layers, for example in each case one or more hole-injection layers, hole-transport layers, hole-blocking layers, electron-transport layers, electron-injection layers, exciton-blocking layers, electron-blocking layers and/or chargegeneration layers. However, it should be pointed out that each of these layers does not necessarily have to be present.

In the other layers of the organic electroluminescent device according to the invention, in particular in the hole-injection and -transport layers and in the electron-injection and -transport layers, use can be made of all materials as are usually employed in accordance with the prior art. The hole-transport layers here may also be p-doped and the electron-transport layers may also be n-doped. A p-doped layer here is taken to mean a layer in which free holes are generated and whose conductivity has thereby been increased. A comprehensive discussion of doped transport layers in OLEDs can be found in Chem. Rev. 2007, 107, 1233. The p-dopant is particularly preferably capable of oxidising the hole-transport material in the hole-transport layer, i.e. has a sufficiently high redox potential, in particular a higher redox potential than the hole-transport material. Suitable dopants are in principle all compounds which are electron-acceptor compounds and are able to increase the conductivity of the organic layer by oxidation of the host. The person skilled in the art will be able to identify suitable compounds without major effort on the basis of his general expert knowledge. Particularly suitable dopants are the compounds disclosed in WO 2011/073149, EP 1968131, EP 2276085, EP 2213662, EP 1722602, EP 2045848, DE 102007031220, U.S. Pat. No. 8,044,390, U.S. Pat. No. 8,057,712, WO 2009/003455, WO 2010/094378, WO 2011/120709 and US 2010/0096600.

The person skilled in the art will therefore be able to employ, without inventive step, all materials known for organic electroluminescent devices in combination with the emitting layer according to the invention.

The cathode preferably comprises metals having a low work function, metal alloys or multilayered structures comprising different metals, such as, for example, alkaline-earth metals, alkali metals, main-group metals or lanthanoids (for example Ca, Ba, Mg, Al, In, Mg, Yb, Sm, etc.). Furthermore suitable are alloys of an alkali metal or alkaline-earth metal and silver, for example an alloy of magnesium and silver. In the case of multilayered structures, further metals which have a relatively high work function, such as, for example, Ag, may also be used in addition to the said metals, in which case combinations of the metals, such as, for example, Ca/Ag or Ba/Ag, are generally used. It may also be preferred to introduce a thin interlayer of a material having a high dielectric constant between a metallic cathode and the organic semiconductor. Suitable for this purpose are, for example, alkali metal or alkaline-earth metal fluorides, but also the corresponding oxides or carbonates (for example LiF, Li₂O, BaF₂, MgO, NaF, CsF, Cs₂CO₃, etc.). The layer thickness of this layer is preferably between 0.5 and 5 nm.

The anode preferably comprises materials having a high work function. The anode preferably has a work function of greater than 4.5 eV vs. vacuum. Suitable for this purpose are on the one hand metals having a high redox potential, such as, for example, Ag, Pt or Au. On the other hand, metal/metal oxide electrodes (for example Al/Ni/NiOₓ, Al/PtOₓ) may also be preferred. At least one of the electrodes here must be transparent or partially transparent in order to facilitate the coupling-out of light. A preferred structure uses a transparent anode. Preferred anode materials here are conductive mixed metal oxides. Particular preference is given to indium tin oxide (ITO) or indium zinc oxide (IZO). Preference is furthermore given to conductive, doped organic materials, in particular conductive doped polymers.

The device is correspondingly (depending on the application) structured, provided with contacts and finally hermetically sealed, since the lifetime of devices of this type is drastically shortened in the presence of water and/or air.

Preference is furthermore given to an organic electroluminescent device, characterised in that one or more layers are applied by means of a sublimation process, in which the materials are vapour-deposited in vacuum sublimation units at an initial pressure of less than 10⁻⁵ mbar, preferably less than 10⁻⁶ mbar. However, it is also possible for the pressure to be even lower, for example less than 10⁻⁷ mbar.

Preference is likewise given to an organic electroluminescent device, characterised in that one or more layers are applied by means of the OVPD (organic vapour-phase deposition) process or with the aid of carrier-gas sublimation, in which the materials are applied at a pressure between 10⁻⁵ mbar and 1 bar. A special case of this process is the OVJP (organic vapour jet printing) process, in which the materials are applied directly through a nozzle and thus structured (for example M. S. Arnold et al., Appl. Phys. Lett. 2008, 92, 053301).

Preference is furthermore given to an organic electroluminescent device, characterised in that one or more layers are produced from solution, such as, for example, by spin coating, or by means of any desired printing process, such as, for example, screen printing, flexographic printing, offset printing, LITI (light induced thermal imaging, thermal transfer printing), inkjet printing or nozzle printing. Soluble compounds are necessary for this purpose, which are obtained, for example, by suitable substitution.

These processes are generally known to the person skilled in the art and can be applied by him without inventive step to organic electroluminescent devices comprising the compounds according to the invention.

The present invention therefore furthermore relates to a process for the production of an organic electroluminescent device according to the invention, characterised in that at least one layer is applied by means of a sublimation process and/or in that at least one layer is applied by means of an OVPD (organic vapour phase deposition) process or with the aid of carrier-gas sublimation and/or in that at least one layer is applied from solution, by spin coating or by means of a printing process.

The organic electroluminescent devices according to the invention are distinguished over the prior art by one or more of the following surprising advantages:
1. The organic electroluminescent devices according to the invention simultaneously have very good efficiency, a very good lifetime and a low operating voltage.
2. The without exception very good device properties can also be achieved with a low emitter concentration. This is achieved only on use of an iridium compound in accordance with the present application. If, by contrast, another iridium compound is used in a mixed matrix, as is described in the present invention, or also in a mixed matrix comprising a hole-transporting material and an electron-transporting material, good results can only be achieved at a higher emitter concentration.
3. The positive effect described above is only achieved if precisely the combination according to the invention of two electron-transporting compounds and a phosphorescent iridium compound, as described above, is used.

The invention is explained in greater detail by the following examples without wishing to restrict it thereby. The person skilled in the art will be able to carry out the invention throughout the range disclosed on the basis of the descriptions and produce further organic electroluminescent devices according to the invention without inventive step.

### EXAMPLES

Determination of HOMO, LUMO, Singlet and Triplet Level

The HOMO and LUMO energy levels and the energy of the lowest triplet state T₁ or of the lowest excited singlet state S₁ of the materials are determined via quantum-chemical calculations. To this end, the “Gaussian09W” software package (Gaussian Inc.) is used. In order to calculate organic substances without metals, firstly a geometry optimisation is carried out using the “Ground State/Semi-empirical/Default Spin/AM1/Charge 0/Spin Singlet” method. This is followed by an energy calculation on the basis of the optimised geometry. The “TD-SFC/DFT/Default Spin/B3PW91” method with the “6-31G(d)” base set is used here (Charge 0, Spin Singlet). For metal-containing compounds, the geometry is optimised via the “Ground State/Hartree-Fock/Default Spin/LanL2 MB/Charge 0/Spin Singlet” method. The energy calculation is carried out analogously to the organic substances as described above, with the difference that the “LanL2DZ” base set is used for the metal atom and the “6-31G(d)” base set is used for the ligands. The energy calculation gives the HOMO energy level HEh or LUMO energy level LEh in hartree units. The HOMO and LUMO energy levels calibrated with reference to cyclic voltammetry measurements are determined therefrom in electron volts as follows:

HOMO(eV)=((HEh*27.212)−0.9899)/1.1206

LUMO(eV)=((LEh*27.212)−2.0041)/1.385

These values are to be regarded in the sense of this application as HOMO and LUMO energy levels of the materials.

The lowest triplet state T₁ is defined as the energy of the triplet state having the lowest energy which arises from the quantum-chemical calculation described.

The lowest excited singlet state S₁ is defined as the energy of the excited singlet state having the lowest energy which arises from the quantum-chemical calculation described.

Table 4 below shows the HOMO and LUMO energy levels and S₁ and T₁ of the various materials.

### Synthesis Examples

The following syntheses are carried out, unless indicated otherwise, in dried solvents under a protective-gas atmosphere. The metal complexes are additionally handled with exclusion of light or under yellow light. The solvents and reagents can be purchased, for example, from SigmaALDRICH or ABCR. The respective numbers in square brackets or the numbers indicated for individual compounds relate to the CAS numbers of the compounds which are known from the literature.

A: Synthesis of the Synthones S:

### Example S1: Dispiro[cyclopentane-1,1′-[1H]indene-3′(2′H),1″-cyclopentane]-5-boronic acid pinacol ester

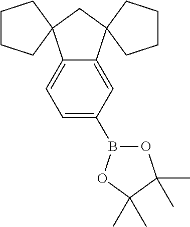 [SMILES: CC1(C)OB(c2ccc3c(c2)C2(CCCC2)CC32CCCC2)OC1(C)C]

### a) Dispiro[cyclopentane-1,1′-[1H]inden-3′(2′H),1″-2-onecyclopentane], [1620682-15-6]

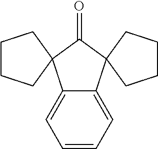 [SMILES: O=C1C2(CCCC2)c2ccccc2C12CCCC2]

A solution of 66.1 g (500 mmol) of indan-2-one [615-13-4] and 340.9 g (1100 mmol) of 1,4-diiodobutane [628-21-7] in 500 ml of THF is added dropwise over the course of 2 h to a vigorously stirred mixture of 40.0 g (1 mol) of NaOH, 40 ml of water, 18.5 g (50 mmol) of tetrabutylammonium iodide [311-28-4] and 1500 ml of THF. When the addition is complete, the mixture is stirred at room temperature for a further 14 h, the aqueous phase is separated off, and the organic phase is evaporated to dryness. The residue is taken up in 1000 ml of n-heptane, washed five times with 300 ml of water each time and dried over magnesium sulfate. The crude product obtained after removal of the n-heptane is subjected to fractional distillation in an oil-pump vacuum (about 0.2 mbar, T about 135° C.). Yield: 83.0 g (345 mmol), 69%. Purity about 95% according to ¹H-NMR.

### b) Dispiro[cyclopentane-1,1′-[1H]indene-3′(2′H),1″-cyclopentane]

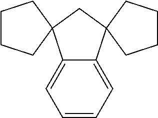 [SMILES: c1ccc2c(c1)C1(CCCC1)CC21CCCC1]

A mixture of 83 g (345 mmol) of dispiro[cyclopentane-1,1′-[1H]inden-3′(2′H),1″-2-onecyclopentane] from a), 100.1 g (2.0 mol) of hydrazine hydrate, 112.2 g (2.5 mol) of potassium hydroxide and 500 ml of triethylene glycol is stirred at 180° C. with vigorous stirring for 16 h. The temperature is then increased stepwise until 250° C. has been reached, during which distillate formed is removed via a water separator and discarded, and the mixture is stirred further until the evolution of nitrogen peters out. After cooling, the reaction mixture is diluted with 500 ml of water and extracted three times with 300 ml of n-heptane each time. The combined n-heptane phases are washed five times with 200 ml of water each time and dried over magnesium sulfate. The crude product obtained after removal of the n-heptane is subjected to fractional distillation in an oil-pump vacuum (about 0.2 mbar, T about 105° C.). Yield: 57.7 g (255 mmol), 74%. Purity about 95% according to ¹H-NMR.

### c) Dispiro[cyclopentane-1,1′-[1H]indene-3′(2′H),1″-cyclopentane]-5-boronic acid pinacol ester

14.0 g (55 mmol) of bispinacolatodiborane [73183-34-3] are added with stirring to a mixture of 1.7 g (2.5 mmol) of methoxy(cyclooctadiene)iridium(I) dimer [12148-71-9], 1.4 g (5 mmol) of 4,4′-di-tert-butyl-2,2-bipyridinyl [72914-19-3] and 500 ml of n-heptane, and the mixture is stirred at room temperature for 15 min. A further 50.8 g (200 mmol) of bispinacolatodiborane and then 57.7 g (255 mmol) of dispiro[cyclopentane-1,1′-[1H]indene-3′(2′H),1″-cyclopentane] from b) are then added, and the reaction mixture is heated at 80° C. for 16 h. After cooling, the n-heptane is removed in vacuo, and the residue is washed by stirring twice with 400 ml of methanol each time. Yield: 70.1 g (199 mmol), 78%. Purity about 98% according to ¹H-NMR.

B. Synthesis of the Ligands L

### Example L1: 2-(Dispiro[cyclopentane-1,1′-[1H]inden-3′(2′H),1″-5-yl-cyclopentane]pyridine

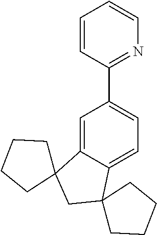 [SMILES: c1ccc(-c2ccc3c(c2)C2(CCCC2)CC32CCCC2)nc1]

841 mg (3 mmol) of tricyclohexylphosphine [2622-14-2] and then 449 mg (2 mmol) of palladium(II) acetate are added to a vigorously stirred mixture of 70.1 g (199 mmol) of dispiro[cyclopentane-1,1′-[1H]indene-3′(2′H),1″-cyclopentane]-5-boronic acid pinacol ester S1, 39.5 g (250 mmol) of 2-bromopyridine [109-04-6], 115.1 g (500 mmol) of tripotassium phosphate monohydrate, 600 ml of toluene, 600 ml of dioxane and 600 ml of water, and the mixture is then heated under reflux for 40 h. After cooling, the organic phase is separated off, washed three times with 200 ml of water each time and once with 200 ml of saturated sodium chloride solution and dried over magnesium sulfate. The desiccant is filtered off via a Celite bed, the solvent and excess 2-bromopyridine are stripped off, and the oil which remains is subjected to fractional bulb-tube distillation twice in vacuo (p about 10⁻⁴ mbar, T about 220° C.). Yield: 40.7 g (134 mmol), 67%. Purity about 99% according to ¹H-NMR.

C. Synthesis of the Complexes

### Example Ir(L1)₃

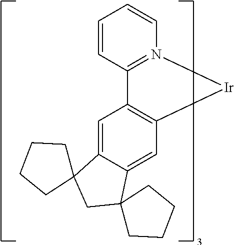

A mixture of 30.3 g (100 mmol) of the ligand L1 and 12.2 g (25 mmol) of trisacetylacetonatoiridium(III) [15635-87-7] is initially introduced in a 250 ml two-necked round-bottomed flask with glass-clad magnetic bar. The flask is provided with a water separator and an air condenser with argon blanketing. The flask is placed in a metal heating bowl. The apparatus is flushed from above with argon via the argon blanketing for 15 min., during which the argon is allowed to flow out of the side neck of the two-necked flask. A glass-clad Pt-100 thermocouple is introduced into the two-necked flask via the side neck, and the end is positioned just above the magnetic stirrer bar. The apparatus is then thermally insulated using several loose wound layers of household aluminium foil, where the insulation is applied up to the centre of the rising tube of the water separator. The apparatus is then heated rapidly to 275° C., measured on the Pt-100 thermocouple which dips into the molten, stirred reaction mixture, using a laboratory heating stirrer. During the next 20 h, the reaction mixture is kept at 270-275° C., during which about 5 ml of acetylacetone distil off successively and collect in the water separator. After cooling, the melt cake is mechanically comminuted and then washed with 300 ml of boiling methanol. The beige suspension obtained in this way is filtered through a reverse frit, the beige solid is washed once with methanol and then dried in vacuo. Crude yield: quantitative. The crude product obtained in this way is subsequently chromatographed on silica gel (about 100 g per g of crude product) with toluene with exclusion of air and light, where the product (yellow band) elutes virtually with the eluent front and dark secondary components remain at the beginning. The core fraction of the yellow band is cut out, the toluene is removed in vacuo, and the yellow glass remaining is taken up in 200 ml of hot acetonitrile, during which crystallisation of the product commences. After stirring for a further one hour, the cooled suspension is filtered through a reverse frit with suction, and the yellow solid is washed once with 50 ml of acetonitrile. The further purification is carried out by continuous hot extraction with acetonitrile five times (amount of acetonitrile introduced about 300 ml, extraction thimble: standard cellulose Soxhlett thimble from Whatman) with careful exclusion of air and light. Finally, the product is subjected to fractional sublimation twice in vacuo (p about 10⁻⁵ mbar, T about 340° C.). Yield: 11.5 g, 42%. Purity: >99.9% according to HPLC.

### Example: Production of the OLEDs

OLEDs according to the invention and OLEDs in accordance with the prior art are produced by a general process in accordance with WO 2004/058911, which is adapted to the circumstances described here (layerthickness variation, materials used).

The results of various OLEDs are presented in the following examples. Glass plates with structured ITO (50 nm, indium tin oxide) form the substrates to which the OLEDs are applied. The OLEDs have in principle the following layer structure: substrate/hole-transport layer 1 (HTL1) consisting of HTM doped with 3% of NDP-9 (commercially available from Novaled), 20 nm/hole-transport layer 2 (HTL2)/optional electron-blocking layer (EBL)/emission layer (EML)/optional hole-blocking layer (HBL)/electron-transport layer (ETL)/optional electron-injection layer (EIL) and finally a cathode. The cathode is formed by an aluminium layer with a thickness of 100 nm.

Firstly, vacuum-processed OLEDs are described. For this purpose, all materials are applied by thermal vapour deposition in a vacuum chamber. The emission layer here always consists of at least one matrix material (host material) and an emitting dopant (emitter), which is admixed with the matrix material or matrix materials in a certain proportion by volume by coevaporation. An expression such as M3:M2:Ir(LH1)₃ (55%:35%:10%) here means that material M3 is present in the layer in a proportion by volume of 55%, M2 is present in the layer in a proportion of 35% and Ir(LH1)₃ is present in the layer in a proportion of 10%. Analogously, the electron-transport layer may also consist of a mixture of two materials. The precise structure of the OLEDs is shown in Table 1. The materials used for the production of the OLEDs are shown in Table 3.

The OLEDs are characterised by standard methods. For this purpose, the electroluminescence spectra, the current efficiency (measured in cd/A) and the voltage (measured at 10 mA/cm² in V) are determined from the current/voltage/luminance characteristic lines (IUL characteristic lines), are determined. The external quantum efficiency (EQE) and the CIE 1931 colour coordinates are derived therefrom. For selected experiments, the lifetime is determined. The lifetime is defined as the time after which the luminous density has dropped to a certain proportion from its initial luminous density at a defined, constant operating current (typically 50 mA/cm²). The term LT50 means that the said lifetime is the time by which the luminous density has dropped to 50% of the initial luminous density. The values for the lifetime can be converted to a value for other initial luminous densities with the aid of conversion formulae known to the person skilled in the art.

Table 1 below shows the layer structures and materials used (see Table 3) both for OLEDs according to the invention and also comparative examples. The associated results of the OLEDs are summarised in Table 2. The HTL1 used is basically HTM doped with 3% of NDP-9.

Examples 1-3 illustrate the crucial effect of this invention. The mixture according to the invention of two electron-transporting matrix materials with an emitter defined in accordance with the invention (see 1 a, 1 b, 1c) results in OLEDs which simultaneously have high efficiency, a low voltage and a long lifetime. In addition, it is advantageous that, when the emitter concentration is reduced from 18% to 12% to 6%, the voltage becomes lower and at the same time the efficiency becomes higher, without significantly adversely affecting the lifetime. By contrast, Example 2 shows that on use of an emitter which does not correspond to the invention in the same matrix system, the efficiency is significantly weaker. Likewise, a reduction in the emitter concentration does not result in a reduction in the voltage, but instead, on the contrary, in an increase. Conversely, the use of a mixture which is not in accordance with the invention of an electron-conducting matrix material and a hole-conducting matrix material with the emitter from Example 1 results in OLEDs having an increased operating voltage (see Example 3).

Only the combination according to the invention of suitable emitters, as defined in the present invention, with two electron-transporting matrices results in OLEDs which simultaneously exhibit good performance data in all three parameters efficiency, voltage and lifetime (and do so in side effect at low emitter concentration). The fact that this effect is not restricted to the materials or layer architectures specifically selected in Example 1 is demonstrated by the further working examples from Example 4, in which further materials are combined in accordance with the invention, in some cases also with other electron- or hole-blocking layers.

TABLE 1
Structure of the OLEDs

| | | | | | |
|---|---|---|---|---|---|
| | HTL2 | EBL | EML | HBL | ETL |
| Ex. | Thickness | Thickness | Thickness | Thickness | Thickness |

Green OLEDs

| | | | | | |
|---|---|---|---|---|---|
| 1a | HTM | EBM | eM1:eM4:G1 | ETM1 | ETM1:ETM2 |
| | 220 nm | 20 nm | (44%:44%:12%) | 10 nm | (50%:50%) |
| | | | 30 nm | | 30 nm |
| 1b | HTM | EBM | eM1:eM4:G1 | ETM1 | ETM1:ETM2 |
| | 220 nm | 20 nm | (47%:47%:6%) | 10 nm | (50%:50%) |
| | | | 30 nm | | 30 nm |
| 1c | HTM | EBM | eM1:eM4:G1 | ETM1 | ETM1:ETM2 |
| | 220 nm | 20 nm | (41%:41%:18%) | 10 nm | (50%:50%) |
| | | | 30 nm | | 30 nm |
| 2a | HTM | EBM | eM1:eM4:Irppy | ETM1 | ETM1:ETM2 |
| (comparison) | 220 nm | 20 nm | (44%:44%:12%) | 10 nm | (50%:50%) |
| | | | 30 nm | | 30 nm |
| 2b | HTM | EBM | eM1:eM4:Irppy | ETM1 | ETM1:ETM2 |
| (comparison) | 220 nm | 20 nm | (47%:47%:6%) | 10 nm | (50%:50%) |
| | | | 30 nm | | 30 nm |
| 2c | HTM | EBM | eM1:eM4:Irppy | ETM1 | ETM1:ETM2 |
| (comparison) | 220 nm | 20 nm | (41%:41%:18%) | 10 nm | (50%:50%) |
| | | | 30 nm | | 30 nm |
| 3a | HTM | EBM | hM1:eM4:G1 | ETM1 | ETM1:ETM2 |
| (comparison) | 220 nm | 20 nm | (44%:44%:12%) | 10 nm | (50%:50%) |
| | | | 30 nm | | 30 nm |
| 3b | HTM | EBM | hM1:eM4:G1 | ETM1 | ETM1:ETM2 |
| (comparison) | 220 nm | 20 nm | (47%:47%:6%) | 10 nm | (50%:50%) |
| | | | 30 nm | | 30 nm |
| 3c | HTM | EBM | hM1:eM4:G1 | ETM1 | ETM1:ETM2 |
| (comparison) | 220 nm | 20 nm | (41%:41%:18%) | 10 nm | (50%:50%) |
| | | | 30 nm | | 30 nm |
| 4a | HTM | EBM | eM1:eM5:G1 | ETM1 | ETM1:ETM2 |
| | 220 nm | 20 nm | (44%:44%:12%) | 10 nm | (50%:50%) |
| | | | 30 nm | | 30 nm |
| 4b | HTM | EBM | eM1:eM5:G1 | ETM1 | ETM1:ETM2 |
| | 220 nm | 20 nm | (47%:47%:6%) | 10 nm | (50%:50%) |
| | | | 30 nm | | 30 nm |
| 4c | HTM | EBM | eM1:eM5:G1 | ETM1 | ETM1:ETM2 |
| | 220 nm | 20 nm | (41%:41%:18%) | 10 nm | (50%:50%) |
| | | | 30 nm | | 30 nm |
| 5a | HTM | EBM | hM2:eM2:G1 | ETM1 | ETM1:ETM2 |
| (comparison) | 220 nm | 20 nm | (44%:44%:12%) | 10 nm | (50%:50%) |
| | | | 30 nm | | 30 nm |
| 5b | HTM | EBM | hM2:eM5:G1 | ETM1 | ETM1:ETM2 |
| (comparison) | 220 nm | 20 nm | (47%:47%:6%) | 10 nm | (50%:50%) |
| | | | 30 nm | | 30 nm |
| 5c | HTM | EBM | hM2:eM5:G1 | ETM1 | ETM1:ETM2 |
| (comparison) | 220 nm | 20 nm | (41%:41%:18%) | 10 nm | (50%:50%) |
| | | | 30 nm | | 30 nm |
| 6a | HTM | EBM | eM2:eM4:G1 | eM2 | ETM1:ETM2 |
| | 220 nm | 20 nm | (44%:44%:12%) | 10 nm | (50%:50%) |
| | | | 30 nm | | 30 nm |
| 6b | HTM | EBM | eM2:eM4:G1 | eM2 | ETM1:ETM2 |
| | 220 nm | 20 nm | (47%:47%:6%) | 10 nm | (50%:50%) |
| | | | 30 nm | | 30 nm |
| 6c | HTM | EBM | eM2:eM4:G1 | eM2 | ETM1:ETM2 |
| | 220 nm | 20 nm | (41%:41%:18%) | 10 nm | (50%:50%) |
| | | | 30 nm | | 30 nm |
| 7a | HTM | EBM | eM1:eM4:G1 | ETM1 | ETM1:ETM2 |
| | 220 nm | 20 nm | (24%:70%:6%) | 10 nm | (50%:50%) |
| | | | 30 nm | | 30 nm |
| 7b | HTM | EBM | eM1:eM4:G1 | ETM1 | ETM1:ETM2 |
| | 220 nm | 20 nm | (70%:24%:6%) | 10 nm | (50%:50%) |
| | | | 30 nm | | 30 nm |
| 8 | HTM | — | eM1:eM4:G1 | ETM1 | ETM1:ETM2 |
| | 240 nm | | (44%:44%:12%) | 10 nm | (50%:50%) |
| | | | 30 nm | | 30 nm |
| 9 | HTM | — | eM1:eM4:G1 | — | ETM1:ETM2 |
| | 240 nm | | (44%:44%:12%) | | (50%:50%) |
| | | | 30 nm | | 40 nm |
| 10 | HTM | EBM | eM3:eM4:G1 | ETM1 | ETM1:ETM2 |
| | 220 nm | 20 nm | (47%:47%:6%) | 10 nm | (50%:50%) |
| | | | 30 nm | | 30 nm |
| 11 | HTM | EBM | eM5:eM6:G1 | ETM1 | ETM1:ETM2 |
| | 220 nm | 20 nm | (47%:47%:6%) | 10 nm | (50%:50%) |
| | | | 30 nm | | 30 nm |
| 12 | HTM | EBM | eM1:eM4:G2 | ETM1 | ETM1:ETM2 |
| | 220 nm | 20 nm | (47%:47%:6%) | 10 nm | (50%:50%) |
| | | | 30 nm | | 30 nm |
| 13 | HTM | EBM | eM1:eM4:G3 | ETM1 | ETM1:ETM2 |
| | 220 nm | 20 nm | (47%:47%:6%) | 10 nm | (50%:50%) |
| | | | 30 nm | | 30 nm |

Red OLEDs

| | | | | | |
|---|---|---|---|---|---|
| 14 | HTM | — | eM1:hM1:R1 | — | ETM1:ETM2 |
| (comparison) | 280 nm | | (63%:31%:6%) | | (50%:50%) |
| | | | 40 nm | | 30 nm |
| 15a | HTM | — | eM1:eM4:Irpiq | — | ETM1:ETM2 |
| (comparison) | 280 nm | | (47%:47%:3%) | | (50%:50%) |
| | | | 40 nm | | 30 nm |
| 15b | HTM | — | eM1:eM4:Irpiq | — | ETM1:ETM2 |
| (comparison) | 280 nm | | (47%:47%:7%) | | (50%:50%) |
| | | | 40 nm | | 30 nm |
| 16a | HTM | — | eM1:eM4:R1 | — | ETM1:ETM2 |
| | 280 nm | | (47%:47%:3%) | | (50%:50%) |
| | | | 40 nm | | 30 nm |
| 16b | HTM | — | eM1:eM4:R1 | — | ETM1:ETM2 |
| | 280 nm | | (47%:47%:7%) | | (50%:50%) |
| | | | 40 nm | | 30 nm |

Yellow OLEDs

| | | | | | |
|---|---|---|---|---|---|
| 17a | HTM | EBM | hM1:eM1:Y1 | ETM1 | ETM1:ETM2 |
| (comparison) | 220 nm | 20 nm | (41%:41%:18%) | 10 nm | (50%:50%) |
| | | | 30 nm | | 30 nm |
| 17b | HTM | EBM | hM1:eM1:Y1 | ETM1 | ETM1:ETM2 |
| (comparison) | 220 nm | 20 nm | (44%:44%:12%) | 10 nm | (50%:50%) |
| | | | 30 nm | | 30 nm |
| 17c | HTM | EBM | hM1:eM1:Y1 | ETM1 | ETM1:ETM2 |
| (comparison) | 220 nm | 20 nm | (47%:47%:6%) | 10 nm | (50%:50%) |
| | | | 30 nm | | 30 nm |
| 18a | HTM | EBM | eM1:eM4:Y1 | ETM1 | ETM1:ETM2 |
| | 220 nm | 20 nm | (41%:41%:18%) | 10 nm | (50%:50%) |
| | | | 30 nm | | 30 nm |
| 18b | HTM | EBM | eM1:eM4:Y1 | ETM1 | ETM1:ETM2 |
| | 220 nm | 20 nm | (44%:44%:12%) | 10 nm | (50%:50%) |
| | | | 30 nm | | 30 nm |
| 18c | HTM | EBM | eM1:eM4:Y1 | ETM1 | ETM1:ETM2 |
| | 220 nm | 20 nm | (47%:47%:6%) | 10 nm | (50%:50%) |
| | | | 30 nm | | 30 nm |

TABLE 2
Results of vacuum-processed OLEDs

| | | | | |
|---|---|---|---|---|
| | EQE (%) | | | |
| | [power eff.] | Voltage (V) | CIE x/y | LT50 (h) |
| Ex. | 10 mA/cm² | 10 mA/cm² | 10 mA/cm² | 50 mA/cm² |

Green OLEDs

| | | | | |
|---|---|---|---|---|
| 1a | 19.8 | 4.3 | 0.34/0.63 | 500 |
| | [55.3 lmW] | | | |
| 1b | 21.0 | 4.0 | 0.32/0.64 | 400 |
| | [63.1 lm/W] | | | |
| 1c | 17.2 | 4.7 | 0.35/0.62 | 500 |
| | [43.9 lmW/] | | | |
| 2a | 15.3 | 4.3 | 0.30/0.64 | 300 |
| (comparison) | [41.4 lm/W] | | | |
| 2b | 15.6 | 4.7 | 0.31/0.64 | 250 |
| (comparison) | [38.8 lmW/] | | | |
| 2c | 15.0 | 4.1 | 0.31/0.64 | 300 |
| (comparison) | [42.9 lm/W] | | | |
| 3a | 21.2 | 5.0 | 0.33/0.64 | 400 |
| (comparison) | [50.9 lm/W] | | | |
| 3b | 22.2 | 4.8 | 0.33/0.64 | 400 |
| (comparison) | [55.4 lm/W] | | | |
| 3c | 19.7 | 5.4 | 0.32/0.65 | 400 |
| (comparison) | [43.7 lm/W] | | | |
| 4a | 20.0 | 4.3 | 0.34/0.63 | 600 |
| | [55.8 lm/W] | | | |
| 4b | 21.2 | 4.0 | 0.32/0.64 | 400 |
| | [63.6 lm/W] | | | |
| 4c | 16.8 | 4.5 | 0.35/0.62 | 500 |
| | [44.8 lm/W] | | | |
| 5a | 19.6 | 5.0 | 0.33/0.64 | 300 |
| (comparison) | [47.0 lm/W] | | | |
| 5b | 21.2 | 4.7 | 0.34/0.63 | 350 |
| (comparison) | [54.1 lm/W] | | | |
| 5c | 19.4 | 5.5 | 0.32/0.65 | 400 |
| (comparison) | [42.3 lm/W] | | | |
| 6a | 20.4 | 4.4 | 0.34/0.63 | 500 |
| | [55.6 lm/W] | | | |
| 6b | 21.5 | 4.1 | 0.32/0.64 | 500 |
| | [62.9 lm/W] | | | |
| 6c | 18.2 | 4.6 | 0.35/0.62 | 600 |
| | [47.5 lm/W] | | | |
| 7a | 19.9 | 4.3 | 0.33/0.64 | 450 |
| | [55.1 lm/W] | | | |
| 7b | 20.8 | 3.9 | 0.33/0.63 | 400 |
| | [63.4 lm/W] | | | |
| 8 | 19.4 | 4.1 | 0.34/0.63 | 600 |
| | [56.4 lm/W] | | | |
| 9 | 19.3 | 4.1 | 0.34/0.63 | 600 |
| | [56.5 lm/W] | | | |
| 10 | 20.5 | 4.0 | 0.32/0.63 | 400 |
| | [61.5 lm/W] | | | |
| 11 | 19.5 | 4.1 | 0.33/0.63 | 350 |
| | [57.1 lm/W] | | | |
| 12 | 19.7 | 4.0 | 0.36/0.62 | 350 |
| | [58.1 lm/W] | | | |
| 13 | 19.3 | 3.9 | 0.33/0.64 | 300 |
| | [59.0 lm/W] | | | |

Red OLEDs

| | | | | |
|---|---|---|---|---|
| 14 | 16.2 | 3.9 | 0.70/0.30 | 700 |
| (comparison) | | | | |
| 15a | 13.5 | 3.7 | 0.68/0.32 | 1400 |
| (comparison) | | | | |
| 15b | 13.2 | 3.7 | 0.68/0.32 | 1700 |
| (comparison) | | | | |
| 16a | 16.7 | 3.5 | 0.70/0.30 | 3500 |
| 16b | 16.2 | 3.7 | 0.70/0.30 | 5000 |

Yellow OLEDs

| | | | | |
|---|---|---|---|---|
| 17a | 17.9 | 4.7 | 0.48/0.52 | 850 |
| (comparison) | | | | |
| 17b | 18.0 | 4.8 | 0.48/0.52 | 800 |
| (comparison) | | | | |
| 17c | 18.3 | 4.6 | 0.46/0.53 | 600 |
| (comparison) | | | | |
| 18a | 18.9 | 4.4 | 0.48/0.52 | 1000 |
| 18b | 18.4 | 4.2 | 0.48/0.52 | 900 |
| 18c | 16.0 | 4.1 | 0.46/0.53 | 750 |

TABLE 3
Structural formulae of the materials used

| | |
|---|---|
| 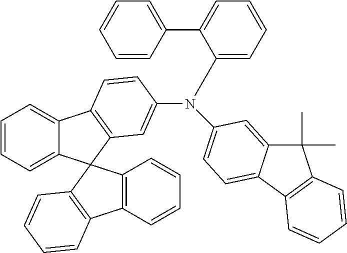 [SMILES: CC1(C)c2ccccc2-c2ccc(N(c3ccc4c(c3)C3(c5ccccc5-c5ccccc53)c3ccccc3-4)c3ccccc3-c3ccccc3)cc21] | HTM |
| 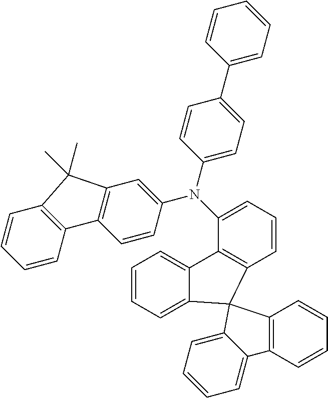 [SMILES: CC1(C)c2ccccc2-c2ccc(N(c3ccc(-c4ccccc4)cc3)c3cccc4c3-c3ccccc3C43c4ccccc4-c4ccccc43)cc21] | EBM |
| 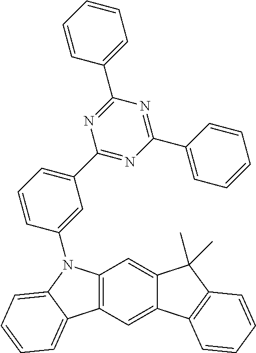 [SMILES: CC1(C)c2ccccc2-c2cc3c4ccccc4n(-c4cccc(-c5nc(-c6ccccc6)nc(-c6ccccc6)n5)c4)c3cc21] | eM1 |
| 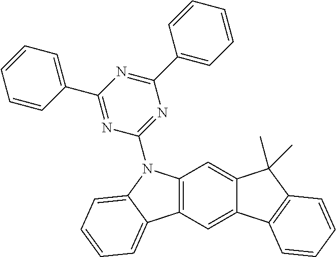 [SMILES: CC1(C)c2ccccc2-c2cc3c4ccccc4n(-c4nc(-c5ccccc5)nc(-c5ccccc5)n4)c3cc21] | eM2 |
| 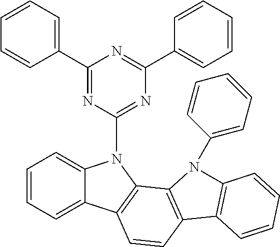 [SMILES: c1ccc(-c2nc(-c3ccccc3)nc(-n3c4ccccc4c4ccc5c6ccccc6n(-c6ccccc6)c5c43)n2)cc1] | eM3 |
| 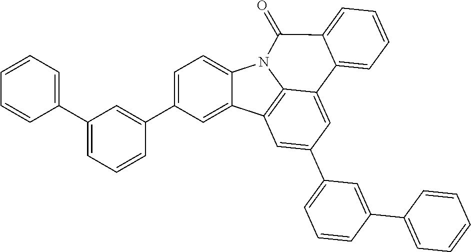 [SMILES: O=c1c2ccccc2c2cc(-c3cccc(-c4ccccc4)c3)cc3c4cc(-c5cccc(-c6ccccc6)c5)ccc4n1c23] | eM4 |
| 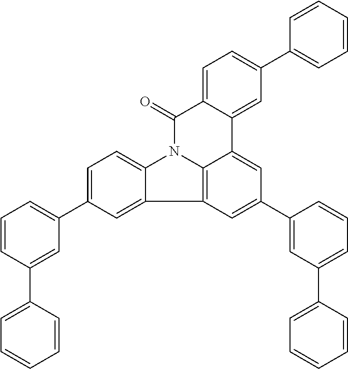 [SMILES: O=c1c2ccc(-c3ccccc3)cc2c2cc(-c3cccc(-c4ccccc4)c3)cc3c4cc(-c5cccc(-c6ccccc6)c5)ccc4n1c23] | eM5 |
| 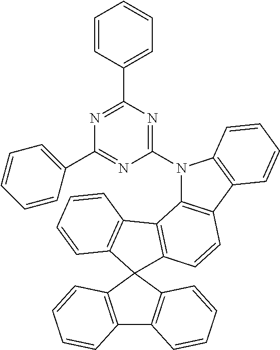 [SMILES: c1ccc(-c2nc(-c3ccccc3)nc(-n3c4ccccc4c4ccc5c(c43)-c3ccccc3C53c4ccccc4-c4ccccc43)n2)cc1] | eM6 |
| 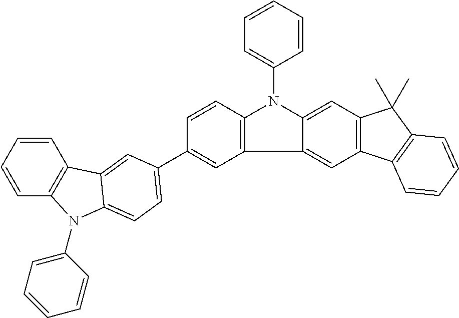 [SMILES: CC1(C)c2ccccc2-c2cc3c4cc(-c5ccc6c(c5)c5ccccc5n6-c5ccccc5)ccc4n(-c4ccccc4)c3cc21] | hM1 |
| 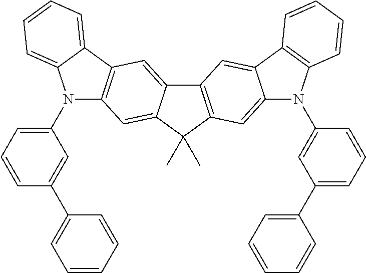 [SMILES: CC1(C)c2cc3c(cc2-c2cc4c5ccccc5n(-c5cccc(-c6ccccc6)c5)c4cc21)c1ccccc1n3-c1cccc(-c2ccccc2)c1] | hM2 |
| 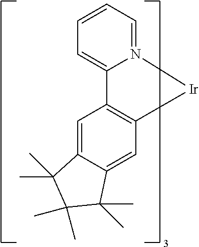 | G1 |
| 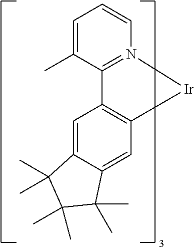 | G2 |
| 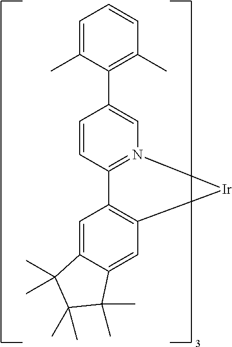 | G3 |
| 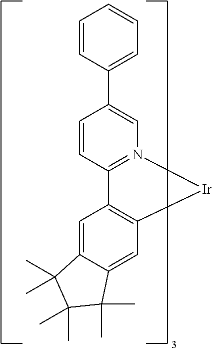 | Y1 |
| 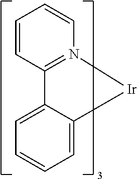 | Irppy |
| 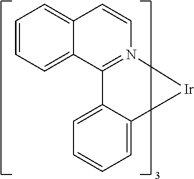 | Irpiq |
| 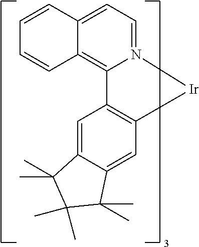 | R1 |
| 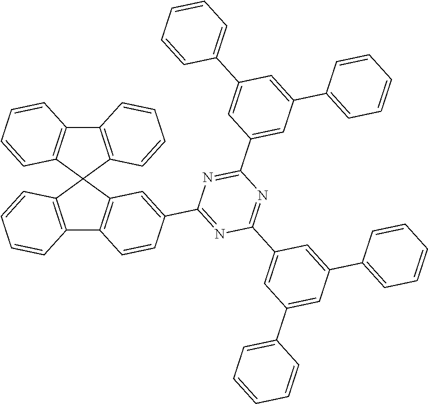 [SMILES: c1ccc(-c2cc(-c3ccccc3)cc(-c3nc(-c4cc(-c5ccccc5)cc(-c5ccccc5)c4)nc(-c4ccc5c(c4)C4(c6ccccc6-c6ccccc64)c4ccccc4-5)n3)c2)cc1] | ETM1 |
| 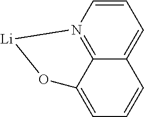 | ETM2/Liq |

TABLE 4
HOMO, LUMO, S₁ and T₁ of the materials used

| Material | HOMO [eV] | LUMO [eV] | S1 [eV] | T1 [eV] |
|---|---|---|---|---|
| eM1 | −5.47 | −2.60 | 2.87 | 2.72 |
| eM2 | −5.68 | −2.55 | 3.09 | 2.69 |
| eM3 | −5.67 | −2.49 | 3.07 | 2.75 |
| eM4 | −5.95 | −2.54 | 3.27 | 2.68 |
| eM5 | −5.94 | −2.60 | 3.21 | 2.66 |
| eM6 | −5.76 | −2.58 | 3.14 | 2.72 |
| hM1 | −5.32 | −1.84 | 3.24 | 2.80 |
| hM2 | −5.21 | −1.58 | 3.14 | 2.73 |

1-12. (canceled)

13. An organic electroluminescent device comprising a cathode, an anode and an emitting layer comprising the following compounds:
(A) at least one electron-transporting compound which has a LUMO≦−2.4 eV; and
(B) at least one further electron-transporting compound which is different from the first electron-transporting compound and has a LUMO≦−2.4 eV; and
(C) at least one phosphorescent iridium compound which comprises at least one at least bidentate ligand bonded to the iridium via one carbon atom and one nitrogen atom or via two carbon atoms and which comprises at least one unit of one of formulae (1) to (7): 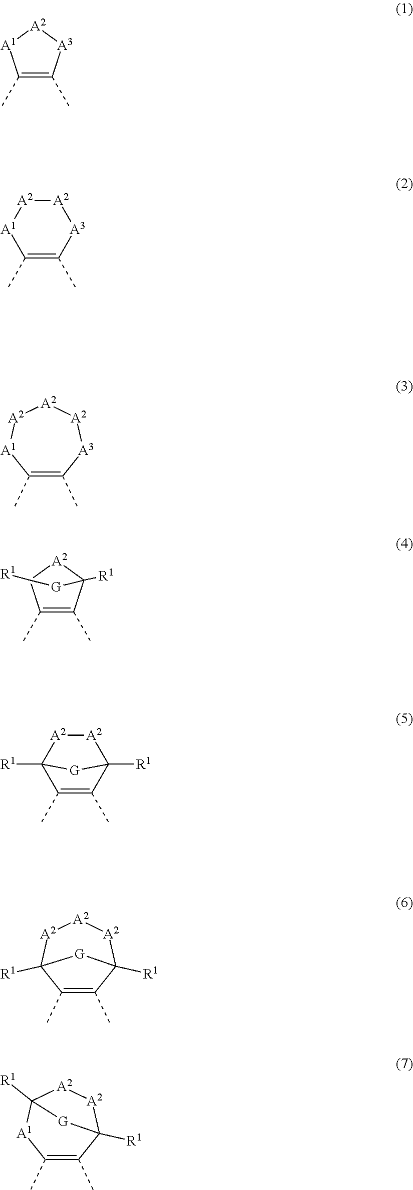
wherein
the two carbon atoms explicitly drawn in are atoms which are part of the ligand and the dashed bonds indicate the linking of the two carbon atoms in the ligand;
A¹ and A³
are, identically or differently on each occurrence, C(R³)₂, O, S, NR³, or C(═O);
A² is C(R¹)₂, O, S, NR³, or C(═O);
with the proviso that no two heteroatoms in the groups of formulae (1) to (7) are bonded directly to one another and no two groups C═O are bonded directly to one another;
G is an alkylene group having 1, 2, or 3 C atoms, which is optionally substituted by one or more radicals R², —CR²═CR²—, or an ortho-linked arylene or heteroarylene group having 5 to 14 aromatic ring atoms, which is optionally substituted by one or more radicals R²;
R¹ is on each occurrence, identically or differently, H, D, F, Cl, Br, I, N(R²)₂, CN, Si(R²)₃, B(OR²)₂, C(═O)R², a straight-chain alkyl, alkoxy, or thioalkoxy group having 1 to 20 C atoms or a straight-chain alkenyl, or alkynyl group having 2 to 20 C atoms or a branched or cyclic alkyl, alkenyl, alkynyl, alkoxy, or thioalkoxy group having 3 to 20 C atoms, each of which are optionally substituted by one or more radicals R², wherein one or more non-adjacent CH₂ groups are optionally replaced by R²C═CR², Si(R²)₂, C═O, NR², O, 5, or CONR² and wherein one or more H atoms are optionally replaced by D, F, or CN, an aromatic or heteroaromatic ring system having 5 to 60 aromatic ring atoms, which is optionally substituted by one or more radicals R², an aryloxy or heteroaryloxy group having 5 to 40 aromatic ring atoms, which is optionally substituted by one or more radicals R², or a diarylamino group, diheteroarylamino group, or arylheteroarylamino group having 10 to 40 aromatic ring atoms, which is optionally substituted by one or more radicals R²; and wherein two or more adjacent radicals R¹ optionally define an aliphatic ring system with one another;
R² is on each occurrence, identically or differently, H, D, F, or an aliphatic, aromatic, and/or heteroaromatic organic radical having 1 to 20 C atoms, wherein one or more H atoms are optionally replaced by D or F; and wherein two or more substituents R² optionally define an aliphatic or aromatic ring system with one another;
R³ is, identically or differently on each occurrence, F, a straight-chain alkyl or alkoxy group having 1 to 10 C atoms or a branched or cyclic alkyl or alkoxy group having 3 to 10 C atoms, each of which is optionally substituted by one or more radicals R², wherein one or more non-adjacent CH₂ groups are optionally replaced by R²C═CR², Si(R²)₂, C═O, NR², O, S, or CONR² and wherein one or more H atoms are optionally replaced by D or F, an aromatic or heteroaromatic ring system having 5 to 24 aromatic ring atoms, which is optionally substituted by one or more radicals R², an aryloxy or heteroaryloxy group having 5 to 24 aromatic ring atoms, which is optionally substituted by one or more radicals R², or an aralkyl or heteroaralkyl group having 5 to 24 aromatic ring atoms, which is optionally substituted by one or more radicals R²; and wherein two radicals R³ which are bonded to the same carbon atom optionally define an aliphatic or aromatic ring system with one another to form a spiro system; and wherein R³ optionally defines an aliphatic ring system with an adjacent radical R¹.

14. The organic electroluminescent device of claim 13, wherein the LUMO of each of the electron-transporting compounds is ≦−2.50 eV.

15. The organic electroluminescent device of claim 13, wherein the emitting layer consists only of the two electron-transporting compounds and the phosphorescent iridium compound or the emitting layer, apart from the two electron-transporting compounds and the phosphorescent iridium compound, further comprises at least one luminescent iridium compound.

16. The organic electroluminescent device of claim 13, wherein the following applies to each of the two electron-transporting compounds: T₁(matrix)≧T₁(emitter), wherein T₁(matrix) is the lowest triplet energy of the respective electron-transporting compound and T₁(emitter) is the lowest triplet energy of the phosphorescent iridium compound.

17. The organic electroluminescent device of claim 13, wherein the electron-transporting compounds are selected from the group consisting of the classes of the triazines; the pyrimidines; the pyrazines; the pyridazines; the pyridines; the lactams; the metal complexes; the aromatic ketones; the aromatic phosphine oxides; the azaphospholes; the azaboroles; which are substituted by at least one electron-transporting substituent; and the quinoxalines.

18. The organic electroluminescent device of claim 13, wherein one of the electron-transporting compounds is a triazine or pyrimidine compound and the other of the electron-transporting compounds is a lactam compound.

19. The organic electroluminescent device of claim 13, wherein at least one electron-transporting compound is selected from the compounds of the formulae (8) and (9): 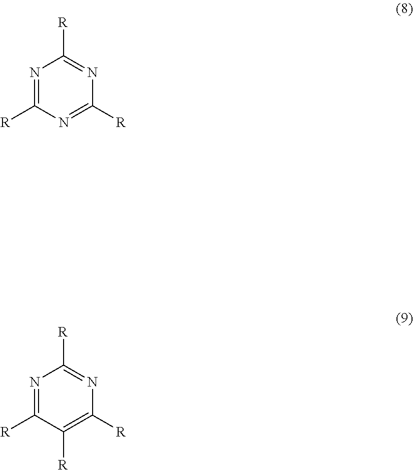
wherein
R is selected on each occurrence, identically or differently, from the group consisting of H, D, F, Cl, Br, I, CN, NO₂, N(R¹)₂, C(═O)R¹, P(═O)R¹, a straight-chain alkyl, alkoxy, or thioalkyl group having 1 to 20 C atoms or a branched or cyclic alkyl, alkoxy, or thioalkyl group having 3 to 20 C atoms or an alkenyl or alkynyl group having 2 to 20 C atoms, each of which is optionally substituted by one or more radicals R¹, wherein one or more non-adjacent CH₂ groups are optionally replaced by R¹C═CR¹, C≡C, Si(R¹)₂, C═O, C═S, C═NR¹, P(═O)(R¹), SO, SO₂, NR¹, O, S, or CONR¹ and wherein one or more H atoms are optionally replaced by D, F, Cl, Br, I, CN, or NO₂, an aromatic or heteroaromatic ring system having 5 to 40 aromatic ring atoms, which is optionally substituted by one or more radicals R¹, an aryloxy or heteroaryloxy group having 5 to 40 aromatic ring atoms, which is optionally substituted by one or more radicals R¹, or an aralkyl or heteroaralkyl group having 5 to 40 aromatic ring atoms, which is optionally substituted by one or more radicals R¹, and wherein two or more adjacent substituents R optionally define a monocyclic or polycyclic, aliphatic, aromatic or heteroaromatic ring system, which is optionally substituted by one or more radicals R¹; with the proviso that at least one of the substituents R is an aromatic or heteroaromatic ring system.

20. The organic electroluminescent device of claim 19, wherein at least one electron-transporting compound is selected from the group consisting of compounds of formulae (8a) and (9a) through (9d): 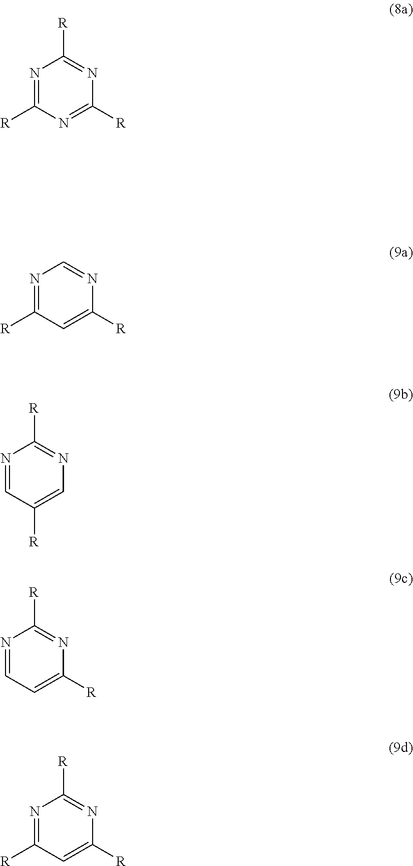
wherein
R is, identically or differently, for an aromatic or heteroaromatic ring system having 5 to 40 aromatic ring atoms, which is optionally substituted by one or more radicals R¹.

21. The organic electroluminescent device of claim 13, wherein at least one electron-transporting compound is a lactam which is selected from the group consisting of compounds of formulae (53) and (54): 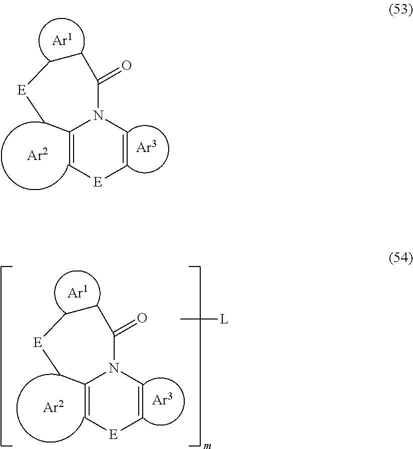
wherein
R is selected on each occurrence, identically or differently, from the group consisting of H, D, F, Cl, Br, I, CN, NO₂, N(R¹)₂, C(═O)R¹, P(═O)R¹, a straight-chain alkyl, alkoxy, or thioalkyl group having 1 to 20 C atoms or a branched or cyclic alkyl, alkoxy, or thioalkyl group having 3 to 20 C atoms or an alkenyl or alkynyl group having 2 to 20 C atoms, each of which is optionally substituted by one or more radicals R¹, wherein one or more non-adjacent CH₂ groups are optionally replaced by R¹C═CR¹, C≡C, Si(R¹)₂, C═O, C═S, C═NR¹, P(═O)(R¹), SO, SO₂, NR¹, O, S, or CONR¹ and wherein one or more H atoms are optionally replaced by D, F, Cl, Br, I, CN, or NO₂, an aromatic or heteroaromatic ring system having 5 to 40 aromatic ring atoms, which is optionally substituted by one or more radicals R¹, an aryloxy or heteroaryloxy group having 5 to 40 aromatic ring atoms, which is optionally substituted by one or more radicals R¹, or an aralkyl or heteroaralkyl group having 5 to 40 aromatic ring atoms, which is optionally substituted by one or more radicals R¹, and wherein two or more adjacent substituents R optionally define a monocyclic or polycyclic, aliphatic, aromatic or heteroaromatic ring system, which is optionally substituted by one or more radicals R′; with the proviso that at least one of the substituents R is an aromatic or heteroaromatic ring system;
R¹ is on each occurrence, identically or differently, H, D, F, Cl, Br, I, N(R²)₂, CN, Si(R²)₃, B(OR²)₂, C(═O)R², a straight-chain alkyl, alkoxy, or thioalkoxy group having 1 to 20 C atoms or a straight-chain alkenyl, or alkynyl group having 2 to 20 C atoms or a branched or cyclic alkyl, alkenyl, alkynyl, alkoxy, or thioalkoxy group having 3 to 20 C atoms, each of which are optionally substituted by one or more radicals R², wherein one or more non-adjacent CH₂ groups are optionally replaced by R²C═CR², Si(R²)₂, C═O, NR², O, S, or CONR² and wherein one or more H atoms are optionally replaced by D, F, or CN, an aromatic or heteroaromatic ring system having 5 to 60 aromatic ring atoms, which is optionally substituted by one or more radicals R², an aryloxy or heteroaryloxy group having 5 to 40 aromatic ring atoms, which is optionally substituted by one or more radicals R², or a diarylamino group, diheteroarylamino group, or arylheteroarylamino group having 10 to 40 aromatic ring atoms, which is optionally substituted by one or more radicals R²; and wherein two or more adjacent radicals R¹ optionally define an aliphatic ring system with one another;
R² is on each occurrence, identically or differently, H, D, F, or an aliphatic, aromatic, and/or heteroaromatic organic radical having 1 to 20 C atoms, wherein one or more H atoms are optionally replaced by D or F; and wherein two or more substituents R² optionally define an aliphatic or aromatic ring system with one another;
E is, identically or differently on each occurrence, a single bond, NR, CR₂, O or S;
Ar¹ is, together with the carbon atoms explicitly depicted, an aromatic or heteroaromatic ring system having 5 to 18 aromatic ring atoms, which may be substituted by one or more radicals R;
Ar² and Ar³
are, identically or differently on each occurrence, together with the carbon atoms explicitly depicted, an aromatic or heteroaromatic ring system having 5 to 18 aromatic ring atoms, which is optionally substituted by one or more radicals R;
L is for m=2 a single bond or a divalent group, or for m=3 a trivalent group or for m=4 a tetravalent group, which is in each case bonded to Ar¹, Ar², or Ar³ at any desired position or is bonded to E in place of a radical R;
m is 2, 3 or 4.

22. The organic electroluminescent device of claim 13, wherein the structures of the formulae (1) to (7) are selected from the structures of the formulae (1-A) through (1-F), (2-A) through (2-F), (3-A) through (3-E), (4-A) through (4-C), (5-A), (6-A), and (7-A), 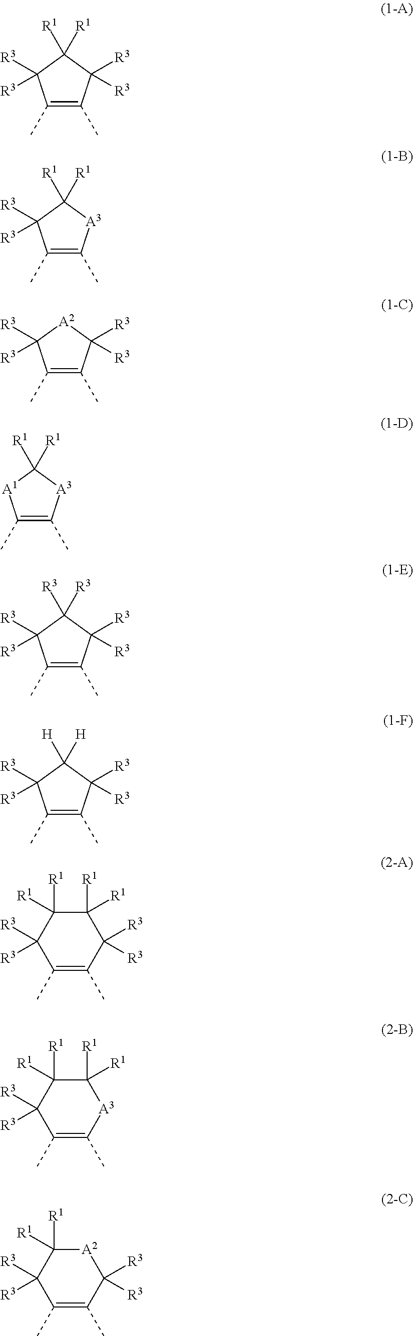 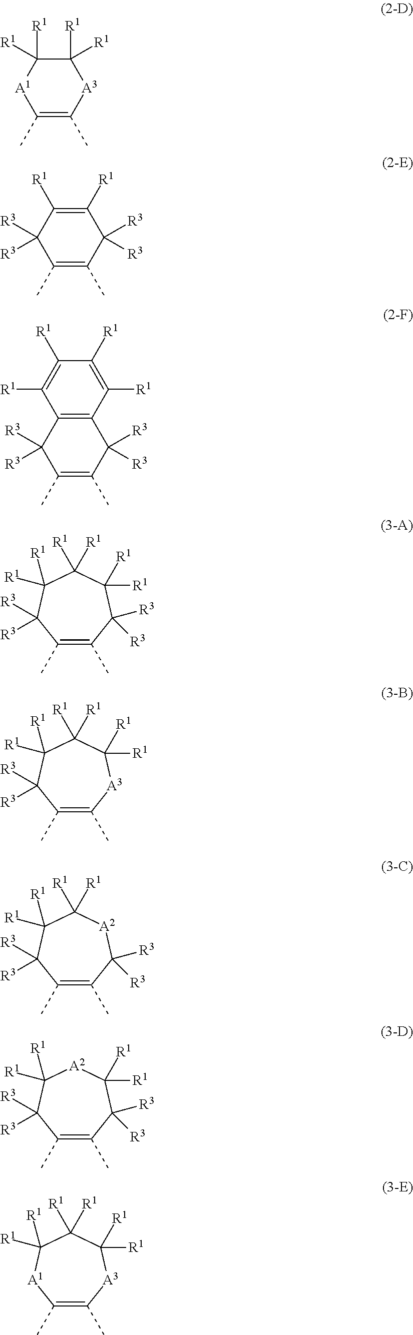 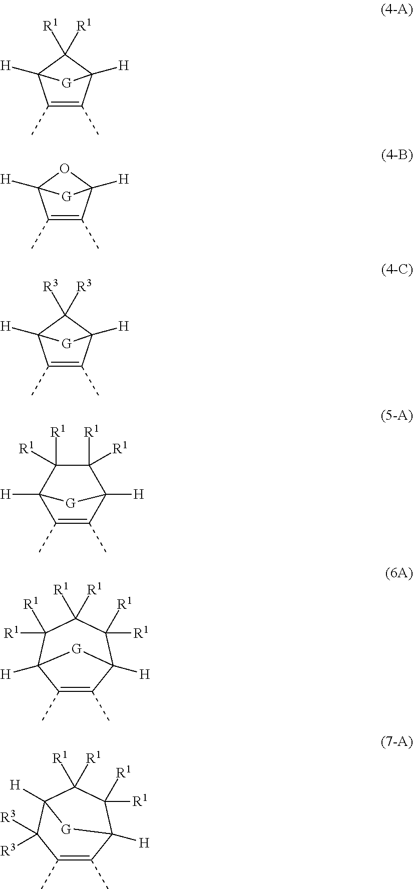
wherein
A¹, A² and A³
are, identically or differently on each occurrence, for O or NR³.

23. The organic electroluminescent device of claim 13, wherein the phosphorescent iridium compound is a compound of formula (75):
Ir(L¹)ₚ(L²)_{q} 75)
wherein
L¹ is a bidentate monoanionic ligand comprising at least one aryl or heteroaryl group bonded to the iridium via a carbon or nitrogen atom and which comprises a group of formulae (1) to (7);
L² is, identically or differently on each occurrence, a monoanionic bidentate ligand;
p is 1, 2, or 3;
q is (3−p).

24. A process for producing an organic electroluminescent according to claim 13, comprising producing one or more layers by means of (1) a sublimation process and/or (2) an organic vapour phase deposition process or with the aid of carrier-gas sublimation and/or (3) from solution.
